(19) United States
(12) Patent Application Publication
(10) Pub. No.: US 2025/0036028 A1
(43) Pub. Date: Jan. 30, 2025

(54) RESIST COMPOSITION AND METHOD FOR FORMING RESIST PATTERN

(71) Applicant: TOKYO OHKA KOGYO CO., LTD., Kawasaki-shi (JP)

(72) Inventors: Tomoyuki Hirano, Kawasaki-shi (JP); Tomonari Sunamichi, Kawasaki-shi (JP); Haruna Hashimoto, Kawasaki-shi (JP); Yusuke Nakagawa, Kawasaki-shi (JP)

(21) Appl. No.: 18/713,393

(22) PCT Filed: Dec. 5, 2022
(86) PCT No.: PCT/JP2022/044740

§ 371 Date: May 24, 2024

(30) Foreign Application Priority Data
Dec. 16, 2021 (JP) 2021-204596

(51) Int. Cl. G03F 7/039; G03F 7/004; G03F 7/038

(52) U.S. Cl. CPC G03F 7/0397; G03F 7/0045; G03F 7/0382

(57) ABSTRACT

A resist composition including a polymer compound having a constitutional unit represented by General Formula (a10-1) below, an onium salt-based acid generator, a crosslinking agent, and a polynuclear phenol low-molecular-weight compound containing 5 or less phenyl groups, in which the resist composition has a solid content concentration of 15% by mass or greater. In the formula, R represents a hydrogen atom, an alkyl group having 1 to 5 carbon atoms, or a halogenated alkyl group having 1 to 5 carbon atoms; Ya^{x1} represents a single bond or a divalent linking group; Wa^{x1} represents an aromatic hydrocarbon group which may have a substituent; and nₐₓ₁ represents an integer of 1 or greater

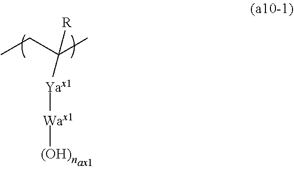

### TECHNICAL FIELD

The present invention relates to a resist composition and a method for forming a resist pattern.

Priority is claimed on Japanese Patent Application No. 2021-204596, filed Dec. 16, 2021, the content of which is incorporated herein by reference.

### BACKGROUND ART

In recent years, in the manufacture of semiconductor elements and liquid crystal display elements, advances in lithography technologies have led to rapid progress in the field of pattern miniaturization. These pattern miniaturization techniques typically involve shortening the wavelength (increasing the energy) of the exposure light source.

Resist materials are required to have lithography characteristics such as sensitivity to these kinds of exposure light sources and resolution that enables reproduction of patterns with minute dimensions.

As a resist material that satisfies these requirements, a chemically amplified resist composition containing a base material component whose solubility in a developing solution is changed due to an action of an acid and an acid generator component that generates an acid upon light exposure has been used in the related art.

In the manufacture of a semiconductor package, a MEMS, and the like, a step of forming a thick resist film on a surface of a processing object, forming a resist pattern, and performing etching or the like is carried out. In a case where a chemically amplified resist composition is used here, the sensitivity is more difficult to maintain during light exposure as the film thickness of the resist film increases, and as a result, problems of a decrease in resolution for development and difficulties in obtaining a desired resist pattern shape occur. Further, there is also a problem in that cracking is likely to occur in the resist pattern as the film thickness of the resist film increases.

Patent Document 1 suggests a resist composition containing a base material component and a specific amount of a polyether compound, in which the resist composition has a solid content concentration of 25% by mass or greater. According to the resist composition, a thick resist film can be formed, and a resist pattern in which cracking is unlikely to occur and the resolution is satisfactory can be formed.

### CITATION LIST

### Patent Document

### [Patent Document 1]

Japanese Unexamined Patent Application, First Publication No. 2021-033158

### SUMMARY OF INVENTION

### Technical Problem

A resist used for thick films is required to reduce occurrence of cracking in a thick film pattern and to have coating properties with respect to a substrate having a step or the like.

In addition, in resists used for thick films, there is room for improvement in lithography characteristics such as resolution or depth of focus (DOF).

The term “DOF” denotes a range of depth of focus that allows a resist pattern to be formed such that a shift of dimensions from the target dimensions is in a predetermined range in a case of light exposure by shifting the focus in the vertical direction with the same exposure amount, that is, a range where a resist pattern faithful to a mask pattern can be obtained, and it is preferable that this value of DOF is as large as possible.

The present invention has been made in consideration of the above-described circumstances, and an object thereof is to provide a resist composition capable of forming a thick-film resist pattern that is unlikely to cause cracking and has satisfactory coating properties with respect to a substrate while lithography characteristics such as resolution and DOF are maintained, and a method for forming a resist pattern using the resist composition.

### Solution to Problem

In order to achieve the above-described object, the present invention employs the following configurations.

That is, according to a first aspect of the present invention, there is provided a resist composition including: a polymer compound (A1) having a constitutional unit (a10) represented by General Formula (a10-1); an onium salt-based acid generator (B1); at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent; and a polynuclear phenol low-molecular-weight compound (Z) containing 5 or less phenyl groups, in which the resist composition has a solid content concentration of 15% by mass or greater.

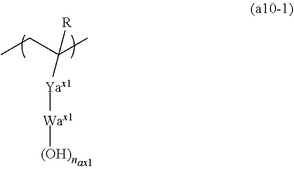

[In the formula, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or greater.]

According to a second aspect of the present invention, there is provided a method for forming a resist pattern, including: a step of forming a resist film on a support using the resist composition according to the first aspect; a step of exposing the resist film to light; and a step of developing the resist film exposed to light to form a resist pattern.

### Advantageous Effects of Invention

According to the present invention, it is possible to provide a resist composition capable of forming a thick-film resist pattern that is unlikely to cause cracking and has satisfactory coating properties with respect to a substrate while lithography characteristics such as resolution and DOF are maintained, and a method for forming a resist pattern using the resist composition.

### BRIEF DESCRIPTION OF DRAWINGS

FIG. 1 is a schematic cross-sectional view showing a substrate which has a surface on which a simulated resist pattern has been formed, and has a step.

FIG. 2 is a schematic cross-sectional view showing a substrate which has a surface on which a simulated resist pattern has been formed, and has a step.

### DESCRIPTION OF EMBODIMENTS

In the present specification and the present claims, the term “aliphatic” is a relative concept used in relation to the term “aromatic”, and defines a group or compound that has no aromaticity.

The term “alkyl group” includes a linear, branched, or cyclic monovalent saturated hydrocarbon group unless otherwise specified. The same applies to the alkyl group in an alkoxy group.

The term “alkylene group” includes a linear, branched, or cyclic divalent saturated hydrocarbon group unless otherwise specified.

Examples of “halogen atom” include a fluorine atom, a chlorine atom, a bromine atom, and an iodine atom.

The term “constitutional unit” indicates a monomer unit constituting a polymer compound (a resin, a polymer, or a copolymer).

The expression “may have a substituent” includes both a case where a hydrogen atom (—H) is substituted with a monovalent group and a case where a methylene (—CH₂—) group is substituted with a divalent group.

The term “light exposure” is a general concept for irradiation with radiation.

The term “acid decomposable group” indicates a group having acid decomposability in which at least a part of a bond in the structure of the acid decomposable group can be cleaved due to the action of an acid.

Examples of the acid decomposable group whose polarity is increased due to the action of an acid include groups which are decomposed due to the action of an acid to generate a polar group.

Examples of the polar group include a carboxy group, a hydroxyl group, an amino group, and a sulfo group (—SO₃H).

More specific examples of the acid decomposable group include a group in which the above-described polar group has been protected by an acid dissociable group (such as a group in which a hydrogen atom of the OH-containing polar group has been protected by an acid dissociable group).

Here, the term “acid dissociable group” indicates both a group (i) having an acid dissociation property in which a bond between the acid dissociable group and an atom adjacent to the acid dissociable group can be cleaved due to the action of an acid and a group (ii) in which some bonds are cleaved due to the action of an acid, a decarboxylation reaction occurs, and thus the bond between the acid dissociable group and the atom adjacent to the acid dissociable group can be cleaved.

It is necessary that the acid dissociable group that constitutes the acid decomposable group is a group which exhibits a lower polarity than that of the polar group generated by the dissociation of the acid dissociable group. Thus, in a case where the acid dissociable group is dissociated by the action of an acid, a polar group exhibiting a higher polarity than that of the acid dissociable group is generated so that the polarity is increased. As a result, the polarity of an entire component (A1) is increased. Due to the increase in the polarity, relatively, the solubility in a developing solution is changed such that the solubility is increased in a case where the developing solution is an alkali developing solution and the solubility is decreased in a case where the developing solution is an organic developing solution.

The term “base material component” denotes an organic compound having a film-forming ability. Organic compounds used as the base material component are classified into non-polymers and polymers. As the non-polymers, those having a molecular weight of 500 or greater and less than 4,000 are typically used. Hereinafter, the term “low-molecular-weight compound” denotes a non-polymer having a molecular weight of 500 or greater and less than 4,000. As the polymer, those having a molecular weight of 1,000 or greater are typically used. Hereinafter. “resin”, “polymer compound”, or “polymer” indicates a polymer having a molecular weight of 1.000 or greater. As the molecular weight of the polymer, the weight-average molecular weight in terms of polystyrene according to gel permeation chromatography (GPC) is used.

The expression “constitutional unit to be derived” denotes a constitutional unit formed by cleavage of a multiple bond between carbon atoms, for example, an ethylenic double bond.

In “acrylic acid ester”, the hydrogen atom bonded to the carbon atom at the α-position may be substituted with a substituent. The substituent (R^{αx}) that substitutes the hydrogen atom bonded to the carbon atom at the α-position is an atom other than the hydrogen atom or a group. Further, the acrylic acid ester includes itaconic acid diester in which the substituent (R^{αx}) has been substituted with a substituent having an ester bond and α-hydroxyacryl ester in which the substituent (R^{αx}) has been substituted with a hydroxyalkyl group or a group obtained by modifying a hydroxyl group thereof. Further, the carbon atom at the α-position of acrylic acid ester indicates the carbon atom to which the carbonyl group of acrylic acid is bonded, unless otherwise specified.

Hereinafter, acrylic acid ester in which the hydrogen atom bonded to the carbon atom at the α-position has been substituted with a substituent is also referred to as α-substituted acrylic acid ester.

The concept “derivative” includes those obtained by substituting a hydrogen atom at the α-position of a target compound with another substituent such as an alkyl group or a halogenated alkyl group, and derivatives thereof. Examples of the derivatives thereof include those obtained by substituting a hydrogen atom of a hydroxyl group of a target compound, in which the hydrogen atom at the α-position may be substituted with a substituent, with an organic group, and those obtained by bonding a substituent other than a hydroxyl group to a target compound in which the hydrogen atom at the α-position may be substituted with a substituent. Further, the α-position denotes the first carbon atom adjacent to a functional group unless otherwise specified.

Examples of the substituent that substitutes the hydrogen atom at the α-position of hydroxystyrene include those for R^{αx}.

In the present specification and the scope of the present claims, asymmetric carbons may be present and enantiomers or diastereomers may be present depending on the structures of the chemical formulae. In this case, these isomers are represented by one chemical formula. These isomers may be used alone or in the form of a mixture.

### (Resist Composition)

A resist composition according to a first aspect of the present invention contains a polymer compound (A1) (hereinafter, also referred to as “component (A1)”) having a constitutional unit (a10) represented by General Formula (a10-1), an onium salt-based acid generator (B1) (hereinafter, also referred to as “component (B1)”), at least one crosslinking agent (C) (hereinafter, also referred to as “component (C)”) selected from the group consisting of a melamine-based crosslinking agent, a urea-based crosslinking agent, an alkylene urea-based crosslinking agent, a glycoluril-based crosslinking agent, and an epoxy-based crosslinking agent, and a polynuclear phenyl low-molecular-weight compound (Z) (hereinafter, also referred to as “component (Z)”) containing 5 or less phenyl groups. The solid content concentration of the resist composition according to the present embodiment is 15% by mass or greater.

In a case where a resist film is formed using such a resist composition, a thick resist film (for example, a film having a film thickness of 2 μm to 20 μm) can be formed.

In a case where a resist film is formed of such a resist composition and the resist film is selectively exposed, since an acid is generated in an exposed portion of the resist film and the solubility of the component (A) in a developing solution is changed due to the action of the acid while the solubility of the component (A) in a developing solution is not changed in an unexposed portion of the resist film, a difference in solubility in the developing solution occurs between the exposed portion of the resist film and the unexposed portion of the resist film. Therefore, in a case where the resist film is developed, the exposed portion of the resist film is dissolved and removed to form a positive tone resist pattern in a case where the resist composition is of a positive tone, whereas the unexposed portion of the resist film is dissolved and removed to form a negative tone resist pattern in a case where the resist composition is of a negative tone.

### <Component (A)>

The component (A) is a base material component whose solubility in a developing solution is changed due to the action of an acid.

In the present invention, the term “base material component” is an organic compound having a film-forming ability, and an organic compound having a molecular weight of 500 or greater is preferably used. In a case where the molecular weight of the organic compound is 500 or greater, the film-forming ability is improved, and a nano-level resist pattern is likely to be formed.

Organic compounds used as the base material component are classified into non-polymers and polymers.

As the non-polymers, those having a molecular weight of 500 or greater and less than 4.000 are typically used. Hereinafter, the term “low-molecular-weight compound” denotes a non-polymer having a molecular weight of 500 or greater and less than 4.000.

As the polymer, those having a molecular weight of 1,000 or greater are typically used. Hereinafter, “resin”, “polymer compound”, or “polymer” indicates a polymer having a molecular weight of 1,000 or greater.

As the molecular weight of the polymer, the weight-average molecular weight in terms of polystyrene according to gel permeation chromatography (GPC) is used.

In the resist composition according to the present embodiment, at least the polymer compound (A1) having the constitutional unit (a10) represented by General Formula (a0-1) is used in the component (A), and a polymer compound and/or a low-molecular-weight compound other than the component (A1) may be further used in combination.

In a case where a resist film is formed using a resist composition containing at least the component (A1), and the resist film is selectively exposed to light, an acid is generated from the component (B1) in an exposed portion of the resist film, crosslinking occurs between the components (A1) through the constitutional unit (a10) having crosslinking properties due to the action of the acid, and as a result, the solubility of the exposed portion of the resist film in an alkali developing solution is decreased. Therefore, in the formation of a resist pattern, in a case where a resist film obtained by coating a support with the resist composition according to the present embodiment is selectively exposed to light, exposed portions of the resist film change to be insoluble in an alkali developing solution, whereas unexposed portions of the resist film remain soluble in the alkali developing solution, and thus a negative tone resist pattern is formed by carrying out development with the alkali developing solution.

### In Regard to Component (A1)

The component (A1) is a polymer compound having a constitutional unit (a10) represented by General Formula (a10-1).

The component (A1) is preferably a copolymer further having, in addition to the constitutional unit (a10), a constitutional unit (a1) containing an aromatic ring (excluding an aromatic ring to which a hydroxy group is bonded) in a side chain.

In addition, the component (A1) may have a constitutional unit other than the constitutional unit (a10) and the constitutional unit (a1).

In Regard to Constitutional Unit (a10):

The constitutional unit (a10) is a constitutional unit represented by General Formula (a10-1).

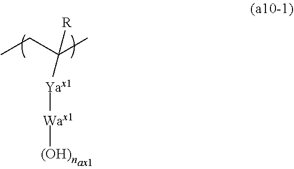

[In the formulae, R represents a hydrogen atom, an alkyl group having 1 to 5 carbon atoms, or a halogenated alkyl group having 1 to 5 carbon atoms. Ya^{x1} represents a single bond or a divalent linking group. Wa^{x1} represents an aromatic hydrocarbon group which may have a substituent. nₐₓ₁ represents an integer of 1 or greater.]

In the Formula (a10-1), R represents a hydrogen atom, an alkyl group having 1 to 5 carbon atoms, or a halogenated alkyl group having 1 to 5 carbon atoms.

R represents preferably a hydrogen atom, an alkyl group having 1 to 5 carbon atoms, or a fluorinated alkyl group having 1 to 5 carbon atoms, and from the viewpoint of industrial availability, more preferably a hydrogen atom, a methyl group, or trifluoromethyl group, still more preferably a hydrogen atom or a methyl group, and particularly preferably a hydrogen atom.

In Formula (a10-1), Ya^{x1} represents a single bond or a divalent linking group.

In the chemical formula, the divalent linking group as Ya^{x1} is not particularly limited, and suitable examples thereof include a divalent hydrocarbon group which may have a substituent and a divalent linking group having a heteroatom.

Ya^{x1} represents preferably a single bond, an ester bond [—C(═O)—O— or —O—C(═O)—], an ether bond (—O—), a linear or branched alkylene group, or a combination thereof and more preferably a single bond or an ester bond [—C(═O)—O— or —O—C(═O)—].

In Formula (a10-1), Wa^{x1} represents an aromatic hydrocarbon group which may have a substituent.

Examples of the aromatic hydrocarbon group as Wa^{x1} include a group in which (nₐₓ₁+1) hydrogen atoms have been removed from an aromatic ring which may have a substituent. The aromatic ring is not particularly limited as long as the aromatic ring is a cyclic conjugated system having (4n+2) π electrons. The aromatic ring has preferably 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and an aromatic heterocyclic ring obtained by substituting some carbon atoms constituting the above-described aromatic hydrocarbon ring with a heteroatom. Examples of the heteroatom in the aromatic heterocyclic rings include an oxygen atom, a sulfur atom, and a nitrogen atom. Specific examples of the aromatic heterocyclic ring include a pyridine ring and a thiophene ring.

Further, examples of the aromatic hydrocarbon group as Wa^{x1} also include a group in which (nₐₓ₁+1) hydrogen atoms have been removed from an aromatic compound having an aromatic ring (for example, biphenyl or fluorene) which may have two or more substituents.

Among the examples. Wa^{x1} represents preferably a group in which (nₐₓ₁+1) hydrogen atoms have been removed from benzene, naphthalene, anthracene, or biphenyl, more preferably a group in which (nₐₓ₁+1) hydrogen atoms have been removed from benzene or naphthalene, and still more preferably a group in which (nₐₓ₁+1) hydrogen atoms have been removed from benzene.

The aromatic hydrocarbon group as Wa^{x1} may or may not have a substituent. Examples of substituents include an alkyl group, an alkoxy group, a halogen atom, and a halogenated alkyl group. Examples of the alkyl group, the alkoxy group, the halogen atom, and the halogenated alkyl group as the substituent include those described as the substituent of the cyclic aliphatic hydrocarbon group as Ya^{x1}. The substituent is preferably a linear or branched alkyl group having 1 to 5 carbon atoms, more preferably a linear or branched alkyl group having 1 to 3 carbon atoms, still more preferably an ethyl group or a methyl group, and particularly preferably a methyl group. It is preferable that the aromatic hydrocarbon group as Wa^{x1} has no substituent.

In Formula (a10-1), nₐₓ₁ represents an integer of 1 or greater, preferably an integer of 1 to 10, more preferably an integer of 1 to 5, still more preferably 1, 2, or 3, and particularly preferably 1 or 2.

Specific examples of the constitutional unit (a10) represented by Formula (a10-1) are described below.

In the formulae shown below. R^{α} represents a hydrogen atom, a methyl group, or a trifluoromethyl group.

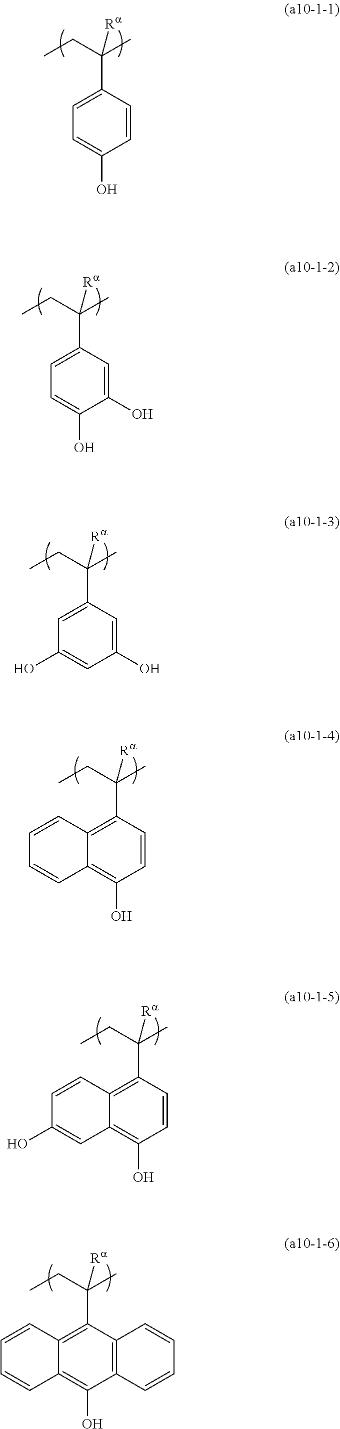

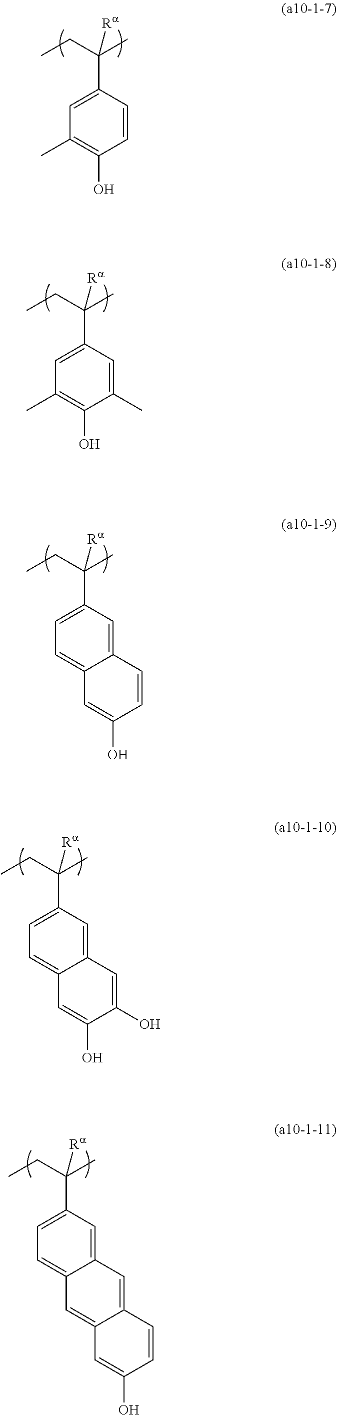

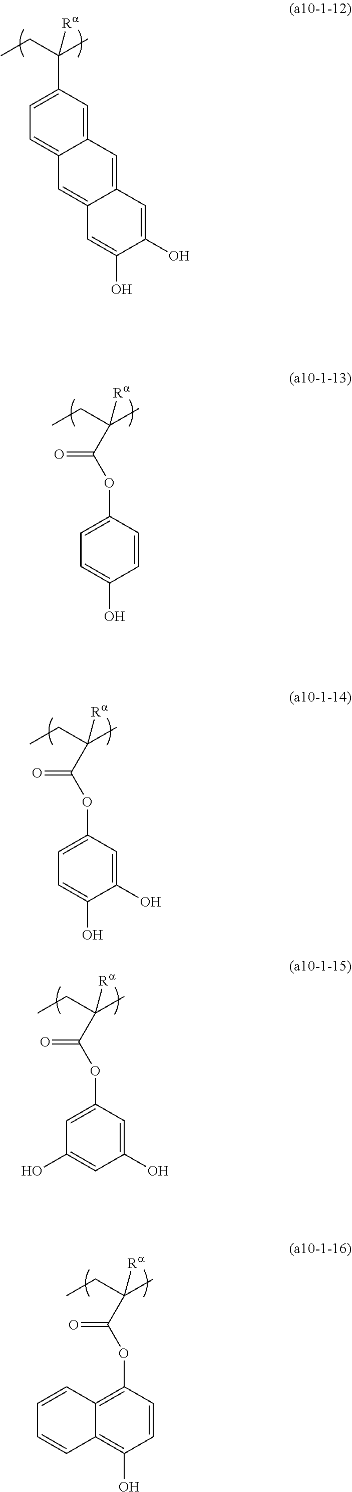

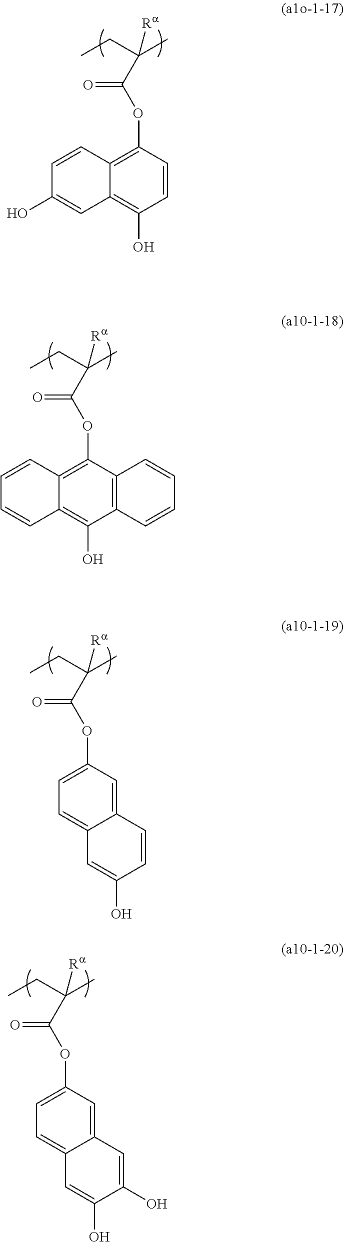

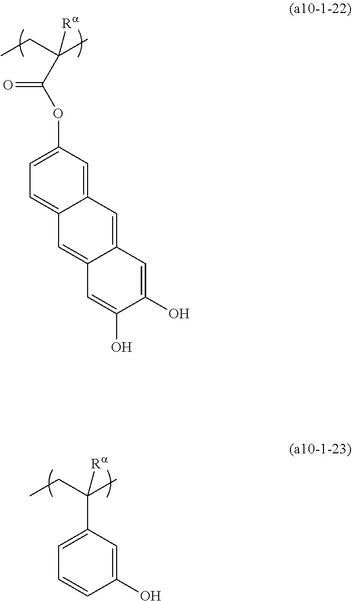

The constitutional unit (a10) of the component (A1) may be used alone or two or more kinds thereof.

The proportion of the constitutional unit (a10) in the component (A) is preferably in a range of 50% to 100% by mole, more preferably in a range of 60% to 100% by mole, still more preferably in a range of 65% to 100% by mole, and particularly preferably in a range of 70% to 100% by mole with respect to the total amount (100% by mole) of all constitutional units constituting the component (A1).

In a case where the proportion of the constitutional unit (a10) is set to be greater than or equal to the above-described lower limits, development characteristics and lithography characteristics are further improved. Meanwhile, in a case where the proportion thereof is set to be less than or equal to the above-described upper limits, the constitutional unit (a10) and other constitutional units are likely to be balanced.

### In Regard to Constitutional Unit (a1):

The component (A1) is preferably a copolymer further having, in addition to the above-described constitutional unit (a10), the constitutional unit (a11) derived from a compound containing an aromatic ring (excluding an aromatic ring to which a hydroxy group is bonded) in the side chain.

Suitable examples of the compound containing an aromatic ring (excluding an aromatic ring to which a hydroxy group is bonded) in the side chain include a compound represented by General Formula (a11-1).

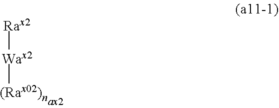

[In Formula (a11-1), Ra^{x2} represents a polymerizable group-containing group. Wa^{x2} represents an (nₐₓ₂+1)-valent aromatic hydrocarbon group. Here, Ra^{x2} and Wa^{x2} may form a condensed ring structure. Ra^{x02} represents a substituent that substitutes a hydrogen atom constituting Wa^{x2} (aromatic hydrocarbon group). nₐₓ₂ represents an integer of 0 to 3. In a case where nₐₓ₂ represents 2 or greater, a plurality of Ra^{x02}'s may be bonded to each other to form a ring structure.]

In Formula (a11-1), Ra^{x2} represents a polymerizable group-containing group.

The term “polymerizable group” as Ra^{x2} denotes a group that enables a compound containing the polymerizable group to be polymerized by radical polymerization or the like and has a multiple bond between carbon atoms, such as an ethylenic double bond.

Examples of the polymerizable group include a vinyl group, an allyl group, acryloyl group, a methacryloyl group, a fluorovinyl group, a difluorovinyl group, a trifluorovinyl group, a difluorotrifluoromethylvinyl group, a trifluoroallyl group, a perfluoroallyl group, a trifluoromethylacryloyl group, a nonylfluorobutylacryloyl group, a vinyl ether group, a fluorine-containing vinyl ether group, an allyl ether group, a fluorine-containing allyl ether group, a styryl group, and a vinylnaphthyl group, a fluorine-containing styryl group, a fluorine-containing vinylnaphthyl group, a norbornyl group, a fluorine-containing norbornyl group, and a silyl group.

The polymerizable group-containing group may be a group formed of only a polymerizable group or a group formed of a polymerizable group and a group other than the polymerizable group. Examples of the group other than the polymerizable group include a divalent hydrocarbon group which may have a substituent and a divalent linking group having a heteroatom.

Suitable examples of Ra^{x2} include a group represented by Chemical Formula: CH₂═C(R)-Ya^{x0}-. In the chemical formula, R represents a hydrogen atom, an alkyl group having 1 to 5 carbon atoms, or a halogenated alkyl group having 1 to 5 carbon atoms, and Ya^{x0} represents a divalent linking group.

In Formula (a11-1), Wa² represents an (nₐₓ₂+1)-valent aromatic hydrocarbon group, and examples thereof include the same groups as those for Wa^{x1} in (a10-1).

Here, Ra^{x2} and Wa^{x2} may form a condensed ring structure.

In a case where Ra^{x2} and Wa^{x2} form a condensed ring structure, the condensed ring structure includes an aromatic ring derived from Wa^{x2}. Further, the multiple bond between carbon atoms of the polymerizable group derived from Ra^{x2} is cleaved to form the main chain of the component (A1). That is, some of the carbon atoms constituting the condensed ring constitute the main chain of component (A1).

In Formula (a11-1), Ra^{x02} represents a substituent that substitutes a hydrogen atom constituting Wa^{x2} (aromatic hydrocarbon group).

Examples of the substituent as Ra^{x02} include an alkyl group, an alkoxy group, and an acyloxy group.

The alkyl group as a substituent represented by Ra^{x02} is preferably an alkyl group having 1 to 5 carbon atoms and more preferably a methyl group, an ethyl group, a propyl group, an n-butyl group, or a tert-butyl group.

The alkoxy group as a substituent represented by Ra^{x02} is preferably an alkoxy group having 1 to 5 carbon atoms, more preferably a methoxy group, an ethoxy group, an n-propoxy group, an iso-propoxy group, an n-butoxy group, or a tert-butoxy group, and particularly preferably a methoxy group or an ethoxy group.

The acyloxy group as a substituent represented by Ra^{x02} is preferably an acyloxy group having 2 to 6 carbon atoms, more preferably CH₃C(═O)—O— (acetoxy group) or C₂H₅C(═O)—O—, and particularly preferably CH₃C(═O)—O— (acetoxy group).

In Formula (a1-1), nₐₓ₂ represents an integer of 0 to 3, preferably 0, 1, or 2, and more preferably 0 or 1.

In a case where nₐₓ₂ represents 2 or greater, a plurality of Ra^{x02}'s may be bonded to each other to form a ring structure. The ring structure formed here may be a hydrocarbon ring or a heterocyclic ring. Examples of the ring structure include a ring structure formed by two Ra^{x02}'s bonded to the same aromatic ring as Wa^{x2} and one side (bond between carbon atoms) of this aromatic ring (Wa^{x2}) to which the two Ra^{x02}'s are bonded.

Suitable examples of such a constitutional unit (a11) include constitutional units each represented by General Formulae (a1-u1-1) to (a11-u1-6).

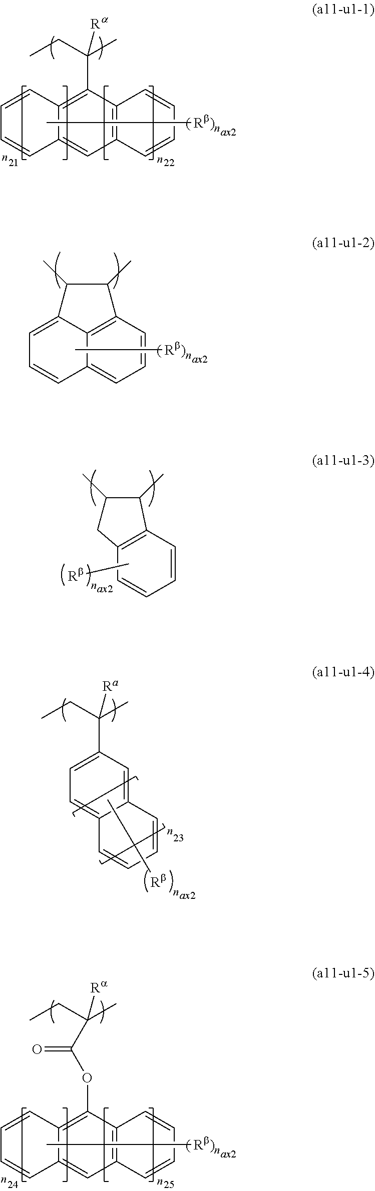

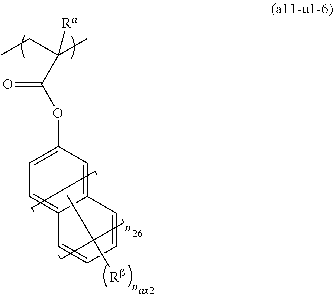

[In the formula, R^{α} represents a hydrogen atom, a methyl group, or a trifluoromethyl group. RP represents an alkyl group, an alkoxy group, or an acyloxy group. nₐₓ₂ represents an integer of 0 to 3. In a case where nₐₓ₂ represents 2 or greater, a plurality of R^{β}'s may be bonded to each other to form a ring structure. n₂₁, n₂₂, n₂₄, and n₂₅ each independently represent 0 or 1. n₂₃ and n₂₆ each independently represent 1 or 2.]

In Formulae (a1-u1-1) to (a1-u1-6), the alkyl group, the alkoxy group, and the acyloxy group as R^{β} each have the same definition as that for the alkyl group, the alkoxy group, and the acyloxy group, described as the substituents represented by Ra^{x02} in Formula (a11-1).

Specific examples of the constitutional unit (the constitutional unit (a11)) derived from the compound represented by General Formula (a1-1) are shown below.

In the formulae shown below, R^{α} represents a hydrogen atom, a methyl group, or a trifluoromethyl group.

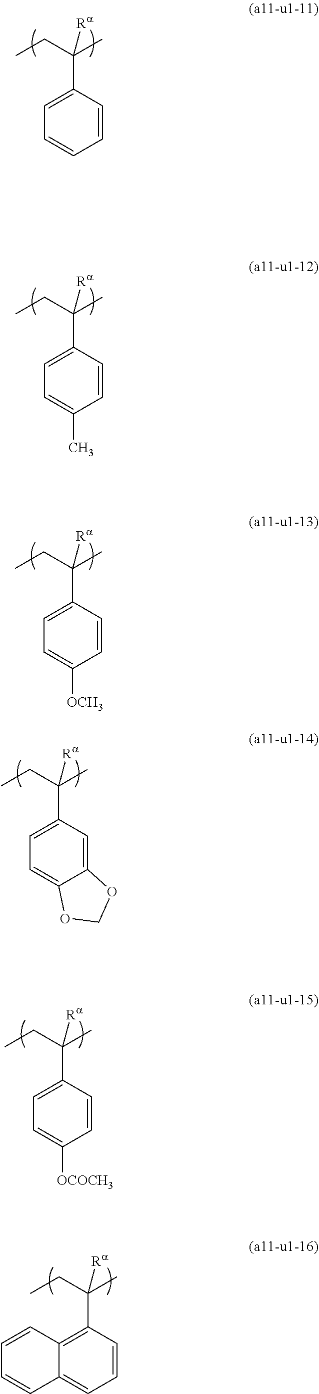

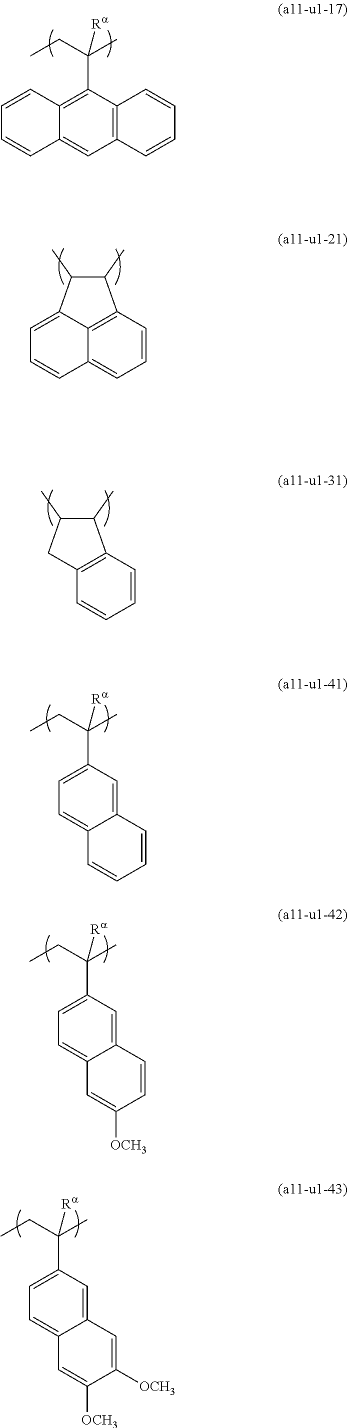

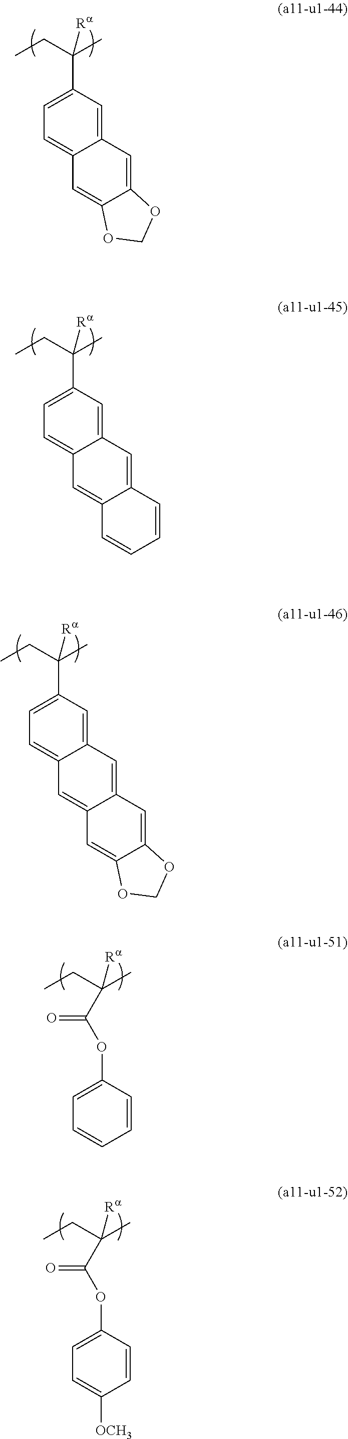

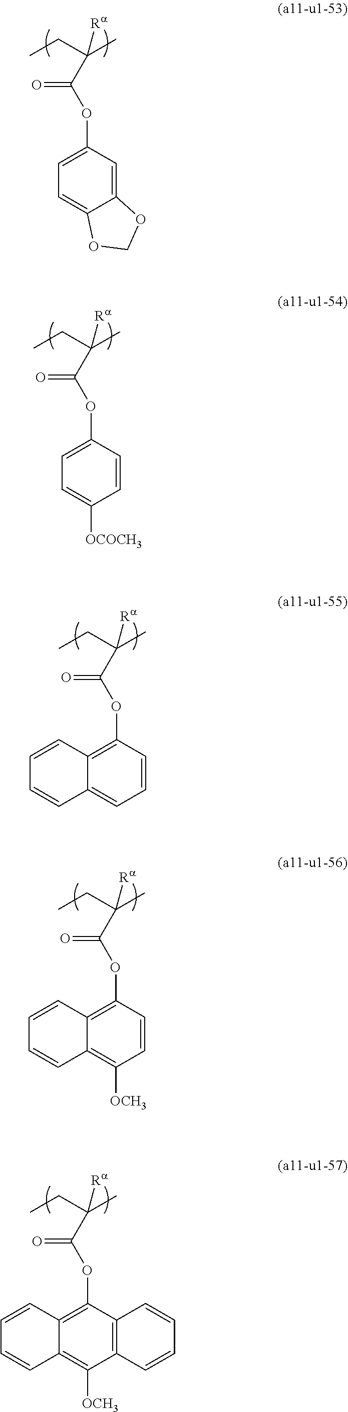

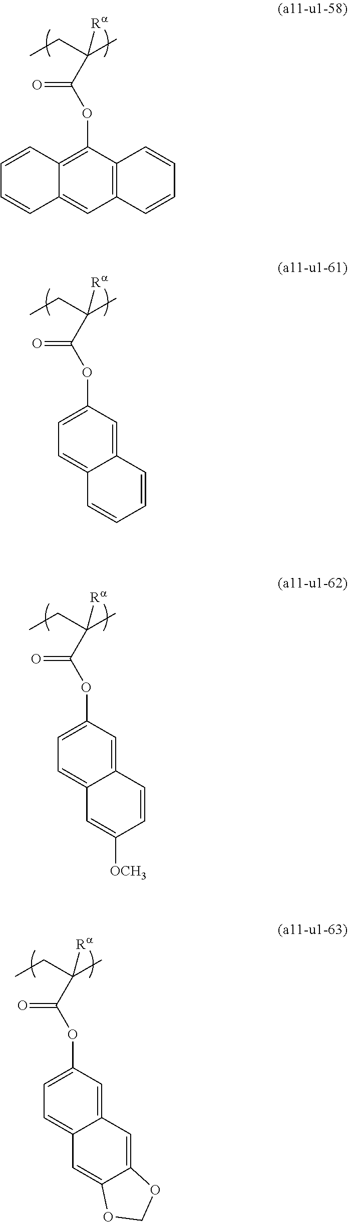

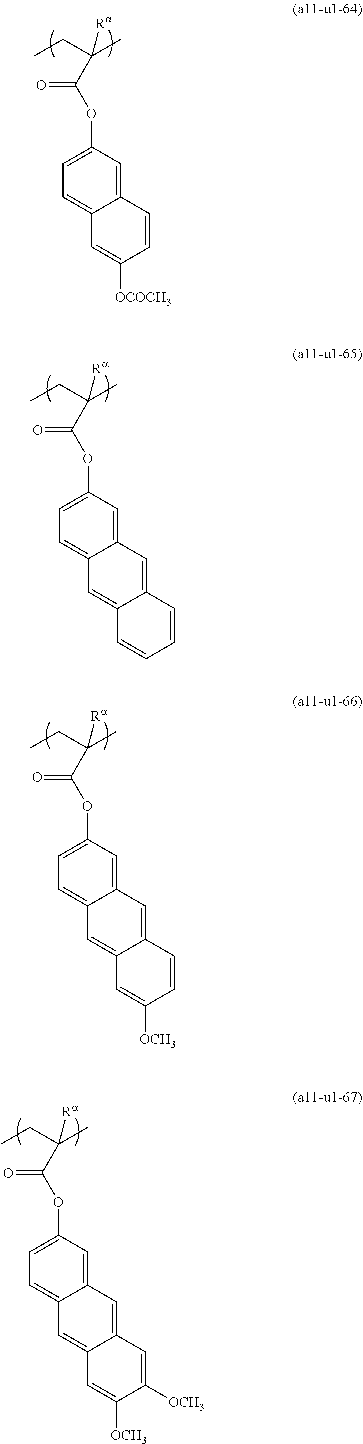

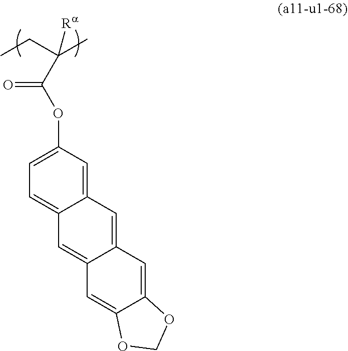

Among the examples, the constitutional unit (a11) is preferably at least one selected from the group consisting of constitutional units each represented by General Formulae (a11-u1-1) to (a1-u1-3) and more preferably a constitutional unit represented by General Formula (a11-u1-1).

Among these, the constitutional unit (a11) is preferably a constitutional unit represented by any of Chemical Formula (a11-u1-11), (a11-u1-21), or (a11-u1-31).

The constitutional unit (a11) of the component (A1) may be used alone or two or more kinds thereof.

In a case where the component (A1) has the constitutional unit (a1), the proportion of the constitutional unit (a11) in the component (A1) is preferably in a range of 1% to 50% by mole, more preferably in a range of 1% to 40% by mole, still more preferably in a range of 1% to 35% by mole, and particularly preferably in a range of 1 to 30% by mole with respect to the total amount (100% by mole) of all constitutional units constituting the component (A1).

In a case where the proportion of the constitutional unit (a11) is set to be greater than or equal to the above-described lower limits, etching resistance and lithography characteristics are further improved. Meanwhile, in a case where the proportion thereof is set to be less than or equal to the above-described upper limits, the constitutional unit (a1) and other constitutional units are likely to be balanced.

### <<Other Constitutional Units>>

The component (A1) may have other constitutional units (hereinafter, also referred to as “constitutional unit (a12)”) in addition to the constitutional unit (a0) and the constitutional unit (a11).

Examples of compounds from which the constitutional unit (a2) is derived include monocarboxylic acids such as acrylic acid, methacrylic acid, and crotonic acid; dicarboxylic acids such as maleic acid, fumaric acid, and itaconic acid; methacrylic acid derivatives having a carboxy group and an ester bond, such as 2-methacryloyloxyethyl succinic acid, 2-methacryloyloxyethyl maleic acid, 2-methacryloyloxyethyl phthalic acid, and 2-methacryloxyethyl hexahydrophthalic acid; (meth)acrylic acid alkyl esters such as methyl (meth)acrylate, ethyl (meth)acrylate, butyl (meth)acrylate, cyclopentyl (meth)acrylate, cyclohexyl (meth)acrylate, adamantyl (meth)acrylate, norbornyl (meth)acrylate, isobornyl (meth)acrylate, tricyclodecyl (meth)acrylate, and tetracyclododecyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aliphatic compounds such as vinyl acetate; conjugate diolefins such as butadiene and isoprene; nitrile group-containing polymerizable compounds such as acrylonitrile and methacrylonitrile; chlorine-containing polymerizable compounds such as vinyl chloride and vinylidene chloride; amide bond-containing polymerizable compounds such as acrylamide and methacrylamide; and epoxy group-containing polymerizable compounds.

Among those, a constitutional unit represented by General Formula (a2-1) is preferable as the constitutional unit (a2).

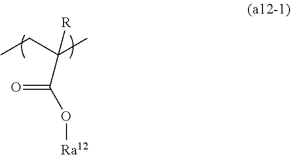

[In the formula, R represents a hydrogen atom, an alkyl group having 1 to 5 carbon atoms, or a halogenated alkyl group having 1 to 5 carbon atoms. Ra¹² represents an alkyl group.]

In Formula (a12-1), R represents a hydrogen atom, an alkyl group having 1 to 5 carbon atoms, or a halogenated alkyl group having 1 to 5 carbon atoms.

R represents preferably a hydrogen atom, an alkyl group having 1 to 5 carbon atoms, or a fluorinated alkyl group having 1 to 5 carbon atoms, and from the viewpoint of industrial availability, more preferably a hydrogen atom, a methyl group, or trifluoromethyl group, still more preferably a hydrogen atom or a methyl group, and particularly preferably a hydrogen atom.

In Formula (a2-1), examples of the alkyl group as Ra¹² include a linear or branched alkyl group and a cyclic alkyl group.

As the linear or branched alkyl group, a linear or branched alkyl group having 1 to 5 carbon atoms is preferable, and a methyl group, an ethyl group, or a butyl group is more preferable.

As the cyclic alkyl group, a cyclopentyl group, a cyclohexyl group, an adamantyl group, a norbornyl group, an isobornyl group, a tricyclodecyl group, or a tetracyclododecyl group is preferable, and a cyclohexyl group or an adamantyl group is more preferable.

The component (A1) may have one or two or more kinds of the constitutional units (a12).

In a case where the component (A1) has the constitutional unit (a12), the proportion of the constitutional unit (a12) in the component (A1) is preferably in a range of 1% to 50% by mole, more preferably in a range of 1% to 40% by mole, still more preferably in a range of 1% to 35% by mole, and particularly preferably in a range of 1% to 30% by mole with respect to the total amount (100% by mole) of all constitutional units constituting the component (A1).

In a case where the proportion of the constitutional unit (a2) is set to be greater than or equal to the above-described lower limits, etching resistance and lithography characteristics are further improved. Meanwhile, in a case where the proportion thereof is set to be less than or equal to the above-described upper limits, the constitutional unit (a12) and other constitutional units are likely to be balanced.

In the resist composition according to the present embodiment, the component (A) contains the polymer compound (A1) (the component (A1)) having the constitutional unit (a10).

Preferred examples of the component (A1) include a polymer compound having at least the constitutional unit (a10). Specific suitable examples thereof include a polymer compound (homopolymer consisting of the constitutional unit (a10)) having a repeating structure of the constitutional unit (a10); a polymer compound having a repeating structure of the constitutional unit (a10) and the constitutional unit (a11); and a polymer compound having a repeating structure of the constitutional unit (a10) and the constitutional unit (a12).

The proportion of the constitutional unit (a10) in the polymer compound having a repeating unit of the constitutional unit (a10) and the constitutional unit (a11) is preferably in a range of 50% to 99% by mole, more preferably in a range of 60% to 99% by mole, and still more preferably in a range of 70% to 99% by mole with respect to the total amount (100% by mole) of all constitutional units constituting the polymer compound.

Further, the proportion of the constitutional unit (a11) in the polymer compound is preferably in a range of 1% to 50% by mole, more preferably in a range of 1% to 40% by mole, and still more preferably in a range of 1% to 30% by mole with respect to the total amount (100% by mole) of all constitutional units constituting the polymer compound.

The proportion of the constitutional unit (a10) in the polymer compound having a repeating unit of the constitutional unit (a10) and the constitutional unit (a12) is preferably in a range of 50% to 99% by mole, more preferably in a range of 60% to 99% by mole, and still more preferably in a range of 70% to 99% by mole with respect to the total amount (100% by mole) of all constitutional units constituting the polymer compound.

Further, the proportion of the constitutional unit (a12) in the polymer compound is preferably in a range of 1% to 50% by mole, more preferably in a range of 1% to 40% by mole, and still more preferably in a range of 1% to 30% by mole with respect to the total amount (100% by mole) of all constitutional units constituting the polymer compound.

The weight-average molecular weight (Mw) (in terms of polystyrene according to gel permeation chromatography (GPC)) of the component (A1) is not particularly limited, but is preferably in a range of 500 to 50,000, more preferably in a range of 1,000 to 30,000, and still more preferably in a range of 1.000 to 20,000.

In a case where Mw of the component (A1) is less than or equal to the upper limits of the above-described preferable ranges, the sufficient solubility in the resist solvent is exhibited in a case of using the composition as a resist. Meanwhile, in a case where Mw thereof is greater than or equal to the lower limits of the above-described preferable ranges, the dry etching resistance and the cross-sectional shape of the resist pattern are further enhanced.

The dispersity (Mw/Mn) of the component (A1) is not particularly limited, but is preferably in a range of 1.0 to 4.0, more preferably in a range of 1.0 to 3.0, and particularly preferably in a range of 1.0 to 2.5. In addition, Mn denotes the number average molecular weight.

Such a component (A1) can be produced by dissolving a monomer, from which each constitutional unit is derived, in a polymerization solvent and adding a radical polymerization initiator such as azobisisobutylonitrile (AIBN) or dimethyl azobisisobutyrate (for example, V-601) to the solution so that the polymerization is carried out.

Alternatively, the component (A1) can be produced by dissolving, in a polymerization solvent, a monomer from which the constitutional unit (a10) is derived and, as necessary, a monomer from which a constitutional unit other than the constitutional unit (a10) is derived, adding thereto a radical polymerization initiator such as described above to carry out polymerization, and then carrying out a deprotection reaction.

Further, a —C(CF₃)₂—OH group may be introduced to the terminal during the polymerization using a combination of chain transfer agents such as HS—CH₂—CH₂—CH₂—C(CF₃)₂—OH. As described above, a copolymer into which a hydroxyalkyl group, formed by substitution of some hydrogen atoms in the alkyl group with fluorine atoms, has been introduced is effective for reducing development defects and reducing line edge roughness (LER: uneven irregularities of a line side wall).

In addition, the component (A1) can be produced according to an anionic polymerization method by using, as a polymerization initiator, an organic alkali metal such as n-butyl lithium, s-butyl lithium, t-butyl lithium, ethyl lithium, ethyl sodium, 1,1-diphenylhexyl lithium, or 1,1-diphenyl-3-methylpentyl lithium.

### In Regard to Component (A2)

In the resist composition of the present embodiment, a base material component (hereinafter, also referred to as “component (A2)”) which does not correspond to the component (A1) and whose solubility in a developing solution is changed due to the action of an acid may be used in combination as the component (A).

The component (A2) is not particularly limited and may be optionally selected from a plurality of components of the related art which have been known as base material components for a chemically amplified resist composition and used.

As the component (A2), a polymer compound or a low-molecular-weight compound may be used alone or in combination of two or more kinds thereof.

The proportion of the component (A1) in the component (A) is preferably 25% by mass or greater, more preferably 50% by mass or greater, and still more preferably 75% by mass or greater, and may be 100% by mass with respect to the total mass of the component (A). In a case where the proportion thereof is 25% by mass or greater, a resist pattern having excellent various lithography characteristics such as high sensitivity, high resolution, and improved roughness is likely to be formed.

In the resist composition of the present embodiment, the content of the component (A) may be adjusted according to the thickness of the resist film intended to be formed.

### <<Onium-Based Acid Generator (B1)>>>

The component (B1) is not particularly limited, and those which have been suggested as an acid generator for a chemically amplified resist composition in the related art can be used.

Examples of the onium salt-based acid generators include a compound represented by General Formula (b-1) (hereinafter, also referred to as “component (b-1)”), a compound represented by General Formula (b-2) (hereinafter, also referred to as “component (b-2)”), and a compound represented by General Formula (b-3) (hereinafter, also referred to as “component (b-3)”).

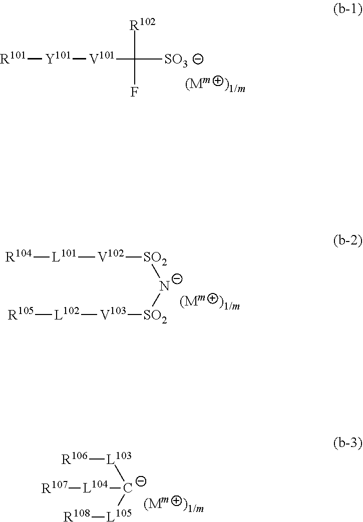

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group having an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰¹ to L¹⁰⁵ each independently represent a single bond, —CO—, or —SO₂—. m represents an integer of 1 or greater, and M^{m+} represents an m-valent onium cation.]

### {Anion Moiety}

Anions in Component (b-1)

In Formula (b-1), R¹⁰¹ represents a cyclic group which may have a substituent, a chain-like alkyl group which may have a substituent, or a chain-like alkenyl group which may have a substituent.

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group denotes a hydrocarbon group that has no aromaticity. Further, the aliphatic hydrocarbon group may be saturated or unsaturated. In general, it is preferable that the aliphatic hydrocarbon group is saturated.

The aromatic hydrocarbon group as R¹⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring of the aromatic hydrocarbon group as R¹⁰¹ include benzene, fluorene, naphthalene, anthracene, phenanthrene, biphenyl, and an aromatic heterocyclic ring in which some carbon atoms constituting any of these aromatic rings have been substituted with heteroatoms. Examples of the heteroatom in the aromatic heterocyclic rings include an oxygen atom, a sulfur atom, and a nitrogen atom.

Specific examples of the aromatic hydrocarbon group as R¹⁰¹ include a group in which one hydrogen atom has been removed from the aromatic ring (an aryl group such as a phenyl group or a naphthyl group) and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R¹⁰¹ include an aliphatic hydrocarbon group having a ring in the structure thereof.

Examples of the aliphatic hydrocarbon group having a ring in the structure thereof include an alicyclic hydrocarbon group (a group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in the middle of a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among these, a polycycloalkane having a crosslinked ring polycyclic skeleton such as adamantane, norbornane, isobornane, tricyclodecane, or tetracyclododecane; and a polycycloalkane having a condensed ring polycyclic skeleton such as a cyclic group having a steroid skeleton are preferable as the polycycloalkane.

Among these examples, as the cyclic aliphatic hydrocarbon group as R¹⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is still more preferable, and an adamantyl group is particularly preferable.

The linear aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group has preferably 2 to 10 carbon atoms, more preferably 3 to 6 carbon atoms, still more preferably 3 or 4 carbon atoms, and most preferably 3 carbon atoms. As the branched aliphatic hydrocarbon group, a branched alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Further, the cyclic hydrocarbon group as R¹⁰1 may have a heteroatom such as a heterocyclic ring. Specific examples thereof include lactone-containing cyclic groups each represented by General Formulae (b2-r-1) to (b2-r-7), —SO₂-containing cyclic groups each represented by General Formulae (b5-r-1) to (b5-r-4), and other heterocyclic groups each represented by Chemical Formulae (r-hr-1) to (r-hr-16). Here, in Chemical Formulae (r-hr-1) to (r-hr-16). * represents a bonding site with respect to Y¹⁰¹ in Formula (b-1).

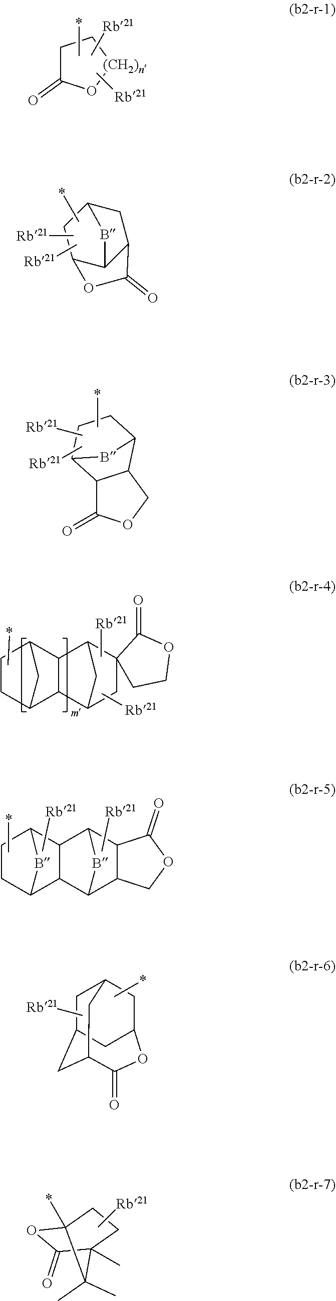

[In the formulae, Rb^{x21}'s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group, R″ represents a hydrogen atom, an alkyl group, or a lactone-containing cyclic group, B″ represents an alkylene group having 1 to 5 carbon atoms which may have an oxygen atom (—O—) or a sulfur atom (—S—), an oxygen atom, or a sulfur atom, n′ represents an integer of 0 to 2, and m′ represents 0 or 1. * represents a bonding site.]

In General Formulae (b2-r-1) to (b2-r-7), an alkyl group having 1 to 6 carbon atoms is preferable as the alkyl group represented by Rb′²¹. Further, it is preferable that the alkyl group is linear or branched. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

An alkoxy group having 1 to 6 carbon atoms is preferable as the alkoxy group represented by Rb′²¹. Further, it is preferable that the alkoxy group is linear or branched. Specific examples of the alkoxy groups include a group formed by linking the alkyl group described above as the alkyl group represented by Rb′²¹ to an oxygen atom (—O—).

As the halogen atom represented by Rb′²¹, a fluorine atom is preferable.

Examples of the halogenated alkyl group as Rb′²¹ include groups in which some or all hydrogen atoms in the alkyl group as Ra′²¹ have been substituted with the halogen atoms. As the halogenated alkyl group, a fluorinated alkyl group is preferable, and a perfluoroalkyl group is particularly preferable.

In both —COOR″ and —OC(═O)R″ as Rb′²¹, R″ represents a hydrogen atom, an alkyl group, or a lactone-containing cyclic group.

The alkyl group as R″ may be linear, branched, or cyclic and has preferably 1 to 15 carbon atoms.

In a case where R″ represents a linear or branched alkyl group, an alkyl group having 1 to 10 carbon atoms is preferable, an alkyl group having 1 to 5 carbon atoms is more preferable, and a methyl group or an ethyl group is particularly preferable.

In a case where R″ represents a cyclic alkyl group, the number of carbon atoms thereof is preferably in a range of 3 to 15, more preferably in a range of 4 to 12, and most preferably in a range of 5 to 10. Specific examples thereof include groups in which one or more hydrogen atoms have been removed from a monocycloalkane, which may or may not be substituted with a fluorine atom or a fluorinated alkyl group; and groups in which one or more hydrogen atoms have been removed from a polycycloalkane such as bicycloalkane, tricycloalkane, or tetracycloalkane. More specific examples thereof include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane, or tetracyclododecane.

Examples of the lactone-containing cyclic group as R″ include the same groups as those for the groups each represented by General Formulae (b2-r-1) to (b2-r-7).

As the hydroxyalkyl group represented by Rb′²¹, a hydroxyalkyl group having 1 to 6 carbon atoms is preferable, and specific examples thereof include a group in which at least one hydrogen atom in the alkyl group as Rb′²¹ has been substituted with a hydroxyl group.

Among the examples, it is preferable that Rb′²¹'s each independently represent a hydrogen atom or a cyano group.

In General Formulae (b2-r-2), (b2-r-3), and (b2-r-5), as the alkylene group having 1 to 5 carbon atoms as B″, a linear or branched alkylene group is preferable, and examples thereof include a methylene group, an ethylene group, an n-propylene group, and an isopropylene group. In a case where the alkylene group has an oxygen atom or a sulfur atom, specific examples thereof include groups in which —O— or —S— is interposed in the terminal of the alkylene group or between the carbon atoms of the alkylene group. Further, examples thereof include —O—CH₂—, —CH₂—O—CH₂—, —S—CH₂—, and —CH₂—S—CH₂—. B″ represents preferably an alkylene group having 1 to 5 carbon atoms or —O—, more preferably an alkylene group having 1 to 5 carbon atoms, and most preferably a methylene group.

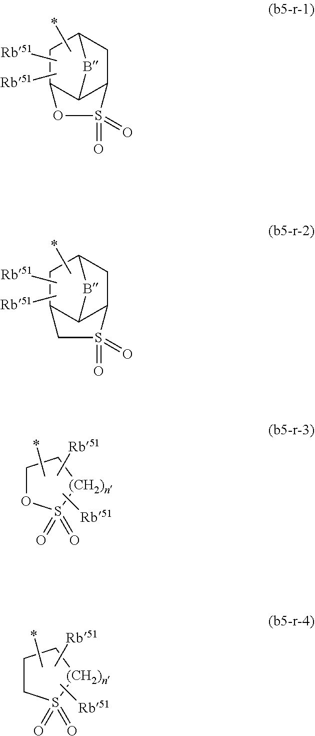

[In the formulae, Rb′⁵¹'s each independently represent a hydrogen atom, an alkyl group, an alkoxy group, a halogen atom, a halogenated alkyl group, a hydroxyl group, —COOR″, —OC(═O)R″, a hydroxyalkyl group, or a cyano group, R″ represents a hydrogen atom, an alkyl group, a lactone-containing cyclic group, or a —SO₂-containing cyclic group, B″ represents an alkylene group having 1 to 5 carbon atoms which may have an oxygen atom or a sulfur atom, an oxygen atom, or a sulfur atom, and n′ represents an integer of 0 to 2. * represents a bonding site.]

In General Formulae (b5-r-1) and (b5-r-2), B″ represents an alkylene group having 1 to 5 carbon atoms which may have an oxygen atom or a sulfur atom, an oxygen atom, or a sulfur atom.

B″ represents preferably an alkylene group having 1 to 5 carbon atoms or —O—, more preferably an alkylene group having 1 to 5 carbon atoms, and still more preferably a methylene group.

In General Formulae (b5-r-1) to (b5-r-4), Rb′⁵¹'s each independently represent a hydrogen atom, an alkyl group, an alkoxy group, a halogen atom, a halogenated alkyl group, a hydroxyl group. —COOR″, —OC(═O)R″, a hydroxyalkyl group, or a cyano group. Among these, it is preferable that Rb′⁵¹'s each independently represent a hydrogen atom or a cyano group.

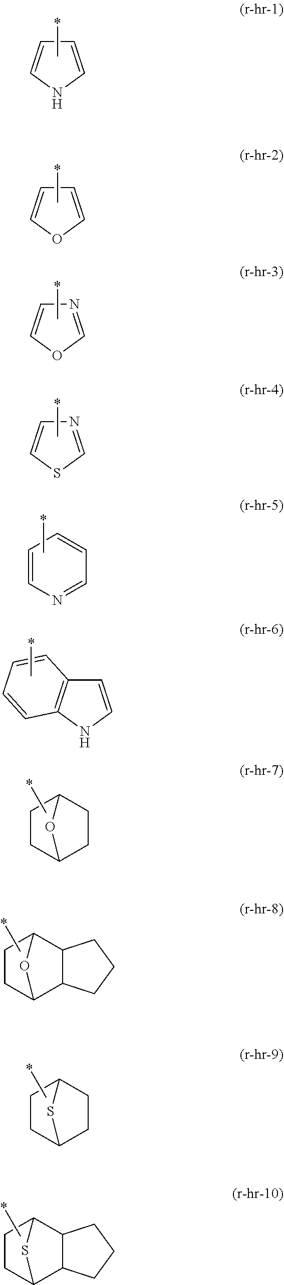

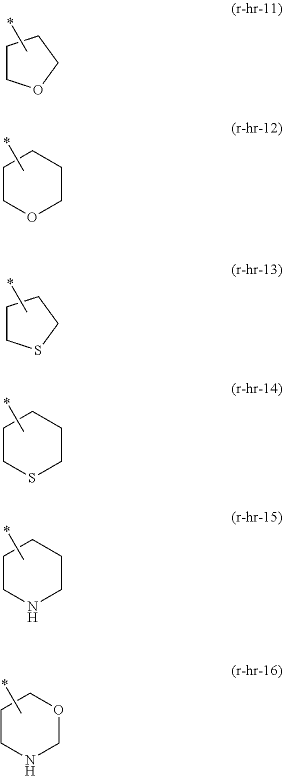

Examples of the substituent for the cyclic group as R¹⁰¹ include an alkyl group, an alkoxy group, a halogen atom, a halogenated alkyl group, a hydroxyl group, a carbonyl group, and a nitro group.

As the alkyl group as the substituent, an alkyl group having 1 to 5 carbon atoms is preferable, and a methyl group, an ethyl group, a propyl group, an n-butyl group, or a tert-butyl group is most preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is most preferable.

Examples of the halogen atom as the substituent include a fluorine atom, a chlorine atom, a bromine atom, and an iodine atom. Among these, a fluorine atom is preferable.

Example of the above-described halogenated alkyl group as the substituent include a group in which some or all hydrogen atoms in an alkyl group having 1 to 5 carbon atoms such as a methyl group, an ethyl group, a propyl group, an n-butyl group, or a tert-butyl group have been substituted with the above-described halogen atoms.

The carbonyl group as the substituent is a group that substitutes a methylene group (—CH₂—) constituting the cyclic hydrocarbon group.

The cyclic hydrocarbon group as R¹⁰¹ may be a condensed cyclic group having a condensed ring in which an aliphatic hydrocarbon ring and an aromatic ring are condensed. Examples of the condensed ring include those obtained by fusing one or more aromatic rings with a polycycloalkane having a crosslinked ring-based polycyclic skeleton. Specific examples of the crosslinked ring-based polycycloalkane include a bicycloalkane such as bicyclo[2.2.1]heptane (norbornane) and bicyclo[2.2.2]octane. As the condensed cyclic group, a group having a condensed ring in which two or three aromatic rings are condensed with a bicycloalkane is preferable, and a group having a condensed ring in which two or three aromatic rings are condensed with bicyclo[2.2.2]octane is more preferable. Specific examples of the condensed cyclic group as R¹⁰¹ include those represented by Formulae (r-br-1) and (r-br-2). In the formulae, * represents a bonding site with respect to Y¹⁰¹ in Formula (b-1).

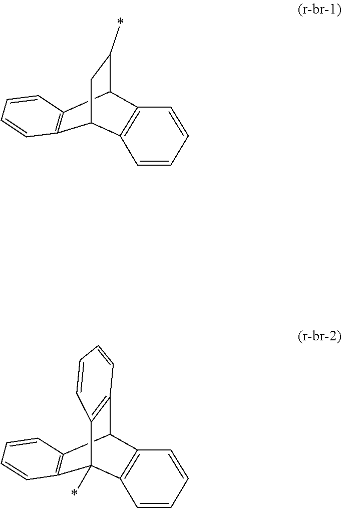 [SMILES: *C1C[C@H]2c3ccccc3[C@@H]1c1ccccc12 ; *C12c3ccccc3C(c3ccccc31)c1ccccc12]

Examples of the substituent that the condensed cyclic group as R¹⁰¹ may have include an alkyl group, an alkoxy group, a halogen atom, a halogenated alkyl group, a hydroxyl group, a carbonyl group, a nitro group, an aromatic hydrocarbon group, and an alicyclic hydrocarbon group.

Examples of the alkyl group, the alkoxy group, the halogen atom, and the halogenated alkyl group as the substituent of the condensed cyclic group include those described as the substituent of the cyclic group as R¹⁰¹.

Examples of the aromatic hydrocarbon group as the substituent of the condensed cyclic group include a group in which one hydrogen atom has been removed from the aromatic ring (an aryl group such as a phenyl group or a naphthyl group), a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group), and a heterocyclic group represented by any of Formulae (r-hr-1) to (r-hr-6).

Examples of the alicyclic hydrocarbon group as the substituent of the condensed cyclic group include a group in which one hydrogen atom has been removed from a monocycloalkane such as cyclopentane or cyclohexane, a group in which one hydrogen atom has been removed from a polycycloalkane such as adamantane, norbornane, isobornane, tricyclodecane, or tetracyclododecane, a lactone-containing cyclic group represented by any of General Formulae (b2-r-1) to (b2-r-7), a —SO₂-containing cyclic group represented by any of General Formulae (b5-r-1) to (b5-r-4), and a heterocyclic group represented by any of Formulae (r-hr-7) to (r-hr-16).

Chain-Like Alkyl Group which May have Substituent:

The chain-like alkyl group as R¹⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group as R¹⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

Examples of the substituent for the chain-like alkyl group or alkenyl group as R¹⁰¹ include an alkoxy group, a halogen atom, a halogenated alkyl group, a hydroxyl group, a carbonyl group, a nitro group, an amino group, and a cyclic group as R¹⁰¹.

Among the examples, R¹⁰¹ represents preferably a cyclic group which may have a substituent and more preferably a cyclic hydrocarbon group which may have a substituent. More specifically, as the cyclic hydrocarbon group, a phenyl group, a naphthyl group, or a group in which one or more hydrogen atoms have been removed from a polycycloalkane, a lactone-containing cyclic group represented by any of General Formulae (b2-r-1) to (b2-r-7, or a —SO₂-containing cyclic group represented by any of General Formulae (b5-r-1) to (b5-r-4) is preferable, a group in which one or more hydrogen atoms have been removed from a polycycloalkane or a —SO₂-containing cyclic group represented by any of General Formulae (b5-r-1) to (b5-r-4) is more preferable, and an adamantyl group or a —SO₂-containing cyclic group represented by General Formula (b5-r-1) is still more preferable.

In a case where the cyclic hydrocarbon group has a substituent, it is preferable that the substituent is a hydroxyl group.

In Formula (b-1), Y¹⁰¹ represents a single bond or a divalent linking group having an oxygen atom.

In a case where Y¹⁰¹ represents a divalent linking group containing an oxygen atom, Y¹⁰¹ may contain an atom other than the oxygen atom. Examples of atoms other than an oxygen atom include a carbon atom, a hydrogen atom, a sulfur atom, and a nitrogen atom.

Examples of the divalent linking group having an oxygen atom include a non-hydrocarbon oxygen atom-containing linking group such as an oxygen atom (an ether bond: —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon oxygen atom-containing linking groups with an alkylene group. Further, a sulfonyl group (—SO₂—) may be further linked to the combination. Examples of the divalent linking group having an oxygen atom include linking groups each represented by General Formulae (y-a1-1) to (y-a1-7). Further, in General Formulae (y-a1-1) to (y-a1-7), V′¹⁰¹ in General Formulae (y-a1-1) to (y-a1-7) is bonded to R¹⁰¹ in Formula (b-1).

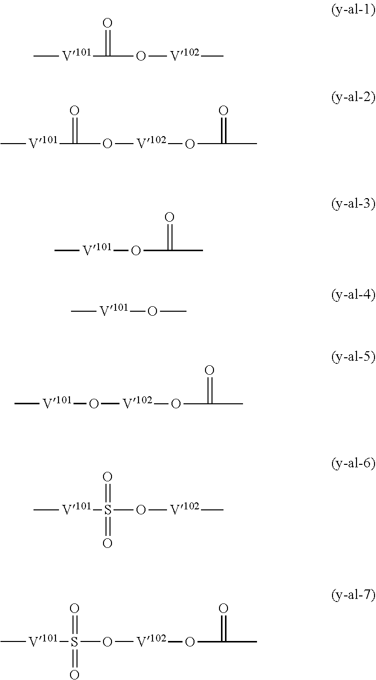

[In the formulae, V′¹⁰¹ represents a single bond or an alkylene group having 1 to 5 carbon atoms, and V′¹⁰² represents a divalent saturated hydrocarbon group having 1 to 30 carbon atoms.]

As the divalent saturated hydrocarbon group as V′¹⁰², an alkylene group having 1 to 30 carbon atoms is preferable, an alkylene group having 1 to 10 carbon atoms is more preferable, and an alkylene group having 1 to 5 carbon atoms is still more preferable.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, some of the methylene groups in the alkylene groups as V′¹⁰¹ and V′¹⁰² may be substituted with a divalent aliphatic cyclic group having 5 to 10 carbon atoms. As the aliphatic cyclic group, a divalent group in which one hydrogen atom has been further removed from the cyclic aliphatic hydrocarbon group (a monocyclic aliphatic hydrocarbon group or a polycyclic aliphatic hydrocarbon group) as Ra′³ in Formula (a1-r-1) is preferable, and a cyclohexylene group, a 1,5-adamantylene group, or a 2,6-adamantylene group is more preferable.

Y¹⁰¹ represents preferably a divalent linking group having an ester bond or a divalent linking group having an ether bond and more preferably a linking group represented by any of Formulae (y-a1-1) to (y-a1-5).

In Formula (b-1). V¹⁰¹ represents a single bond, an alkylene group, or a fluorinated alkylene group. It is preferable that the alkylene group and the fluorinated alkylene group as V¹⁰¹ have 1 to 4 carbon atoms. Examples of the fluorinated alkylene group as V¹⁰¹ include a group in which some or all hydrogen atoms in the alkylene group as V¹⁰¹ have been substituted with fluorine atoms. Among these examples, it is preferable that V¹⁰¹ represents a single bond or a fluorinated alkylene group having 1 to 4 carbon atoms.

In Formula (b-1). R¹⁰2 represents a fluorine atom or a fluorinated alkyl group having 1 to 5 carbon atoms. R¹⁰ represents preferably a fluorine atom or a perfluoroalkyl group having 1 to 5 carbon atoms and more preferably a fluorine atom.

In a case where Y¹⁰¹ represents a single bond, specific example of the anion moiety represented by Formula (b-1) include a fluorinated alkylsulfonate anion such as a trifluoromethanesulfonate anion or a perfluorobutanesulfonate anion. Further, in a case where Y¹⁰¹ represents a divalent linking group having an oxygen atom, specific examples thereof include an anion represented by any of Formulae (an-1) to (an-4).

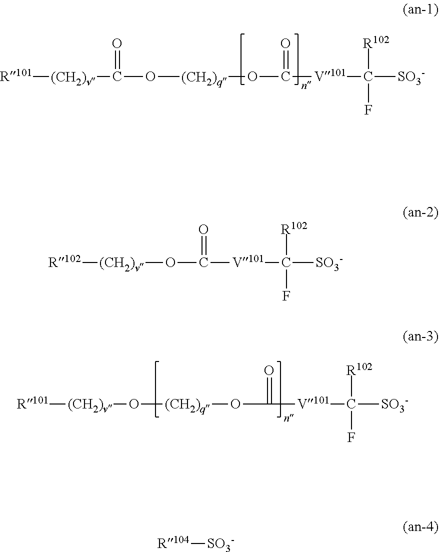

[In the formulae, R″¹⁰¹ represents an aliphatic cyclic group which may have a substituent, a monovalent heterocyclic group represented by any of Chemical Formulae (r-hr-1) to (r-hr-6), a condensed cyclic group represented by Formula (r-br-1) or (r-br-2), or a chain-like alkyl group which may have a substituent. R″¹⁰² represents an aliphatic cyclic group which may have a substituent, a condensed cyclic group represented by Formula (r-br-1) or (r-br-2), a lactone-containing cyclic group represented by any of General Formulae (a2-r-1) and (a2-r-3) to (a2-r-7), or a —SO₂-containing cyclic group represented by any of General Formulae (b5-r-1) to (b5-r-4). R″¹⁰³ represents an aromatic cyclic group which may have a substituent, an aliphatic cyclic group which may have a substituent, or a chain-like alkenyl group which may have a substituent. V″¹⁰¹ represents a single bond, an alkylene group having 1 to 4 carbon atoms, or a fluorinated alkylene group having 1 to 4 carbon atoms. R¹⁰² represents a fluorine atom or a fluorinated alkyl group having 1 to 5 carbon atoms. Each v″ independently represents an integer of 0 to 3, each q″ independently represents an integer of 0 to 20, and n″ represents 0 or 1. R″¹⁰⁴ represents a fluorinated alkyl group.]

As the aliphatic cyclic group as R″¹⁰¹, R″¹⁰², and R″¹⁰³ which may have a substituent, the same groups as those for the cyclic aliphatic hydrocarbon group as R¹⁰¹ in Formula (b-1) are preferable. Examples of the substituent include the same groups as those for the substituent which may substitute the cyclic aliphatic hydrocarbon group as R¹⁰¹ in Formula (b-1).

As the aromatic cyclic group as R″¹⁰³ which may have a substituent, the same groups as those for the aromatic hydrocarbon group in the cyclic hydrocarbon group as R¹⁰¹ in Formula (b-1) are preferable. Examples of the substituent include the same groups as those for the substituent which may substitute the aromatic hydrocarbon group as R¹⁰¹ in Formula (b-1).

As the chain-like alkyl group as R″¹⁰¹ which may have a substituent, the same groups as those for the chain-like alkyl group as R¹⁰¹ in Formula (b-1) are preferable.

As the chain-like alkenyl group as R″¹⁰³ which may have a substituent, the same groups as those for the chain-like alkenyl group as R¹⁰¹ in Formula (b-1) are preferable.

As the fluorinated alkyl group as R″¹⁰⁴, a linear or branched fluorinated alkyl group having 1 to 5 carbon atoms is preferable, a linear or branched perfluoroalkyl group having 1 to 5 carbon atoms is more preferable, and a nonafluorobutyl group is still more preferable.

Anions in Component (b-2)

In Formula (b-2), R¹⁰⁴ and R¹⁰⁵ each independently represent a cyclic group which may have a substituent, a chain-like alkyl group which may have a substituent, or a chain-like alkenyl group which may have a substituent, and examples thereof include the same groups as those for R¹⁰¹ in Formula (b-1). Here, R¹⁰⁴ and R¹⁰⁵ may be bonded to each other to form a ring.

R¹⁰⁴ and R¹⁰⁵ represent preferably a chain-like alkyl group which may have a substituent and more preferably a linear or branched alkyl group or a linear or branched fluorinated alkyl group.

The chain-like alkyl group has preferably 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ decreases within the range of the number of carbon atoms from the viewpoint that the solubility in a solvent for a resist is also satisfactory. Further, in the chain-like alkyl group as R¹⁰⁴ and R¹⁰⁵, it is preferable that the number of hydrogen atoms substituted with fluorine atoms is as large as possible from the viewpoint that the acid strength increases and the transparency to high energy light or electron beams having a wavelength of 250 nm or less is improved. The proportion of fluorine atoms in the chain-like alkyl group, that is, the fluorination ratio is preferably in a range of 70% to 100% and more preferably in a range of 90% to 100%, and it is most preferable that the chain-like alkyl group is a perfluoroalkyl group in which all hydrogen atoms are substituted with fluorine atoms.

In Formula (b-2), V¹⁰² and V¹⁰³ each independently represent a single bond, an alkylene group, or a fluorinated alkylene group, and examples thereof include the same groups as those for V¹⁰¹ in Formula (b-1).

In Formula (b-2). L¹⁰¹ and L¹⁰² each independently represent a single bond or an oxygen atom.

Anions in Component (b-3)

In Formula (b-3), R¹⁰⁶ to R¹⁰⁸ each independently represent a cyclic group which may have a substituent, a chain-like alkyl group which may have a substituent, or a chain-like alkenyl group which may have a substituent, and examples thereof include the same groups as those for R¹⁰¹ in Formula (b-1).

In Formula (b-3). L¹⁰³ to L¹⁰⁵ each independently represent a single bond, —CO—, or —SO₂—.

Among the examples, as the anion moiety of the component (B), an anion in the component (b-1) is preferable. Among the examples, an anion represented by any of General Formulae (an-1) to (an-3) is more preferable, an anion represented by General Formula (an-1) or (an-2) is still more preferable, and an anion represented by General Formula (an-2) is particularly preferable.

### {Cation Moiety}

In Formulae (b-1), (b-2), and (b-3), M^{m+} represents an m-valent onium cation. Among these, a sulfonium cation and an iodonium cation are preferable.

m represents an integer of 1 or greater.

Preferred examples of the cation moiety ((M^{m+})_{l/m}) include organic cations each represented by General Formulae (ca-1) to (ca-5).

Among the examples, a cation represented by General Formula (ca-1) is preferable as the cation moiety ((M^{m+})_{l/m}).

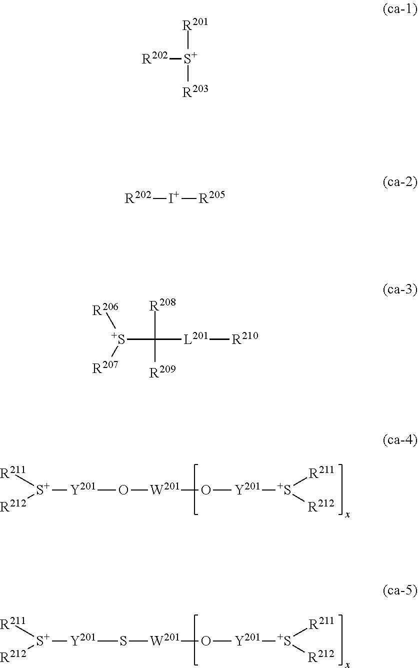

[In the formulae, R²⁰¹ to R²⁰⁷, R²¹¹, and R²¹² each independently represent an aryl group which may have a substituent, an alkyl group which may have a substituent, or an alkenyl group which may have a substituent. R²⁰¹ to R²⁰³, R²⁰⁶ and R²⁰⁷, and R²¹¹ and R²¹² may be bonded to each other to form a ring with the sulfur atom in the formula. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a SO₂-containing cyclic group which may have a substituent. L²⁰¹ represents —C(═O)— or —C(═O)—O—. Y²⁰¹'s each independently represent an arylene group, an alkylene group, or an alkenylene group. x represents 1 or 2. W²⁰¹ represents an (x+1)-valent linking group.]

In General Formulae (ca-1) to (ca-5), examples of the aryl group as R²⁰¹ to R²⁰⁷, R²¹¹, and R²¹² include an unsubstituted aryl group having 6 to 20 carbon atoms. Among these, a phenyl group or a naphthyl group is preferable.

The alkyl group as R²⁰¹ to R²⁰⁷, R²¹¹, and R²¹² is a chain-like or cyclic alkyl group, and the number of carbon atoms thereof is preferably in a range of 1 to 30.

It is preferable that the alkenyl group as R²⁰¹ to R²⁰⁷, R²¹¹, and R²¹² has 2 to 10 carbon atoms.

Examples of the substituent which may be included in R²⁰¹ to R²⁰⁷ and R²¹⁰ to R²¹² include an alkyl group, a halogen atom, a halogenated alkyl group, a carbonyl group, a cyano group, an amino group, an aryl group, and groups each represented by General Formulae (ca-r-1) to (ca-r-7).

In General Formulae (ca-1) to (ca-5), in a case where R²⁰¹ to R²⁰³, R²⁰⁶ and R²⁰⁷, and R²¹¹ and R²¹² are bonded to each other to form a ring with a sulfur atom in the formula, these groups may be bonded to each other via a heteroatom such as a sulfur atom, an oxygen atom, or a nitrogen atom, or a functional group such as a carbonyl group, —SO—, —SO₂—, —SO₃—, —COO—, —CONH— or —N(R_{N})— (here, R_{N} represents an alkyl group having 1 to 5 carbon atoms). As a ring to be formed, a ring containing the sulfur atom in the formula in the ring skeleton thereof is preferably a 3- to 10-membered ring and particularly preferably a 5- to 7-membered ring containing the sulfur atom. Specific examples of the ring to be formed include a thiophene ring, a thiazole ring, a benzothiophene ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a SO₂-containing cyclic group which may have a substituent.

Examples of the aryl group as R²¹⁰ include an unsubstituted aryl group having 6 to 20 carbon atoms. Among these, a phenyl group or a naphthyl group is preferable.

As the alkyl group as R²¹⁰, a chain-like or cyclic alkyl group having 1 to 30 carbon atoms is preferable.

It is preferable that the alkenyl group as R²¹⁰ has 2 to 10 carbon atoms.

As the SO₂-containing cyclic group as R²¹⁰ which may have a substituent, “—SO₂-containing polycyclic group” is preferable, and a group represented by General Formula (b5-r-1) is more preferable.

Y²⁰¹'s each independently represent an arylene group, an alkylene group, or an alkenylene group.

Examples of the arylene group as Y²⁰¹ include a group in which one hydrogen atom has been removed from an aryl group described as the aromatic hydrocarbon group represented by R¹⁰¹ in Formula (b-1).

Examples of the alkylene group and alkenylene group as Y²⁰¹ include a group in which one hydrogen atom has been removed from the group described as the chain-like alkyl group or the chain-like alkenyl group as R¹⁰¹ in Formula (b-1).

In Formula (ca-4), x represents 1 or 2.

W²⁰¹ represents an (x+1)-valent linking group, that is, a divalent or trivalent linking group.

As the divalent linking group represented by W²⁰¹, a divalent hydrocarbon group which may have a substituent is preferable, and examples thereof include the same divalent hydrocarbon groups which may have a substituent as those for Lz¹ in General Formula (z-1). The divalent linking group as W²⁰¹ may be any of linear, branched, or cyclic and is preferably cyclic. Among these, a group in which two carbonyl groups are combined with both ends of the arylene group is preferable. Examples of the arylene group include a phenylene group and a naphthylene group. Among these, a phenylene group is particularly preferable.

Examples of the trivalent linking group as W²⁰¹ include a group in which one hydrogen atom has been removed from the above-described divalent linking group as W²⁰¹ and a group obtained by bonding the divalent linking group to another divalent linking group described above. As the trivalent linking group as W²⁰¹, a group obtained by bonding two carbonyl groups to an arylene group is preferable.

Specific examples of suitable cations represented by Formula (ca-1) include cations each represented by Chemical Formulae (ca-1-1) to (ca-1-70).

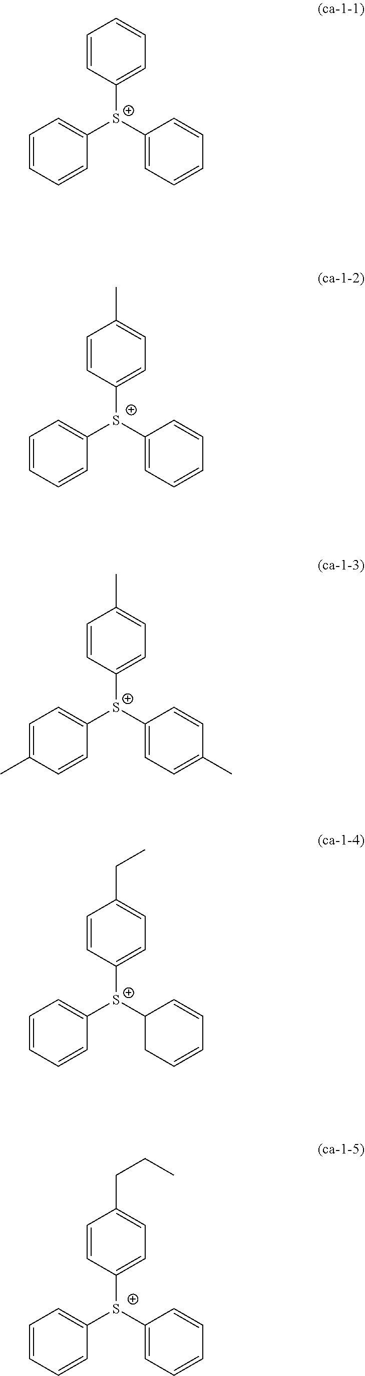

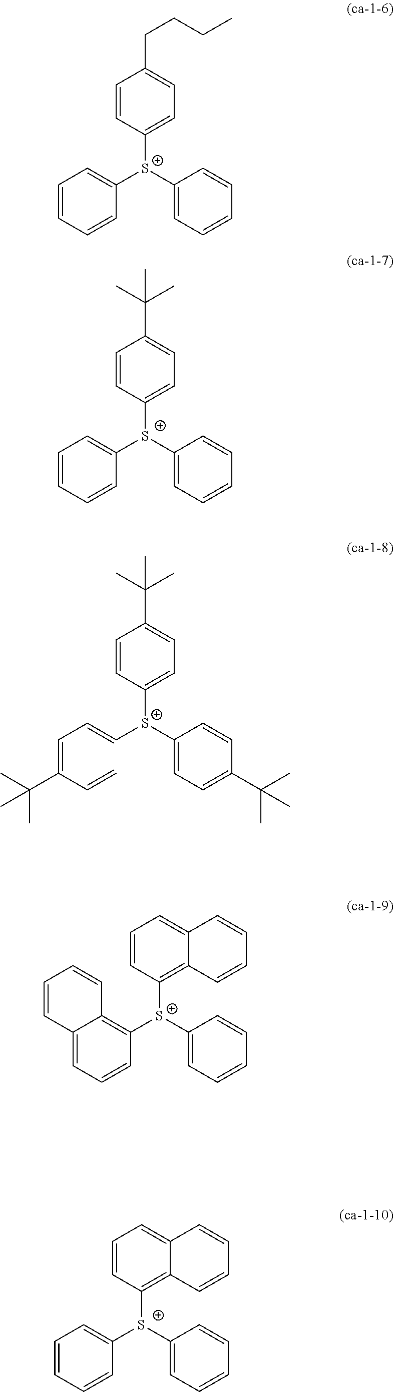 [SMILES: CCCCc1ccc([S+](c2ccccc2)c2ccccc2)cc1 ; CC(C)(C)c1ccc([S+](c2ccccc2)c2ccccc2)cc1 ; C=C/C(=C\C=C\[S+](c1ccc(C(C)(C)C)cc1)c1ccc(C(C)(C)C)cc1)C(C)(C)C ; c1ccc([S+](c2cccc3ccccc23)c2cccc3ccccc23)cc1 ; c1ccc([S+](c2ccccc2)c2cccc3ccccc23)cc1]

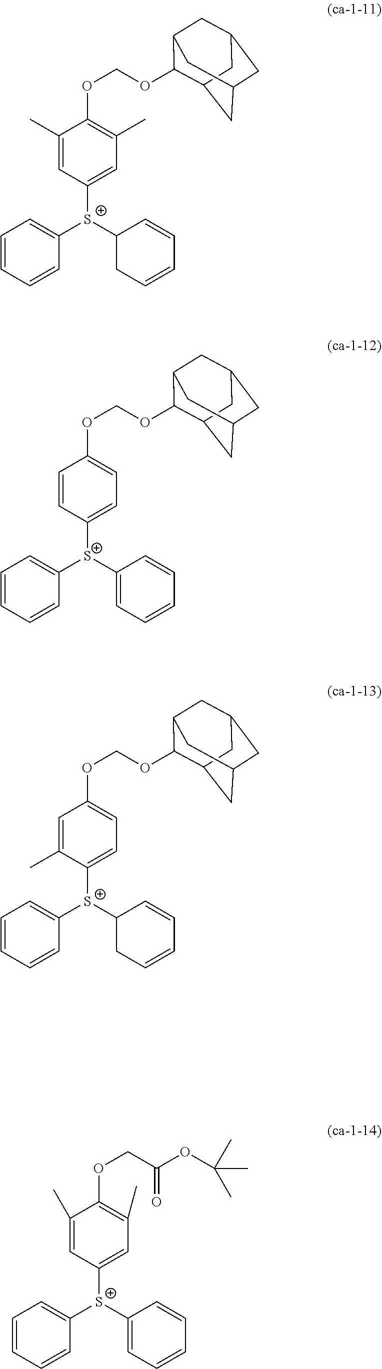 [SMILES: Cc1cc([S+](c2ccccc2)C2C=CC=CC2)cc(C)c1OCOC1C2CC3CC(C2)CC1C3 ; c1ccc([S+](c2ccccc2)c2ccc(OCOC3C4CC5CC(C4)CC3C5)cc2)cc1 ; Cc1cc(OCOC2C3CC4CC(C3)CC2C4)ccc1[S+](c1ccccc1)C1C=CC=CC1 ; Cc1cc([S+](c2ccccc2)c2ccccc2)cc(C)c1OCC(=O)OC(C)(C)C]

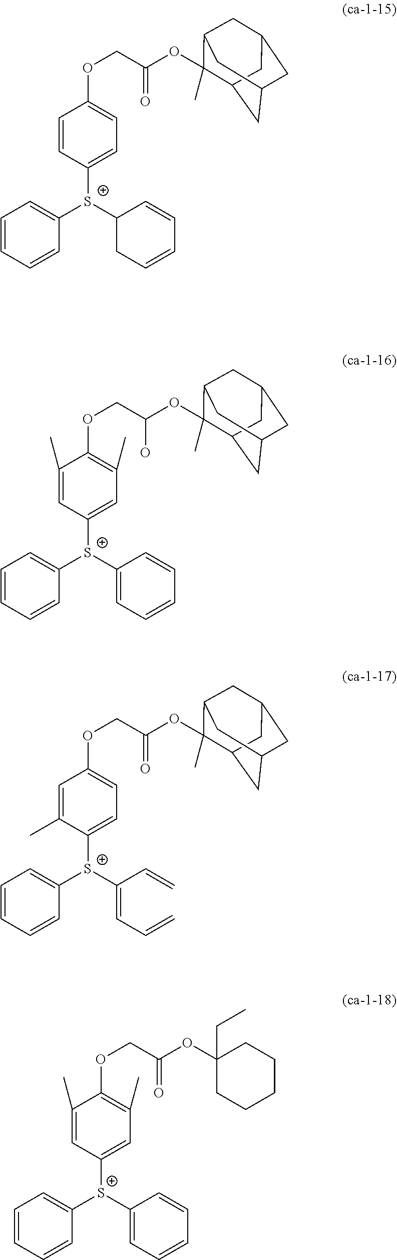 [SMILES: CC1(OC(=O)COc2ccc([S+](c3ccccc3)C3C=CC=CC3)cc2)C2CC3CC(C2)CC1C3 ; Cc1cc([S+](c2ccccc2)c2ccccc2)cc(C)c1OCC(O)OC1(C)C2CC3CC(C2)CC1C3 ; C=C/C=C(\C=C)[S+](c1ccccc1)c1ccc(OCC(=O)OC2(C)C3CC4CC(C3)CC2C4)cc1C ; CCC1(OC(=O)COc2c(C)cc([S+](c3ccccc3)c3ccccc3)cc2C)CCCCC1]

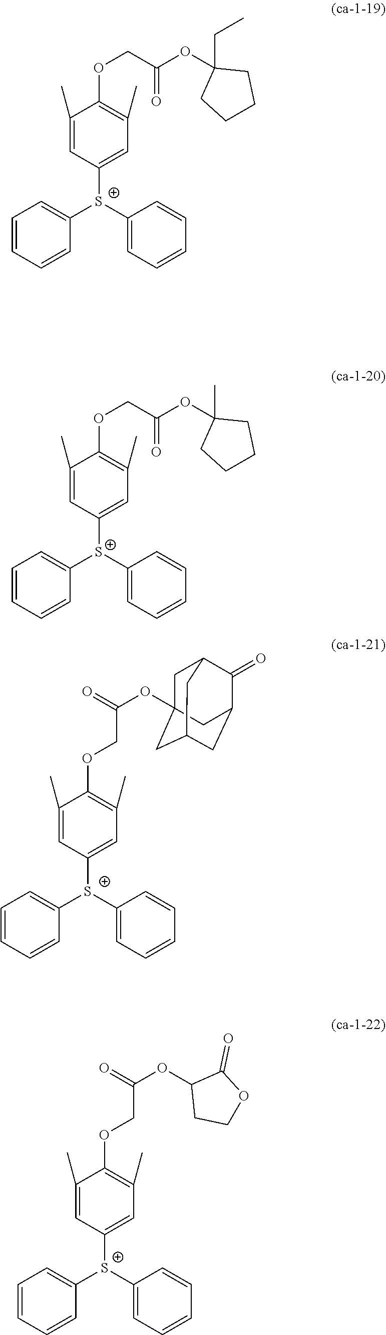 [SMILES: CCC1(OC(=O)COc2c(C)cc([S+](c3ccccc3)c3ccccc3)cc2C)CCCC1 ; Cc1cc([S+](c2ccccc2)c2ccccc2)cc(C)c1OCC(=O)OC1(C)CCCC1 ; Cc1cc([S+](c2ccccc2)c2ccccc2)cc(C)c1OCC(=O)OC12CC3CC(C1)C(=O)C(C3)C2 ; Cc1cc([S+](c2ccccc2)c2ccccc2)cc(C)c1OCC(=O)OC1CCOC1=O]

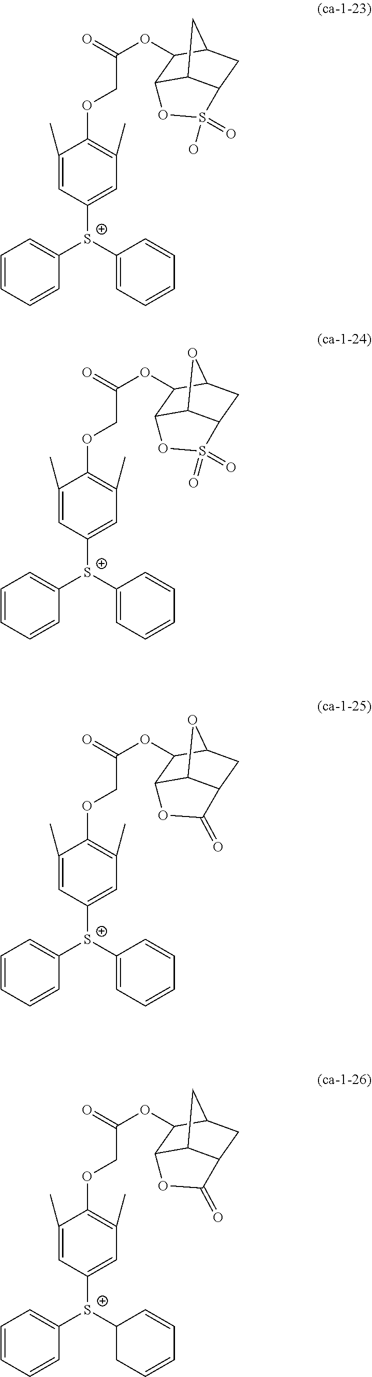

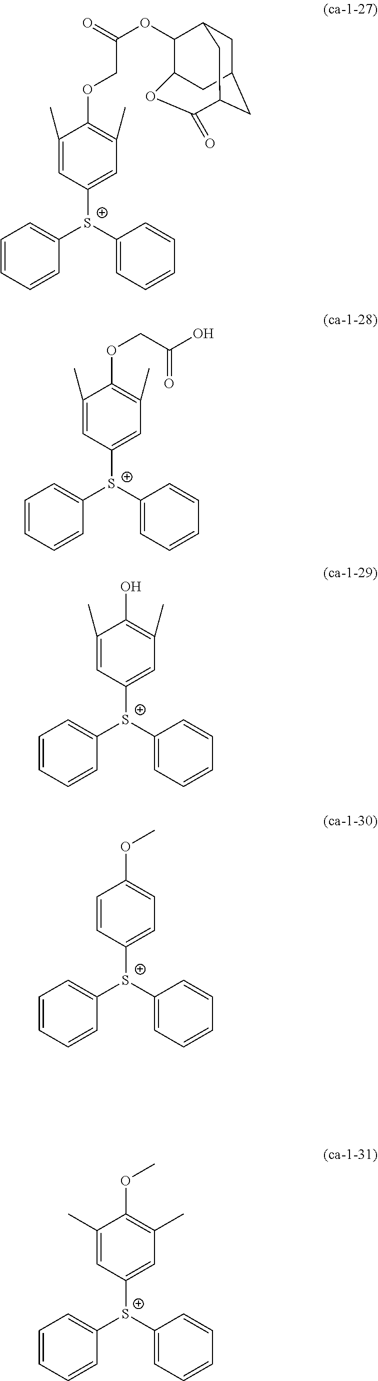

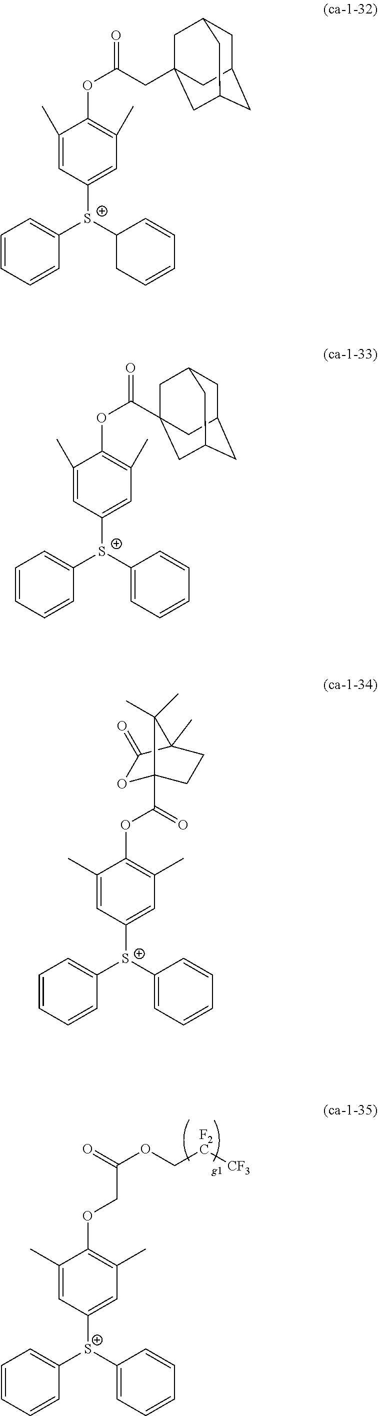

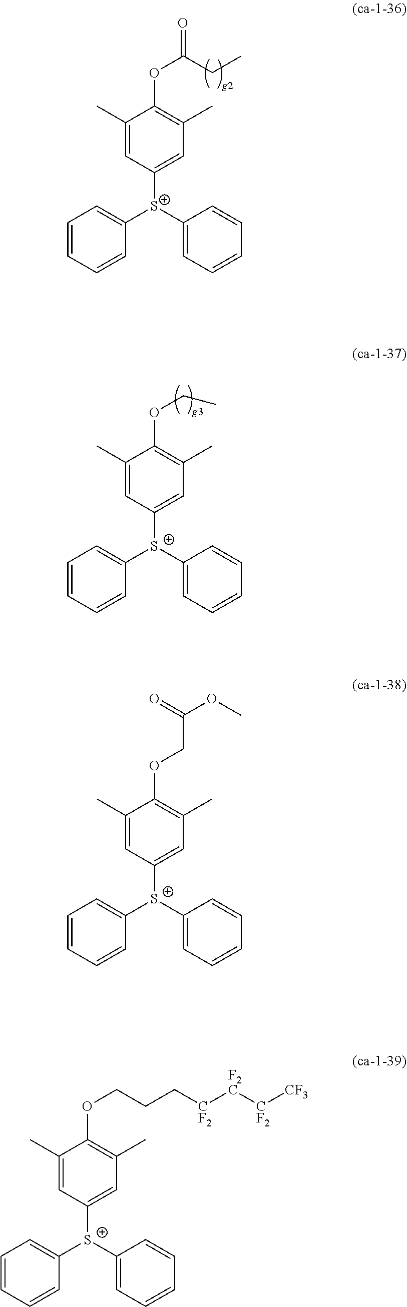

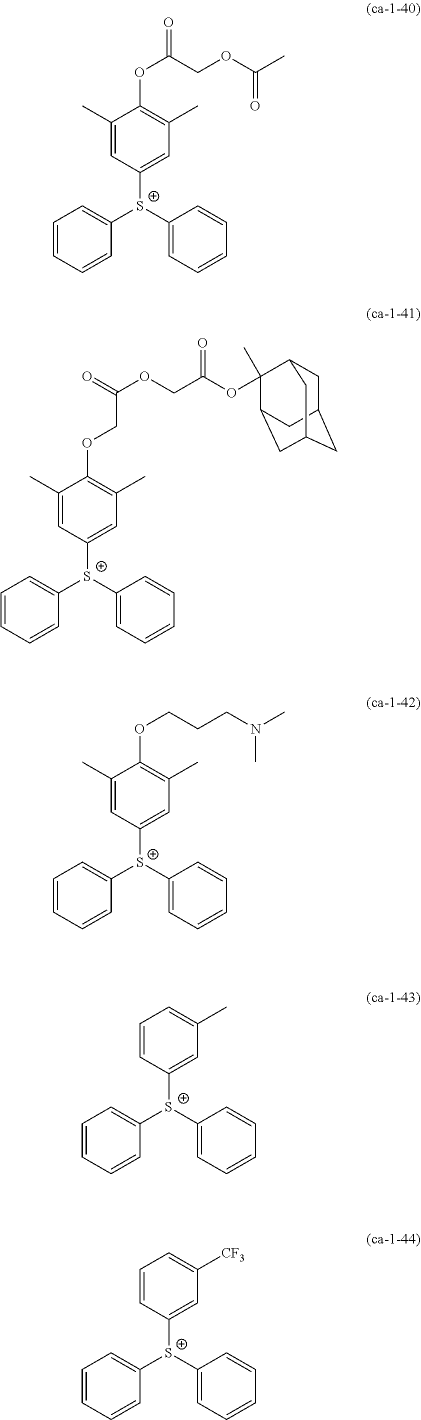 [SMILES: CC(=O)OCC(=O)Oc1c(C)cc([S+](c2ccccc2)c2ccccc2)cc1C ; Cc1cc([S+](c2ccccc2)c2ccccc2)cc(C)c1OCC(=O)OCC(=O)OC1(C)C2CC3CC(C2)CC1C3 ; Cc1cc([S+](c2ccccc2)c2ccccc2)cc(C)c1OCCCN(C)C ; Cc1cccc([S+](c2ccccc2)c2ccccc2)c1 ; FC(F)(F)c1cccc([S+](c2ccccc2)c2ccccc2)c1]

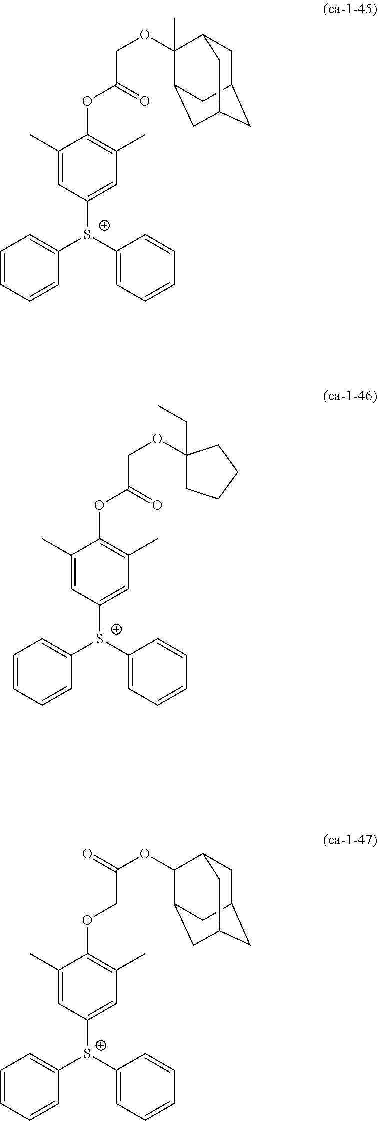 [SMILES: Cc1cc([S+](c2ccccc2)c2ccccc2)cc(C)c1OC(=O)COC1(C)C2CC3CC(C2)CC1C3 ; CCC1(OCC(=O)Oc2c(C)cc([S+](c3ccccc3)c3ccccc3)cc2C)CCCC1 ; Cc1cc([S+](c2ccccc2)c2ccccc2)cc(C)c1OCC(=O)OC1C2CC3CC(C2)CC1C3]

[In the formulae, g1, g2, and g3 represent a repeating number, g1 represents an integer of 1 to 5, g2 represents an integer of 0 to 20, and g3 represents an integer of 0 to 20.]

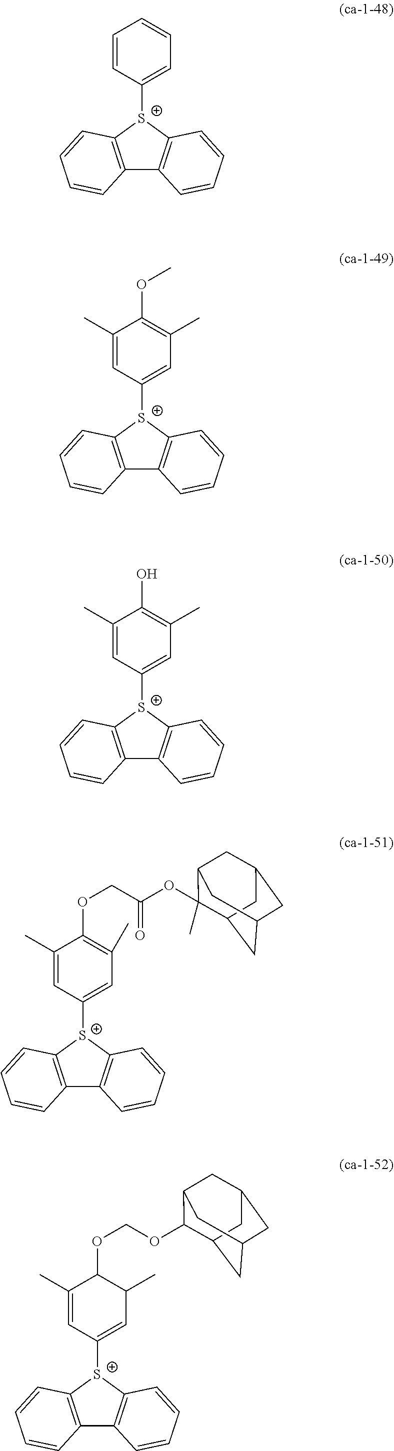 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; CC1=CC([s+]2c3ccccc3c3ccccc32)=CC(C)C1OCOC1C2CC3CC(C2)CC1C3]

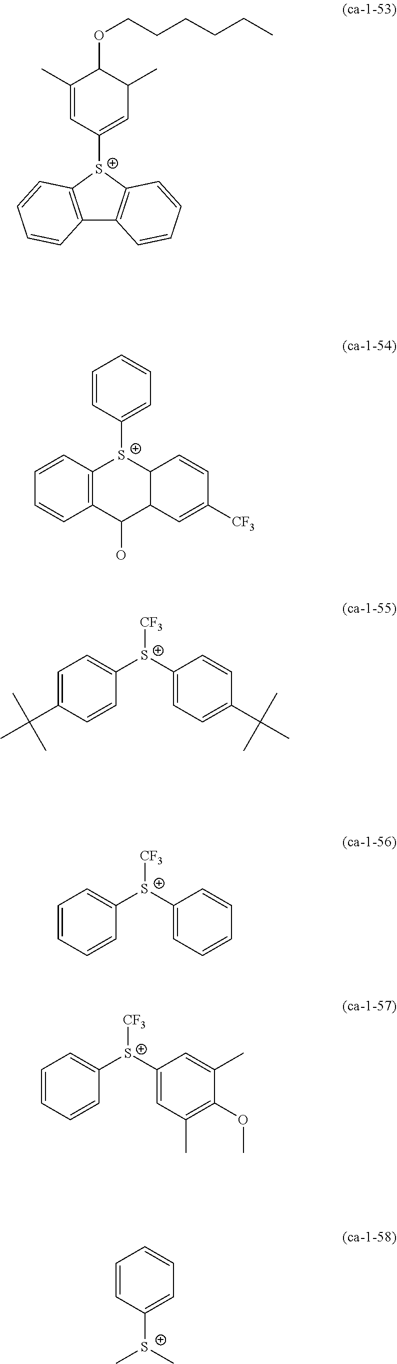

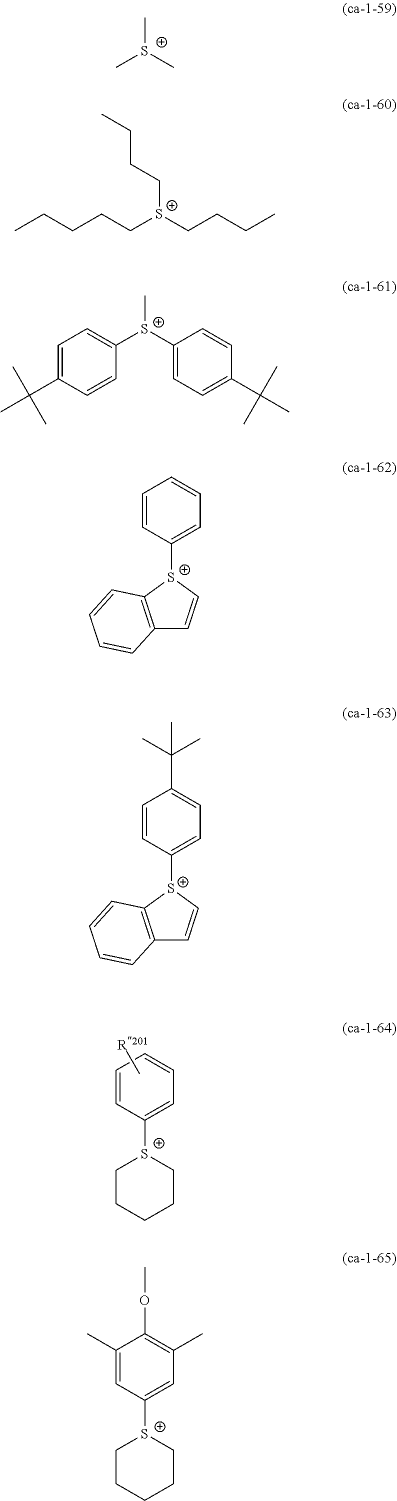

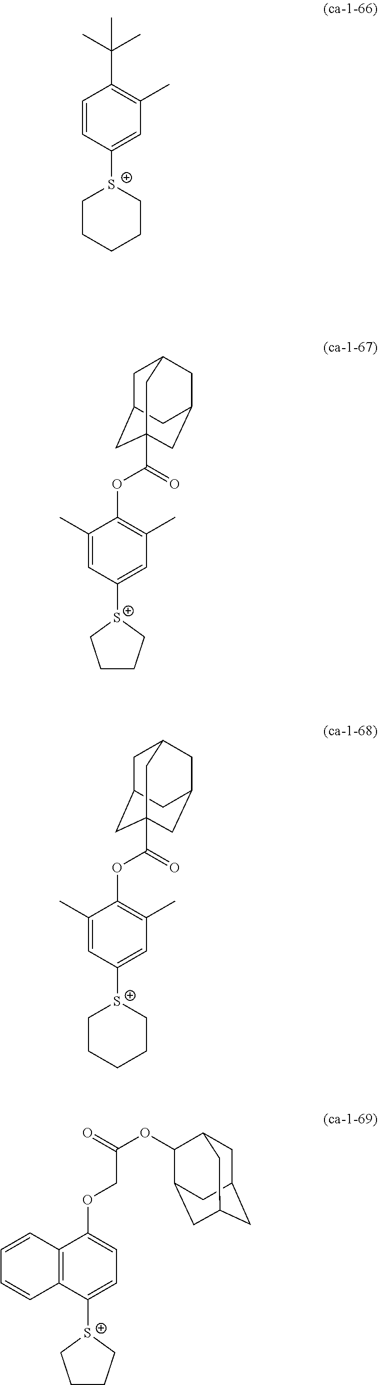 [SMILES: Cc1cc([S+]2CCCCC2)ccc1C(C)(C)C ; Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3]

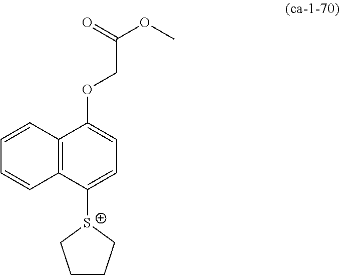 [SMILES: COC(=O)COc1ccc([S+]2CCCC2)c2ccccc12]

[In the formulae, R″²⁰¹ represents a hydrogen atom or a substituent, and examples of the substituent include the same groups as those for the substituents that R²⁰¹ to R²⁰⁷ and R²¹⁰ to R²¹² may have.]

Specific examples of suitable cations represented by Formula (ca-2) include a diphenyliodonium cation and a bis(4-tert-butylphenyl)iodonium cation.

Specific examples of suitable cations represented by Formula (ca-3) include cations each represented by Formulae (ca-3-1) to (ca-3-6).

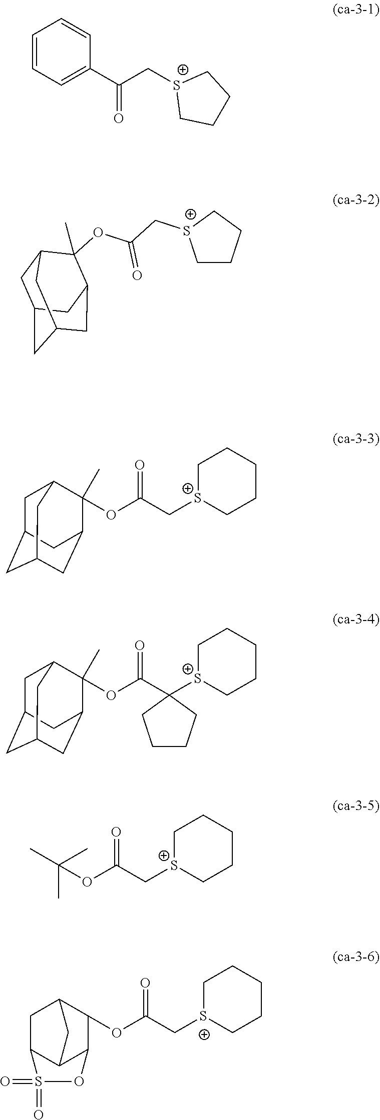 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

Specific examples of suitable cations represented by Formula (ca-4) include cations each represented by Formulae (ca-4-1) and (ca-4-2).

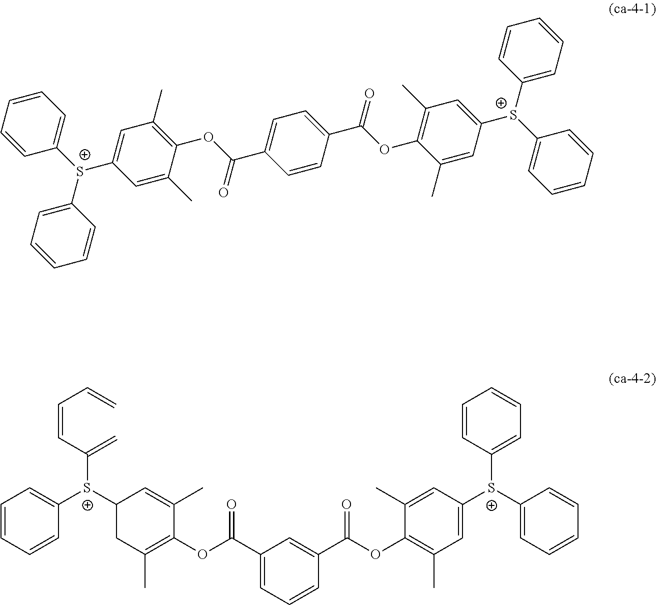 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; C=C/C=C\C(=C)[S+](c1ccccc1)C1C=C(C)C(OC(=O)c2cccc(C(=O)Oc3c(C)cc([S+](c4ccccc4)c4ccccc4)cc3C)c2)=C(C)C1]

Specific examples of suitable cations represented by Formula (ca-5) include cations each represented by General Formulae (ca-5-1) and (ca-5-3).

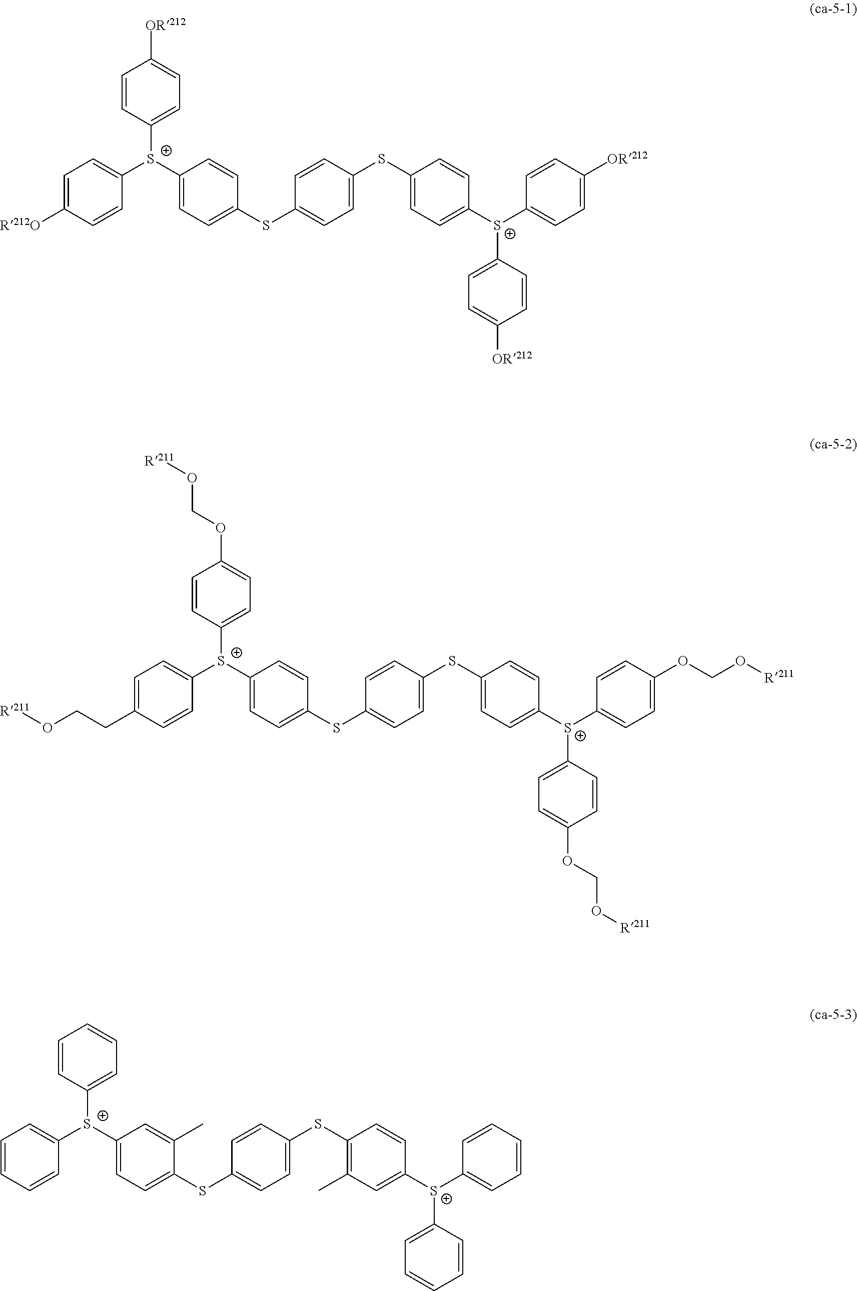

Among the examples, a cation represented by General Formula (ca-1) is preferable as the cation moiety ((M^{m+})_{l/m}).

In the present embodiment, it is preferable that the component (B1) contains an acid generator (B1-1) represented by General Formula (b1-1).

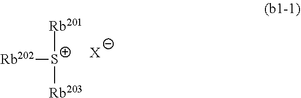

[In the formula, Rb²⁰¹ to Rb²⁰³ each independently represent an aryl group which may have a substituent, an alkyl group which may have a substituent, or an alkenyl group which may have a substituent. R²⁰¹ to R²⁰³ may be bonded to each other to form a ring with the sulfur atoms in the formula. X⁻ represents a counter anion.]

In Formula (b1-1), Rb²⁰¹ and Rb²⁰³ each have the same definition as that for R²⁰¹ to R²⁰³ in General Formula (ca-1). Among the examples, it is preferable that Rb²⁰¹ to Rb²⁰³ each independently represent an aryl group which may have a substituent or Rb²⁰¹ represents an aryl group which may have a substituent and Rb²⁰² and Rb²⁰³ are bonded to each other to form a ring with the sulfur atom in the formula, more preferable that Rb²⁰¹ represents an aryl group which may have a substituent and Rb²⁰² and Rb²⁰³ are bonded to each other to form a ring with the sulfur atom in the formula, and still more preferable that Rb²⁰¹ represents an aryl group which may have a substituent and Rb²⁰² and Rb²⁰³ are bonded to each other to form a tetrahydrothiophenium ring or a tetrahydrothiopyranium ring with the sulfur atom in the formula.

In Formula (b1-1), as the counter anion represented by X⁻, an anion of the component (b-1), an anion of the component (b-2), or an anion of the component (b-3) is preferable, an anion of the component (b-1) is more preferable, an anion represented by any of Formulae (an-1) to (an-4) is still more preferable, and an anion represented by Formula (an-1) or (an-4) is even still more preferable.

In the resist composition according to the present embodiment, the component (B1) may be used alone or in combination of two or more kinds thereof.

The content of the component (B1) in the resist composition according to the present embodiment is preferably in a range of 50 parts by mass or less, more preferably in a range of 0.1 to 40 parts by mass, still more preferably in a range of 0.1 to 30 parts by mass, and particularly preferably in a range of 0.1 to 20 parts by mass with respect to 100 parts by mass of the component (A1).

In a case where the content of the component (B1) is set to be in the above-described preferable ranges, pattern formation can be sufficiently carried out. Further, it is preferable that each component of the resist composition is dissolved in an organic solvent from the viewpoint that a uniform solution is likely to be obtained and the storage stability of the resist composition is enhanced.

### <Component (C)>

The component (C) is at least one crosslinking agent selected from the group consisting of a melamine-based crosslinking agent, a urea-based crosslinking agent, an alkylene urea-based crosslinking agent, a glycoluril-based crosslinking agent, and an epoxy-based crosslinking agent.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine. Among these, hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea. Among these, bismethoxymethyl urea is preferable.

Examples of the alkylene urea-based crosslinking agent include a compound represented by General Formula (CA-1).

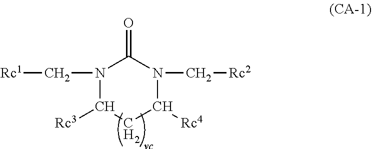

[In General Formula (CA-1), Rc¹ and Rc² each independently represent a hydroxyl group or a lower alkoxy group, Rc³ and Rc⁴ each independently represent a hydrogen atom, a hydroxyl group, or a lower alkoxy group, and vc represents an integer of 0 to 2.]

In a case where Rc¹ and Rc² represent a lower alkoxy group, it is preferable that Rc¹ and Rc² represent an alkoxy group having 1 to 4 carbon atoms, and Rc¹ and Rc² may be linear or branched. Rc¹ and Rc² may be the same as or different from each other. It is more preferable that Rc¹ and Rc² are the same as each other.

In a case where Rc³ and Rc⁴ represent a lower alkoxy group, it is preferable that Rc³ and Rc⁴ represent an alkoxy group having 1 to 4 carbon atoms, and Rc¹ and Rc⁴ may be linear or branched. Rc³ and Rc⁴ may be the same as or different from each other. It is more preferable that Rc³ and Rc⁴ are the same as each other.

vc represents an integer of 0 to 2 and preferably 0 or 1.

As the alkylene urea-based crosslinking agent, a compound in which vc represents 0 (ethylene urea-based crosslinking agent) and/or a compound in which vc represents 1 (propylene urea-based crosslinking agent) is particularly preferable.

The compound represented by General Formula (CA-1) can be obtained by performing a condensation reaction of alkylene urea with formalin or by reacting the product thereof with a lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxymethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by performing a condensation reaction of glycoluril with formalin or by reacting this product with lower alcohol.

Specific examples of the glycoluril-based crosslinking agents include mono-, di-, tri-, and/or tetra-hydroxymethylated glycoluril; mono-, di-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

The epoxy-based crosslinking agent is not particularly limited as long as it has an epoxy group, and any epoxy-based crosslinking agent can be selected and used. Among the examples, an epoxy-based crosslinking agent containing two or more epoxy groups is preferable. In a case where the epoxy-based crosslinking agent contains two or more epoxy groups, crosslinking reactivity is improved.

The number of epoxy groups is preferably 2 or more, more preferably 2 to 4, and most preferably 2.

Suitable epoxy-based crosslinking agents are shown below.

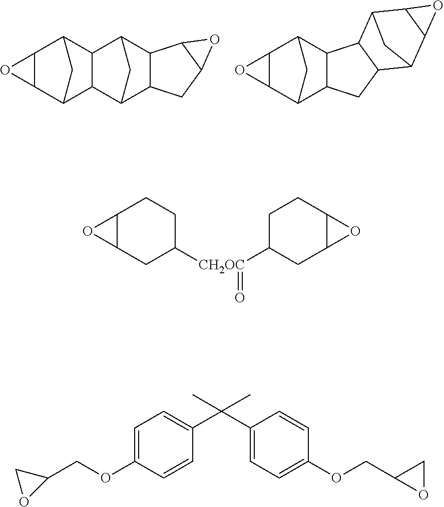

Among the examples, as the component (C), a crosslinking agent containing a —NCH₂—OCH₃ group is preferable, a crosslinking agent selected from the group consisting of a compound represented by General Formula (c1-1) or (c1-2), a compound containing a —NCH₂—OCH₃ group and a melamine skeleton, and a mono-, di-, tri- and/or tetra-methoxymethylated glycoluril is more preferable, and a crosslinking agent selected from the group consisting of a compound containing a —NCH₂—OCH₃ group and a melamine skeleton and a mono-, di-, tri- and/or tetra-methoxymethylated glycoluril is still more preferable.

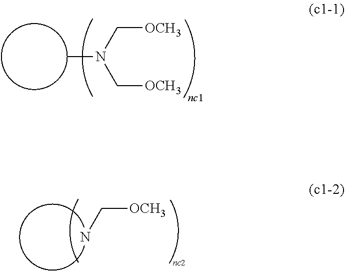

[In the formulae, nc1 and nc2 each independently represent an integer of 1 to 3.]

The component (C) may be used alone or in combination of two or more kinds thereof.

The content of the component (C) in the resist composition according to the present embodiment is preferably in a range of 1 to 50 parts by mass, more preferably in a range of 3 to 40 parts by mass, still more preferably in a range of 3 to 30 parts by mass, and most preferably in a range of 5 to 25 parts by mass with respect to 100 parts by mass of the component (A1).

In a case where the content of the component (C) is greater than or equal to the above-described lower limits, the formation of crosslinking proceeds sufficiently, and thus resolution performance and lithography characteristics are further improved. In addition, a satisfactory resist pattern with less swelling can be obtained. Further, in a case where the content thereof is less than or equal to the above-described upper limits, the storage stability of the resist composition is satisfactory, and the temporal deterioration of the sensitivity is likely to be suppressed.

### <(Z) Component>

The component (Z) is a polynuclear phenol low-molecular-weight compound containing 5 or less phenyl groups, preferably a polynuclear phenol low-molecular-weight compound containing 2 to 5 phenyl groups, and more preferably a polynuclear phenol low-molecular-weight compound containing 3 or 4 phenyl groups.

In a case where the component (Z) contains 2 to 5 phenyl groups, the transmittance of the resist film to an exposure light source in a case of forming a thick-film resist pattern is likely to be enhanced, and the resolution is likely to be enhanced. Further, in a case where the component (Z) contains 2 to 5 phenyl groups, occurrence of cracking in the thick-film resist pattern is more likely to be reduced.

The number of phenolic hydroxyl groups contained in the component (Z) is not particularly limited, but is preferably in a range of 2 to 5 and more preferably 3 or 4 from the viewpoint of improving the lithography characteristics such as the resolution and DOE

In the present embodiment, it is preferable that the component (Z) contains a compound represented by General Formula (z-1).

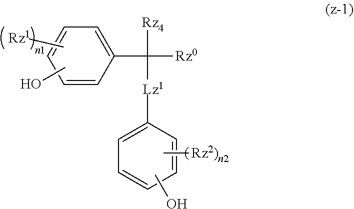

[In the formula, Rz¹ and Rz² each independently represent a substituent. n1 and n2 each independently represent an integer of 0 to 4. Lz¹ represents a single bond or a divalent linking group. Rz⁰ represents a hydrocarbon group which may have a substituent. Rz⁴ represents a hydrogen atom or an alkyl group.]

In Formula (z-1), examples of the substituent as Rz¹ and Rz² include an alkyl group, a halogen atom, a halogenated alkyl group, a carbonyl group, a cyano group, an amino group, and an aryl group. Among these, as the substituent represented by Rz¹ and Rz², an alkyl group is preferable, a linear or branched alkyl group having 1 to 5 carbon atoms is more preferable, and a methyl group is still more preferable.

In Formula (z-1), n1 and n2 each independently represent an integer of 0 to 4 and preferably an integer of 0 to 3. Further, from the viewpoint of increasing the sensitivity, it is preferable that n1 and n2 each independently represent an integer of 1 to 3.

In Formula (z-1), the divalent linking group as Lz¹ is not particularly limited, and suitable examples thereof include a divalent hydrocarbon group which may have a substituent and a divalent linking group having a heteroatom.

Divalent Hydrocarbon Group which May have Substituent:

In a case where Lz¹ represents a divalent hydrocarbon group which may have a substituent, the hydrocarbon group may be an aliphatic hydrocarbon group or an aromatic hydrocarbon group.

### Aliphatic Hydrocarbon Group as Lz¹

The aliphatic hydrocarbon group denotes a hydrocarbon group that has no aromaticity. The aliphatic hydrocarbon group may be saturated or unsaturated. In general, it is preferable that the aliphatic hydrocarbon group is saturated.

Examples of the aliphatic hydrocarbon group include a linear or branched aliphatic hydrocarbon group and an aliphatic hydrocarbon group having a ring in the structure thereof.

### Linear or Branched Aliphatic Hydrocarbon Group

The linear aliphatic hydrocarbon group has preferably 1 to 10 carbon atoms, more preferably 1 to 6 carbon atoms, and still more preferably 1 to 4 carbon atoms.

As the linear aliphatic hydrocarbon group, a linear alkylene group is preferable, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

As the branched aliphatic hydrocarbon group, a branched alkylene group is preferable, and specific examples thereof include alkylalkylene groups, for example, alkylmethylene groups such as —CH(CH₃)—, —CH(CH₂CH), —C(CH₃)₂—, —C(CH₃)(CH₂CH₃)—, —C(CH₃)(CH₂CH₂CH₃)—, and —C(CH₂CH₃)₂; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

The linear or branched aliphatic hydrocarbon group may or may not have a substituent. Examples of the substituent include a fluorine atom, a fluorinated alkyl group having 1 to 5 carbon atoms which has been substituted with a fluorine atom, and a carbonyl group.

### Aliphatic Hydrocarbon Group Having Ring in Structure Thereof

Examples of the aliphatic hydrocarbon group having a ring in the structure thereof include a cyclic aliphatic hydrocarbon group which may have a substituent having a heteroatom in the ring structure thereof (a group in which two hydrogen atoms have been removed from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in the middle of a linear or branched aliphatic hydrocarbon group. Examples of the linear or branched aliphatic hydrocarbon group include the same groups as those described above.

The cyclic aliphatic hydrocarbon group has preferably 3 to 20 carbon atoms and more preferably 3 to 12 carbon atoms.

The cyclic aliphatic hydrocarbon group may be a polycyclic group or a monocyclic group. As the monocyclic alicyclic hydrocarbon group, a group in which two hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which two hydrogen atoms have been removed from a polycycloalkane is preferable. As the polycycloalkane, a group having 7 to 12 carbon atoms is preferable. Specific examples of the polycycloalkane include adamantane, norbornane, isobornane, tricyclodecane, and tetracyclododecane.

The cyclic aliphatic hydrocarbon group may or may not have a substituent. Examples of the substituent include an alkyl group, an alkoxy group, a halogen atom, a halogenated alkyl group, a hydroxyl group, and a carbonyl group.

As the alkyl group as the substituent, an alkyl group having 1 to 5 carbon atoms is preferable, and a methyl group, an ethyl group, a propyl group, an n-butyl group, or a tert-butyl group is more preferable.

As the alkoxy group as the substituent, an alkoxy group having 1 to 5 carbon atoms is preferable, and a methoxy group, an ethoxy group, an n-propoxy group, an iso-propoxy group, an n-butoxy group, or a tert-butoxy group is more preferable, and a methoxy group or an ethoxy group is still more preferable.

Examples of the halogen atom as the substituent include a fluorine atom, a chlorine atom, a bromine atom, and an iodine atom. Among these, a fluorine atom is preferable.

Examples of the halogenated alkyl group as the substituent include groups in which some or all hydrogen atoms in the above-described alkyl groups have been substituted with the above-described halogen atoms.

In the cyclic aliphatic hydrocarbon group, some carbon atoms constituting the ring structure thereof may be substituted with a substituent having a heteroatom. As the substituent having a heteroatom, —O—, —C(═O)—O—, —S—, —S(═O)₂—, or —S(═O)₂—O— is preferable.

### Aromatic Hydrocarbon Group as Lz¹

The aromatic hydrocarbon group is a hydrocarbon group having at least one aromatic ring.

The aromatic ring is not particularly limited as long as the aromatic ring is a cyclic conjugated system having (4n+2) n electrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Here, the number of carbon atoms in a substituent is not included in the number of carbon atoms.

Specific examples of the aromatic ring include aromatic hydrocarbon rings such as benzene, naphthalene, anthracene, and phenanthrene; and aromatic heterocyclic rings in which some of the carbon atoms constituting the above-described aromatic hydrocarbon rings have been substituted with heteroatoms. Examples of the heteroatom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group in which two hydrogen atoms have been removed from the above-described aromatic hydrocarbon ring or aromatic heterocyclic ring (an arylene group or a heteroarylene group); a group in which two hydrogen atoms have been removed from an aromatic compound having two or more aromatic rings (such as biphenyl or fluorene); and a group in which one hydrogen atom of a group (an aryl group or a heteroaryl group) obtained by removing one hydrogen atom from the above-described aromatic hydrocarbon ring or aromatic heterocyclic ring has been substituted with an alkylene group (for example, a group obtained by further removing one hydrogen atom from an aryl group in an arylalkyl group such as a benzyl group, a phenethyl group, a cumyl group, a 1-naphthylmethyl group, a 2-naphthylmethyl group, a 1-naphthylethyl group, or a 2-naphthylethyl group). The number of carbon atoms in the alkylene group bonded to the aryl group or the heteroaryl group is preferably in a range of 1 to 4, more preferably 1 or 2, and particularly preferably 1.

In the aromatic hydrocarbon group, the hydrogen atom in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

As the alkyl group as the substituent, an alkyl group having 1 to 5 carbon atoms is preferable, and a methyl group, an ethyl group, a propyl group, an n-butyl group, or a tert-butyl group is more preferable.

As the alkoxy group, the halogen atom, and the halogenated alkyl group as the substituents, the groups described as the substituents that substitute a hydrogen atom in the cyclic aliphatic hydrocarbon group are exemplary examples.

### Divalent Linking Group Having Heteroatom:

In a case where Lz¹ represents a divalent linking group having a heteroatom, preferred examples of the linking group include —O—, —C(═O)—O—, —O—C(═O)—, —C(═O)—, —O—C(═O)—O—, —C(═O)—NH—, —NH—. —NH—C(═NH)—(H may be substituted with a substituent such as an alkyl group or an acyl group), —S—, —S(═O)₂—, —S(═O)₂—O—, and a group represented by General Formula: —Y²¹—O—Y²²—. —Y²¹—O—, —Y²¹—C(═O)—O—, —C(═O)—O—Y²¹—, —[Y²¹—C(═O)—O]ₘ—Y²²—, —Y²¹—O—C(═O)—Y²²—, or —Y²¹—S(═O)₂—O—Y²²—[in the formulae, Y²¹ and Y²² each independently represent a divalent hydrocarbon group which may have a substituent, O represents an oxygen atom, and m″ represents an integer of 0 to 3].

In a case where the divalent linking group containing a heteroatom is —C(═O)—NH—, —C(═O)—NH—C(═O)—, —NH—, or —NH—C(═NH)—, H may be substituted with a substituent such as an alkyl group or an acyl group. The substituent (an alkyl group, an acyl group, or the like) has preferably 1 to 10 carbon atoms, more preferably 1 to 8 carbon atoms, and particularly preferably 1 to 5 carbon atoms.

In General Formulae —Y²¹—O—Y²²—, —Y²¹—O—, —Y²¹—C(═O)—O—, —C(═O)—O—Y²¹—, —[Y²¹—C(═O)—O]_{m″}—Y²²—, —Y²¹—O—C(═O)—Y²²—, or —Y²¹—S(═O)₂—O—Y²²—, Y²¹ and Y²² each independently represent a divalent hydrocarbon group which may have a substituent. Examples of the divalent hydrocarbon group include the same groups described as the divalent linking group represented by Lz¹ (divalent hydrocarbon group which may have a substituent).

Y²¹ represents preferably a linear aliphatic hydrocarbon group, more preferably a linear alkylene group, still more preferably a linear alkylene group having 1 to 5 carbon atoms, and particularly preferably a methylene group or an ethylene group.

Y²² represents preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]_{m″}—Y²²—, m″ represents an integer of 0 to 3, preferably an integer of 0 to 2, more preferably 0 or 1, and particularly preferably 1. That is, a group represented by Formula —Y²¹—C(═O)—O—Y²²— is particularly preferable as the group represented by Formula —[Y²¹—C(═O)—O]_{m″}—Y²²—. Among these, a group represented by Formula —(CH₂)_{a′}—C(═O)—O—(CH₂)_{b′}— is preferable. In the formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

Among the examples, Lz¹ represents preferably a single bond, a linear or branched aliphatic hydrocarbon group, or an aromatic hydrocarbon group, more preferably a single bond, a linear alkylene group having 1 to 10 carbon atoms, or a group in which one hydrogen atom in an aryl group has been substituted with an alkylene group having 1 to 4 carbon atoms, and still more preferably a single bond, a linear alkylene group having 1 to 4 carbon atoms, or a group obtained by further removing one hydrogen atom from a benzyl group, a phenethyl group, or a cumyl group. From the viewpoint of reducing occurrence of cracking in the thick-film resist pattern, it is preferable that Lz¹ represents a linear alkylene group having 1 to 4 carbon atoms.

In Formula (z-1), examples of the hydrocarbon group as Rz⁰ include a linear or branched alkyl group and a cyclic hydrocarbon group.

It is preferable that the linear alkyl group as Rz⁰ has 1 to 5 carbon atoms. Specific examples thereof include a methyl group, an ethyl group, an n-propyl group, an n-butyl group, and an n-pentyl group.

It is preferable that the branched alkyl group as Rz⁰ has 3 to 10 carbon atoms. Specific examples include an isopropyl group, an isobutyl group, a tert-butyl group, an isopentyl group, a neopentyl group, a 1,1-diethylpropyl group, and a 2,2-dimethylbutyl group.

In a case where Rz⁰ represents a cyclic hydrocarbon group, the hydrocarbon group may be an aliphatic hydrocarbon group or an aromatic hydrocarbon group and may be a polycyclic group or a monocyclic group.

As the aliphatic hydrocarbon group which is a monocyclic group, a group in which one hydrogen atom has been removed from a monocycloalkane is preferable. The monocycloalkane has preferably 3 to 6 carbon atoms, and specific examples thereof include cyclopentane and cyclohexane.

As the aliphatic hydrocarbon group which is a polycyclic group, a group in which one hydrogen atom has been removed from a polycycloalkane is preferable. As the polycycloalkane, a group having 7 to 12 carbon atoms is preferable, and specific examples thereof include adamantane, norbornane, isobornane, tricyclodecane, and tetracyclododecane.

Examples of the aromatic hydrocarbon group as Rz⁰ include a group in which one or more hydrogen atoms have been removed from an aromatic hydrocarbon ring having 5 to 30 carbon atoms. Among the examples. Rz⁰ represents preferably a group in which one or more hydrogen atoms have been removed from an aromatic hydrocarbon ring having 6 to 15 carbon atoms, more preferably a group in which one or more hydrogen atoms have been removed from benzene, naphthalene, anthracene, or phenanthrene, still more preferably a group in which one or more hydrogen atoms have been removed from benzene, naphthalene, or anthracene, particularly preferably a group in which one or more hydrogen atoms have been removed from benzene or naphthalene, and most preferably a group in which one or more hydrogen atoms have been removed from benzene.

Examples of the substituent that the hydrocarbon group as Rz⁰ may have include a hydroxy group, a carboxyl group, a halogen atom, an alkoxy group (a methoxy group, an ethoxy group, a propoxy group, or a butoxy group), and an alkyloxycarbonyl group. Among these, a hydroxy group is preferable as the substituent that the hydrocarbon group as Rz⁰ may have.

In Formula (z-1), as the alkyl group as Rz⁴, a linear or branched alkyl group having 1 to 5 carbon atoms is preferable, a linear alkyl group having 1 to 3 carbon atoms is more preferable, and a methyl group is still more preferable.

In the present embodiment, it is more preferable that the component (Z) contains a compound represented by General Formula (z-1-1).

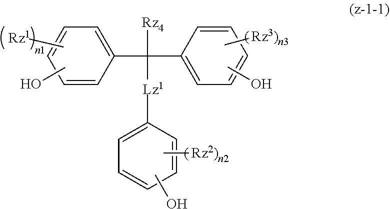

In the formula, Rz¹, Rz², and R³ each independently represent a substituent. n1, n2, and n3 each independently represent an integer of 0 to 4. Lz¹ represents a single bond or a divalent linking group. Rz⁴ represents a hydrogen atom or an alkyl group.]

In Formula (z-1-1), the substituent as Rz¹, Rz², and Rz³ has the same definition as that for Rz¹ and R² in Formula (z-1).

In Formula (z-1-1), n1, n2, and n3 each independently represent an integer of 0 to 4 and preferably an integer of 0 to 3. Further, from the viewpoint of increasing the sensitivity, it is preferable that n1, n2, and n3 each independently represent an integer of 1 to 3.

In Formula (z-1), Lz¹ and R^{z} each have the same definition as that for Lz¹ and Rz⁴ in Formula (z-1).

Specific preferred examples of the component (Z) are shown below.

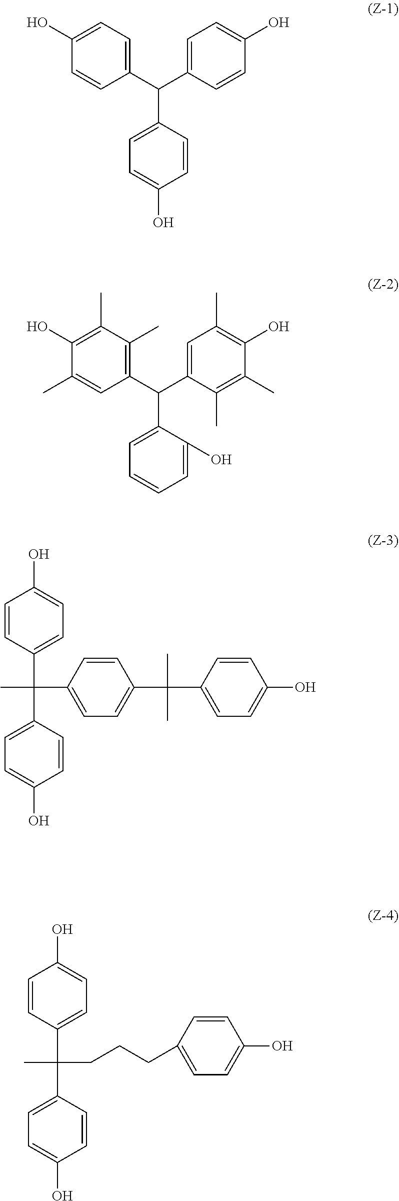

The component (Z) contained in the resist composition according to the present embodiment may be used alone or in a combination of two or more kinds thereof.

The content of the component (Z) in the resist composition according to the present embodiment is preferably in a range of 0.1 to 35 parts by mass, more preferably in a range of 0.3 to 30 parts by mass, still more preferably in a range of 0.5 to 25 parts by mass, and particularly preferably in a range of 1 to 20 parts by mass with respect to 100 parts by mass of the component (A1).

In a case where the content of the component (Z) is greater than or equal to the lower limits of the above-described preferable ranges, occurrence of cracking in the thick-film resist pattern is more likely to be reduced. Meanwhile, in a case where the content of the component (Z) is less than or equal to the upper limits of the above-described preferable ranges, the lithography characteristics such as the resolution and DOF are likely to be improved.

### <Optional Components>

### <<Component (D)>>

The resist composition in the present embodiment may further contain an acid diffusion control agent component (hereinafter, referred to as a “component (D)”) in addition to the component (A), the component (B), the component (C), and the component (Z). The component (D) acts as a quencher (an acid diffusion control agent) which traps the acid generated in the resist composition upon light exposure.

Examples of the component (D) include a nitrogen-containing organic compound (D1) (hereinafter, referred to as a “component (D1)”) and a photodecomposable base (D2) (hereinafter, referred to as a “component (D2)”) which does not correspond to the component (D1) and has acid diffusion controllability that is lost by the decomposition upon light exposure.

In a case where a resist composition containing the component (D) is obtained, the contrast between the exposed portion and the unexposed portion of the resist film can be further improved at the time of the formation of a resist pattern.

From the viewpoint of improving the transmittance of the resist film to the exposure light source in a case of forming a thick-film resist pattern, the component (D1) is preferable as the component (D).

### In Regard to Component (D1)

The component (D1) is a base component and is a nitrogen-containing organic compound component that acts as an acid diffusion control agent in the resist composition.

The component (D1) is not particularly limited as long as the component acts as an acid diffusion control agent, and examples thereof include aliphatic amines and an aromatic amines.

Among these, the aliphatic amine is preferably a secondary aliphatic amine or a tertiary aliphatic amine.

The aliphatic amine is an amine containing one or more aliphatic groups, and the number of carbon atoms in the aliphatic group is preferably in a range of 1 to 12.

Examples of the aliphatic amine include an amine obtained by substituting at least one hydrogen atom of ammonia NH₃ with an alkyl group or hydroxyalkyl group having 12 or less carbon atoms (an alkylamine or an alkylalcoholamine) and a cyclic amine.

Specific examples of the alkylamines and the alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, a trialkylamine of 5 to 10 carbon atoms is preferable, and tri-n-pentylamine and tri-n-octylamine are particularly preferable.

Examples of the cyclic amine include a heterocyclic compound having a nitrogen atom as a heteroatom. The heterocyclic compound may be a monocyclic compound (aliphatic monocyclic amine) or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

Examples of aromatic amines include 4-dimethylaminopyridine, pyrrole, indole, pyrazole, imidazole, and derivatives thereof, tribenzyl amine, an aniline compound, and N-tert-butoxycarbonylpyrrolidine.

The component (D1) may be used alone or in a combination of two or more kinds thereof.

Among these, the component (D1) is preferably an aromatic amine and more preferably an aniline compound. Examples of the aniline compound include 2,6-diisopropylaniline, N,N-dimethylaniline, N,N-dibutylaniline, and N,N-dihexylaniline.

### In Regard to Component (D2)

The component (D2) is not particularly limited as long as the component is decomposed upon light exposure and loses the acid diffusion controllability, and one or more compounds selected from the group consisting of a compound represented by Formula (d2-1) (hereinafter, referred to as a “component (d2-1)”), a compound represented by Formula (d2-2) (hereinafter, referred to as a “component (d2-2)”), and a compound represented by Formula (d2-3) (hereinafter, referred to as a “component (d2-3)”) are preferable.

At exposed portions of the resist film, the components (d2-1) to (d2-3) are decomposed and then lose the acid diffusion controllability (basicity), and therefore the components (d2-1) to (d2-3) cannot act as a quencher, whereas the components (d2-1) to (d2-3) act as a quencher at unexposed portions of the resist film.

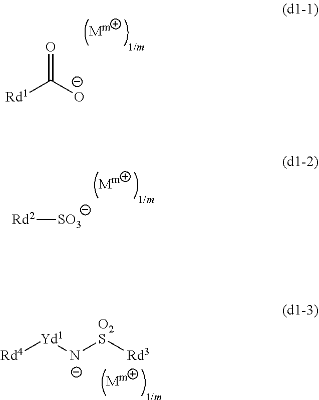

[In the formulae, Rd¹ to Rd⁴ represent a cyclic group which may have a substituent, a chain-like alkyl group which may have a substituent, or a chain-like alkenyl group which may have a substituent. Here, the carbon atom adjacent to the S atom as Rd² in General Formula (d2-2) has no fluorine atom bonded thereto. Yd¹ represents a single bond or a divalent linking group. m represents an integer of 1 or greater, and M′^{m+}'s each independently represent an m-valent onium cation.]

{Component (d2-1)}

### Anion Moiety

In Formula (d2-1), Rd¹ represents a cyclic group which may have a substituent, a chain-like alkyl group which may have a substituent, or a chain-like alkenyl group which may have a substituent, and examples thereof include the same groups as those for R¹⁰¹ in Formula (b-1).

Among these, it is preferable that Rd¹ represents an aromatic hydrocarbon group which may have a substituent, an aliphatic cyclic group which may have a substituent, or a chain-like alkyl group which may have a substituent. Examples of the substituent that these groups may have include a hydroxyl group, an oxo group, an alkyl group, an aryl group, a fluorine atom, a fluorinated alkyl group, the lactone-containing cyclic groups each represented by General Formulae (a2-r-1) to (a2-r-7), an ether bond, an ester bond, or a combination thereof. In a case where an ether bond or an ester bond is included as the substituent, the substituent may be bonded through an alkylene group, and a linking group represented by any of Formulae (y-a1-1) to (y-a1-5) is preferable as the substituent.

Suitable examples of the aromatic hydrocarbon group include a phenyl group, a naphthyl group, and a polycyclic structure (for example, a polycyclic structure composed of a ring structure of a bicyclooctane skeleton and a ring structure other than the bicyclooctane skeleton).

As the aliphatic cyclic group, a group in which one or more hydrogen atoms have been removed from a polycycloalkane such as adamantane, norbornane, isobornane, tricyclodecane or tetracyclododecane is more preferable.

It is preferable that the chain-like alkyl group has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group; and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group has preferably 1 to 11 carbon atoms, more preferably 1 to 8 carbon atoms, and still more preferably 1 to 4 carbon atoms. The fluorinated alkyl group may have an atom other than a fluorine atom. Examples of the atom other than a fluorine atom include an oxygen atom, a sulfur atom, and a nitrogen atom.

Rd¹ represents preferably a fluorinated alkyl group in which some or all hydrogen atoms constituting a linear alkyl group have been substituted with fluorine atoms and particularly preferably a fluorinated alkyl group (linear perfluoroalkyl group) in which all hydrogen atom, constituting a linear alkyl group have been substituted with a fluorine atom.

Specific preferred examples of the anion moiety in the component (d2-1) are shown below.

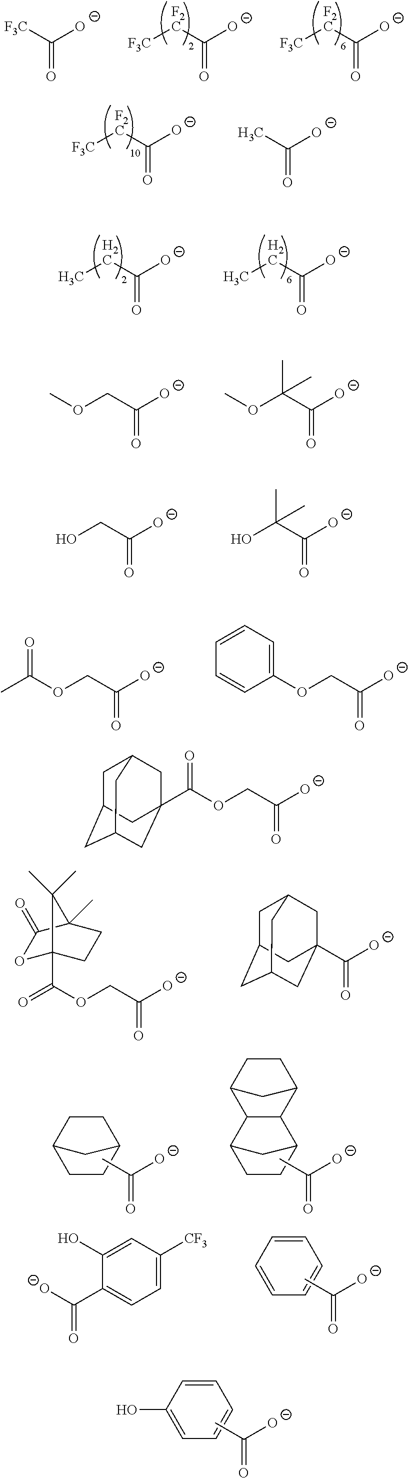

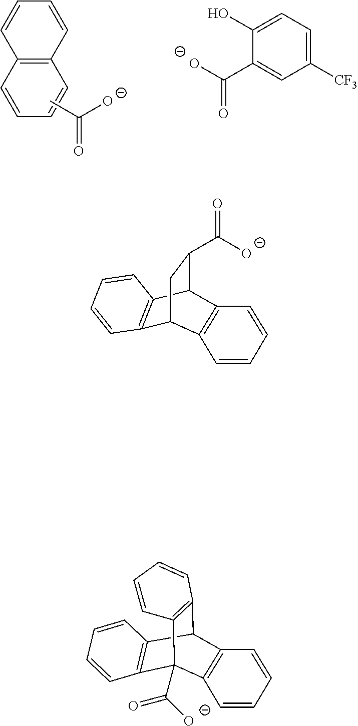

### Cation Moiety

In Formula (d2-1), M′^{m+} represents an m-valent onium cation.

Suitable examples of the onium cation as M′^{m+} include the same cations as the cations each represented by General Formulae (ca-1) to (ca-4), a cation represented by General Formula (ca-1) is more preferable, and a cation represented by any of General Formulae (ca-1-1) to (ca-1-78) and (ca-1-101) to (ca-1-149) are still more preferable.

The component (d2-1) may be used alone or in combination of two or more kinds thereof.

{Component (d2-2)}

### Anion Moiety

In Formula (d2-2), Rd² represents a cyclic group which may have a substituent, a chain-like alkyl group which may have a substituent, or a chain-like alkenyl group which may have a substituent, and examples thereof include the same groups as those for R¹⁰¹ in Formula (b-1).

Here, no fluorine atom is bonded to the carbon atom adjacent to the S atom in Rd² (the carbon atom is not substituted with fluorine). In this manner, the anion of the component (d2-2) is an appropriately weak acid anion, and thus the quenching ability of the component (D2) is improved.

It is preferable that Rd² represents a chain-like alkyl group which may have a substituent or an aliphatic cyclic group which may have a substituent. The chain-like alkyl group has preferably 1 to 10 carbon atoms and more preferably 3 to 10 carbon atoms. As the aliphatic cyclic group, a group in which one or more hydrogen atoms have been removed from adamantane, norbornane, isobornane, tricyclodecane, or tetracyclododecane (a group which may have a substituent); and a group in which one or more hydrogen atoms have been removed from camphor are more preferable.

The hydrocarbon group as Rd² may have a substituent. Examples of the substituent include the same substituents as the substituents that the hydrocarbon group (an aromatic hydrocarbon group, an aliphatic cyclic group, or a chain-like alkyl group) as Rd¹ in Formula (d2-1) may have.

Specific preferred examples of the anion moiety in the component (d2-2) are shown below.

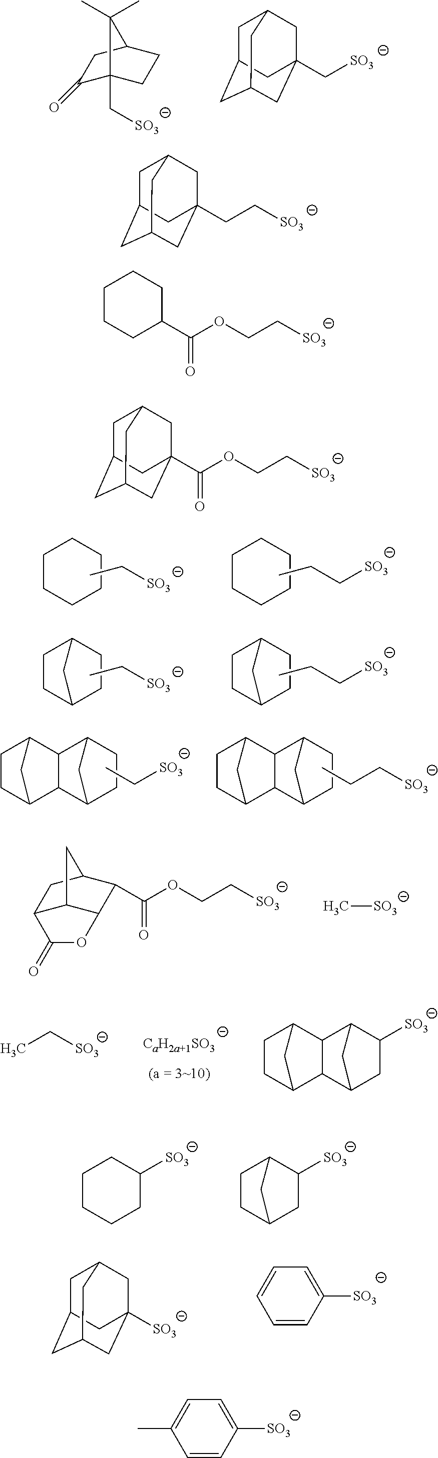

### Cation Moiety

In Formula (d2-2), M′^{m+} represents an m-valent onium cation and has the same definition as that for M′^{m+} in Formula (d2-1). The component (d2-2) may be used alone or in combination of two or more kinds thereof.

{Component (d2-3)}

### Anion Moiety

In Formula (d2-3), Rd³ represents a cyclic group which may have a substituent, a chain-like alkyl group which may have a substituent, or a chain-like alkenyl group which may have a substituent, examples thereof include the same groups as those for R¹⁰¹ in Formula (b-1). Among the examples, a cyclic group having a fluorine atom, a chain-like alkyl group, or a chain-like alkenyl group is preferable. Among these, a fluorinated alkyl group is preferable, and the same groups as those for the fluorinated alkyl group represented by Rd¹ are more preferable.

In Formula (d2-3), Rd⁴ represents a cyclic group which may have a substituent, a chain-like alkyl group which may have a substituent, or a chain-like alkenyl group which may have a substituent, and examples thereof include the same groups as those for R¹⁰¹ in Formula (b-1).

Among these, an alkyl group which may have a substituent, an alkoxy group which may have a substituent, an alkenyl group which may have a substituent, or a cyclic group which may have a substituent is preferable.

As the alkyl group represented by Rd⁴, a linear or branched alkyl group having 1 to 5 carbon atoms is preferable, and specific examples thereof include a methyl group, an ethyl group, a propyl group, an isopropyl group, an n-butyl group, an isobutyl group, a tert-butyl group, a pentyl group, an isopentyl group, and a neopentyl group. Some hydrogen atoms in the alkyl group as Rd⁴ may be substituted with a hydroxyl group, a cyano group, or the like.

As the alkoxy group represented by Rd⁴, an alkoxy group having 1 to 5 carbon atoms is preferable, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

Examples of the alkenyl group as Rd⁴ include the same groups as those for R¹⁰¹ in Formula (b-1). Among the examples, a vinyl group, a propenyl group (an allyl group), a 1-methylpropenyl group, or a 2-methylpropenyl group is preferable. These groups may have an alkyl group having 1 to 5 carbon atoms or a halogenated alkyl group having 1 to 5 carbon atoms as a substituent.

Examples of the cyclic group as Rd⁴ include the same groups as those for R¹⁰¹ in Formula (b-1). Among the examples, an alicyclic group in which one or more hydrogen atoms have been removed from a cycloalkane such as cyclopentane, cyclohexane, adamantane, norbornane, isobornane, tricyclodecane, or tetracyclododecane or an aromatic group such as a phenyl group or a naphthyl group is preferable. In a case where Rd⁴ represents an alicyclic group, the resist composition is satisfactorily dissolved in an organic solvent so that the lithography characteristics are enhanced.

In Formula (d2-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group having a heteroatom. Examples of the divalent linking groups are the same as those for the divalent hydrocarbon group which may have a substituent and the divalent linking group having a heteroatom, described in the section of the divalent linking group as Ya^{x1} in Formula (a10-1).

It is preferable that Yd¹ represents a carbonyl group, an ester bond, an amide bond, an alkylene group, or a combination thereof. As the alkylene group, a linear or branched alkylene group is more preferable, and a methylene group or an ethylene group is still more preferable.

Specific preferred examples of the anion moiety in the component (d2-3) are shown below.

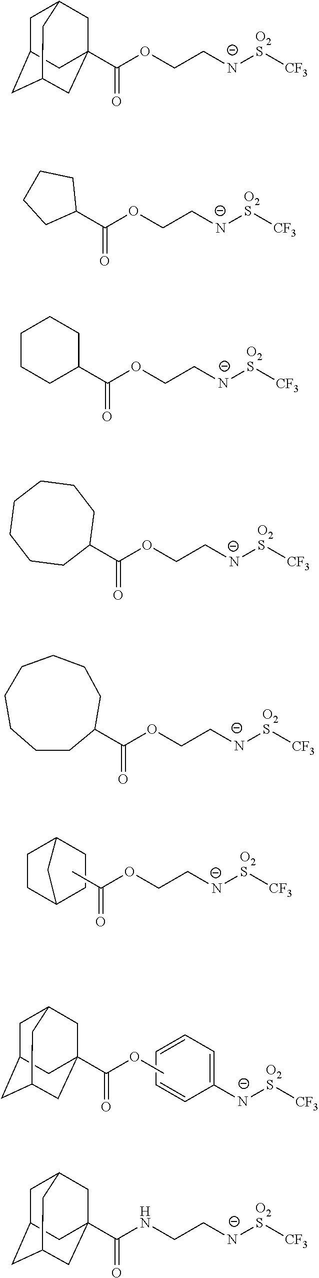

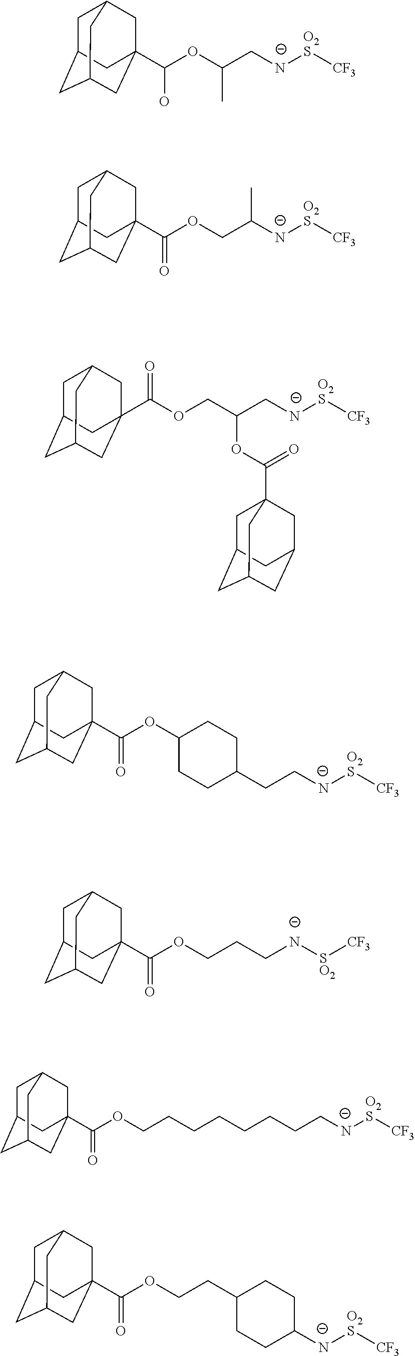

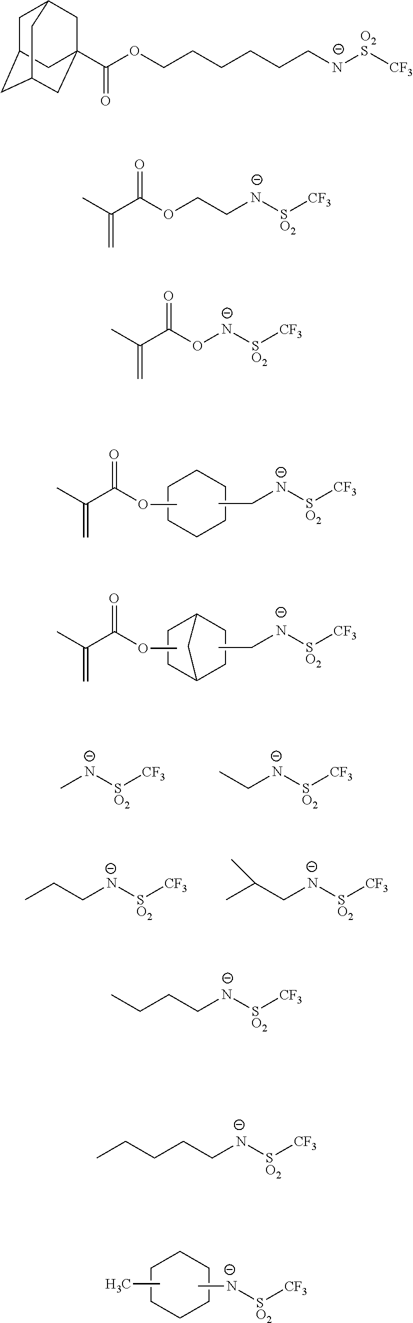

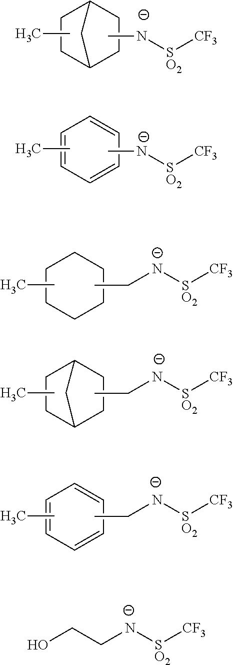

### Cation Moiety

In Formula (d2-3), M′^{m+} represents an m-valent onium cation and has the same definition as that for M′^{m+} in Formula (d2-1).

The component (d2-3) may be used alone or in combination of two or more kinds thereof.

As the component (D2), only one of the above-described components (d2-1) to (d2-3) or a combination of two or more kinds thereof may be used.

In a case where the resist composition contains the component (D2), the content of the component (D2) in the resist composition is preferably in a range of 0.5 to 35 parts by mass, more preferably in a range of 1 to 25 parts by mass, still more preferably in a range of 2 to 20 parts by mass, and particularly preferably in a range of 3 to 15 parts by mass with respect to 100 parts by mass of the component (A).

In a case where the content of the component (D2) is greater than or equal to the lower limits of the above-described preferable ranges, particularly satisfactory lithography characteristics and an excellent resist pattern shape are likely to be obtained. Meanwhile, in a case where the content thereof is less than or equal to the above-described upper limits, the balance between the component (D2) and other components can be achieved, and thus various lithography characteristics are enhanced.

### Method of Producing Component (D2):

The methods of producing the components (d2-1) and (d2-2) are not particularly limited, and the components (d2-1) and (d2-2) can be produced by known methods.

Further, the method of producing the component (d2-3) is not particularly limited, and the component (d2-3) can be produced in the same manner as disclosed in United States Patent Application, Publication No. 2012-0149916.

<<At Least One Compound (E) Selected from Group Consisting of Organic Carboxylic Acids, Phosphorus Oxo Acids, and Derivatives Thereof>>

For the purpose of preventing deterioration of the sensitivity and improving the resist pattern shape and the post-exposure temporal stability, the resist composition according to the present embodiment may contain, as an optional component, at least one compound (E) (hereinafter, referred to as “component (E)”) selected from the group consisting of an organic carboxylic acid, and a phosphorus oxo acid and a derivative thereof.

Specific examples of the organic carboxylic acid include acetic acid, malonic acid, citric acid, malic acid, succinic acid, benzoic acid, and salicylic acid. Among these, salicylic acid is preferable.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group. Examples of the hydrocarbon group include an alkyl group having 1 to 5 carbon atoms and an aryl group having 6 to 15 carbon atoms.

Examples of the phosphoric acid derivatives include phosphoric acid esters such as phosphoric acid di-n-butyl ester and phosphoric acid diphenyl ester.

Examples of the phosphonic acid derivatives include phosphonic acid esters such as phosphonic acid dimethyl ester, phosphonic acid di-n-butyl ester, phenylphosphonic acid, phosphonic acid diphenyl ester, and phosphonic acid dibenzyl ester.

Examples of the phosphinic acid derivatives include phosphinic acid ester and phenylphosphinic acid.

In the resist composition of the present embodiment, the component (E) may be used alone or in combination of two or more kinds thereof.

In a case where the resist composition contains the component (E), the content of the component (E) is preferably in a range of 0.01 to 5 parts by mass and more preferably in a range of 0.05 to 3 parts by mass with respect to 100 parts by mass of the component (A). In a case where the content thereof is in the above-described ranges, the lithography characteristics are further improved.

### <<Fluorine Additive Component (F)>>

The resist composition according to the present embodiment may further contain a fluorine additive component (hereinafter, referred to as “component (F)”) as a hydrophobic resin.

The component (F) is used to impart water repellency to the resist film and used as a resin different from the component (A), and thus the lithography characteristics are enhanced.

As the component (F), for example, the fluorine-containing polymer compounds described in Japanese Unexamined Patent Application, First Publication Nos. 2010-002870, 2010-032994, 2010-277043, 2011-13569, and 2011-128226 can be used.

Specific examples of the component (F) include a polymer having a constitutional unit (f1) represented by General Formula (f1-1). As the polymer, a polymer (homopolymer) formed of only the constitutional unit (f1) represented by Formula (f1-1); a copolymer of the constitutional unit (f1) and the constitutional unit (a1); or a copolymer of the constitutional unit (f1), a constitutional unit derived from acrylic acid or methacrylic acid, and the constitutional unit (a1) is preferable, and a copolymer of the constitutional unit (f1) and the constitutional unit (a1) is more preferable. Here, as the constitutional unit (a1) copolymerized with the constitutional unit (f1), a constitutional unit derived from 1-ethyl-1-cyclooctyl (meth)acrylate or a constitutional unit derived from 1-methyl-1-adamantyl (meth)acrylate is preferable, and a constitutional unit derived from 1-ethyl-1-cyclooctyl (meth)acrylate is more preferable.

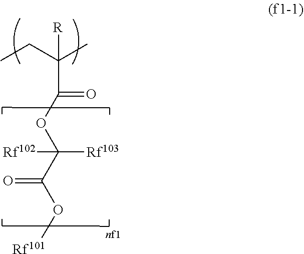

[In the formula, R has the same definition as described above, Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer of 0 to 5, and Rf¹⁰¹ represents an organic group having a fluorine atom.]

In Formula (f1-1). R bonded to the carbon atom at the α-position has the same definition as described above. It is preferable that R represents a hydrogen atom or a methyl group.

In Formula (f1-1), a fluorine atom is preferable as the halogen atom as Rf¹⁰² and Rf¹⁰³. Examples of the alkyl group having 1 to 5 carbon atoms as Rf¹⁰² and Rf¹⁰³ include the same groups as those for the alkyl group having 1 to 5 carbon atoms as R. Among the examples, a methyl group or an ethyl group is preferable. Specific examples of the halogenated alkyl group having 1 to 5 carbon atoms as Rf¹⁰² and Rf¹⁰³ include groups in which some or all hydrogen atoms of an alkyl group having 1 to 5 carbon atoms have been substituted with halogen atoms. Among these, a fluorine atom is preferable as the halogen atom. Among these, Rf¹⁰² and Rf¹⁰³ represent preferably a hydrogen atom, a fluorine atom, or an alkyl group having 1 to 5 carbon atoms, more preferably a hydrogen atom, a fluorine atom, a methyl group, or an ethyl group, and still more preferably a hydrogen atom.

In Formula (f1-1), nf¹ represents an integer of 0 to 5, preferably an integer of 0 to 3, and more preferably 1 or 2.

In Formula (f1-1), Rf¹⁰¹ represents an organic group having a fluorine atom and preferably a hydrocarbon group having a fluorine atom.

The hydrocarbon group having a fluorine atom may be linear, branched, or cyclic, and the number of carbon atoms thereof is preferably in a range of 1 to 20, more preferably in a range of 1 to 15, and particularly preferably in a range of 1 to 10.

In the hydrocarbon group having a fluorine atom, preferably 25% or more of the hydrogen atoms in the hydrocarbon group are fluorinated, more preferably 50% or more thereof are fluorinated, and particularly preferably 60% or more thereof are fluorinated from the viewpoint of increasing the hydrophobicity of the resist film during immersion exposure.

Among the examples, Rf¹⁰¹ represents more preferably a fluorinated hydrocarbon group having 1 to 6 carbon atoms and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight-average molecular weight (Mw) (in terms of polystyrene according to gel permeation chromatography) of the component (F) is preferably in a range of 1,000 to 50,000, more preferably in a range of 5000 to 40000, and most preferably in a range of 10,000 to 30.000. In a case where the weight-average molecular weight thereof is less than or equal to the upper limits of the above-described ranges, the resist composition exhibits a satisfactory solubility in a solvent for a resist enough to be used as a resist. Meanwhile, in a case where the weight-average molecular weight thereof is greater than or equal to the lower limits of the above-described ranges, water repellency of the resist film is improved.

Further, the dispersity (Mw/Mn) of the component (F) is preferably in a range of 1.0 to 5.0, more preferably in a range of 1.0 to 3.0, and most preferably in a range of 1.0 to 2.5.

In the resist composition according to the present embodiment, the component (F) may be used alone or in combination of two or more kinds thereof.

In a case where the resist composition contains the component (F), the content of the component (F) is preferably in a range of 0.5 to 10 parts by mass and more preferably in a range of 1 to 10 parts by mass with respect to 100 parts by mass of the component (A).

### <<Organic Solvent Component (S)>>

The resist composition of the present embodiment can be produced by dissolving the resist materials in an organic solvent component (hereinafter, referred to as “component (S)”).

The component (S) may be any organic solvent which can dissolve each component to be used to obtain a uniform solution, and an optional organic solvent can be appropriately selected from those which have been known as solvents of a chemically amplified resist composition and then used.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond, such as ethylene glycol monoacetate, diethylene glycol monoacetate, propylene glycol monoacetate, and dipropylene glycol monoacetate; polyhydric alcohol derivatives of compounds having an ether bond such as monoalkyl ether or monophenyl ether, such as monomethylether, monoethylether, monopropylether, or monobutylether of polyhydric alcohols or compounds having an ester bond [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene, and mesitylene; and dimethylsulfoxide (DMSO).

In the resist composition of the present embodiment, the component (S) may be used alone or in the form of a mixed solvent of two or more kinds thereof. Among these. PGMEA, PGME, γ-butyrolactone, EL, or cyclohexanone is preferable.

Further, a mixed solvent obtained by mixing PGMEA with a polar solvent is also preferable as the component (S). The blending ratio (mass ratio) of the mixed solvent can be appropriately determined in consideration of the compatibility between PGMEA and the polar solvent, but is preferably in a range of 1:9 to 9:1 and more preferably in a range of 2:8 to 8:2.

More specifically, in a case where EL or cyclohexanone is blended as the polar solvent, the mass ratio of PGMEA to EL or cyclohexanone is preferably in a range of 1:9 to 9:1 and more preferably in a range of 2:8 to 8:2. Further, in a case where PGME is blended as the polar solvent, the mass ratio of PGMEA to PGME is preferably in a range of 1:9 to 9:1, more preferably in a range of 2:8 to 8:2, and still more preferably in a range of 3:7 to 7:3. Further, a mixed solvent of PGMEA. PGME, and cyclohexanone is also preferable.

Further, a mixed solvent of γ-butyrolactone and at least one selected from PGMEA and EL is also preferable as the component (S). In this case, as the mixing ratio, the mass ratio between the former and the latter is preferably in a range of 70:30 to 95:5.

The amount of the component (S) to be used is set such that the solid content concentration of the resist composition is 15% by mass or greater. In the present specification, the solid content in the resist composition denotes components other than the component (S). The solid content concentration of the resist composition is calculated by the following equation.

Solid content concentration (% by mass)=total mass of components other than component (S)/total mass of resist composition×100

For example, in a case where the resist composition consists of the component (A), the component (Z), the component (B), the component (D), and the component (S), an equation of “solid content concentration (% by mass)=[(component (A)+component (Z)+component (B)+component (D))/(component (A)+component (Z)+component (B)+component (D)+component (S)]×100” is satisfied.

In a case where the resist composition is applied onto a substrate to form a resist film, a thick resist film (for example, a film having a film thickness of 2 μm to 20 μm) can be formed by setting the solid content concentration of the resist composition to 15% by mass or greater. The solid content concentration of the resist composition is not particularly limited as long as the solid content concentration is 15% by mass or greater, and can be appropriately determined depending on the desired film thickness of the resist film. Typically, the film thickness of the resist film increases as the solid content concentration increases.

The upper limit of the solid content concentration of the resist composition is not particularly limited as long as the concentration is set such that the solid content can be dissolved. The solid content concentration of the resist composition is, for example, 60% by mass or less, preferably 55% by mass or less, and more preferably 50% by mass or less.

The solid content concentration of the resist composition is, for example, in a range of 15% to 60% by mass, in a range of 15% to 55% by mass, or in a range of 15% to 50% by mass.

As desired, miscible additives such as additive resins, dissolution inhibitors, plasticizers, stabilizers, colorants, halation prevention agents, and dyes for improving the performance of the resist film can be added to the resist composition of the present embodiment, as appropriate.

After the resist material is dissolved in the component (S), impurities may be removed from the resist composition of the present embodiment using a porous polyimide film, a porous polyamideimide film, or the like. For example, the resist composition may be filtered using a filter formed of a porous polyimide film, a filter formed of a porous polyamideimide film, a filter formed of a porous polyimide film and a porous polyamideimide film, or the like. Examples of the porous polyimide film and the porous polyamideimide film include those described in Japanese Unexamined Patent Application, First Publication No. 2016-155121.

The resist composition according to the present embodiment described above has a solid content concentration of 15% by mass or greater and contains a polynuclear phenol low-molecular-weight compound (Z) (component (Z)) containing 5 or less phenyl groups.

Since the resist composition according to the present embodiment has a solid content concentration of 15% by mass or greater, a thick resist film (for example, a film having a film thickness of 2 μm to 20 μm) is formed in a case where a substrate is coated with the resist composition to form a resist film. In a case of such a thick resist film, cracking is likely to occur in the resist pattern. Further, since light is unlikely to reach the bottom of the film, the sensitivity during light exposure is difficult to maintain, and a resist pattern having a satisfactory shape is unlikely to be formed.

Since the resist composition according to the present embodiment contains the component (Z), cracking is unlikely to occur while the lithography characteristics such as the resolution and DOF are maintained, and a thick-film resist pattern having satisfactory coating properties with respect to a substrate can be formed. The reason for this is assumed that since the component (Z) containing a phenolic hydroxyl group is present in the resist film formed of the resist composition, crosslinking occurs between the components (A1) through the constitutional unit (a10) in the components (A1) upon light exposure, and the flexibility can be imparted to exposed portions of the resist film in which the rigidity is likely to increase in a case where the solubility of the exposed portions of the resist film in an alkali developing solution is decreased, and as a result, occurrence of cracking can be reduced. Further, since the number of phenyl groups in the component (Z) is 5 or less, occurrence of cracking is assumed to be reduced while the lithography characteristics such as the resolution or DOF are maintained.

### (Method for Forming Resist Pattern)

A method for forming a resist pattern according to the second aspect of the present invention is a method including a step of forming a resist film on a support using the resist composition according to the first aspect of the present invention described above, a step of exposing the resist film to light, and a step of developing the resist film exposed to light to form a resist pattern.

According to the embodiment of the method for forming a resist pattern, a method for forming a resist pattern, which is performed in the following manner, is an exemplary example.

First, a support is coated with the resist composition of the present embodiment using a spinner or the like, and a bake (post applied bake (PAB)) treatment is performed under a temperature condition of 80° C. to 150° C. for 40 to 120 seconds and preferably 60 to 90 seconds to form a resist film.

Following the selective exposure carried out on the resist film by, for example, exposure through a mask (mask pattern) having a predetermined pattern formed on the mask by using an exposure apparatus such as an electron beam lithography apparatus or an ArF exposure apparatus, or direct irradiation of the resist film for drawing with an electron beam without using a mask pattern, a bake treatment (post exposure bake (PEB)) is carried out, for example, under a temperature condition in a range of 80° C. to 150° C. for 40 to 120 seconds and preferably 60 to 90 seconds.

Next, the resist film is subjected to a developing treatment. The developing treatment is conducted using an alkali developing solution in a case of an alkali developing process and using a developing solution containing an organic solvent (organic developing solution) in a case of a solvent developing process.

After the developing treatment, it is preferable to conduct a rinse treatment. As the rinse treatment, water rinsing using pure water is preferable in a case of the alkali developing process, and rinsing using a rinse solution containing an organic solvent is preferable in a case of the solvent developing process.

In a case of the solvent developing process, after the developing treatment or the rinse treatment, the developing solution or the rinse solution attached onto the pattern may be removed by a treatment using a supercritical fluid.

After the developing treatment or the rinse treatment, drying is conducted. As desired, a bake treatment (post bake) may be conducted after the developing treatment.

In this manner, a resist pattern can be formed.

The support is not particularly limited and a known support of the related art can be used, and examples thereof include a substrate for an electronic component and a substrate on which a predetermined wiring pattern has been formed. Specific examples thereof include a metal substrate such as a silicon wafer, copper, chromium, iron, or aluminum; and a glass substrate. As the materials of the wiring pattern, copper, aluminum, nickel, or gold can be used.

The method for forming a resist pattern according to the embodiment is a method useful at the time of being carried out by forming a thick resist film. Even in a case where the film thickness of the resist film formed by coating a substrate with the resist composition is, for example, in a range of 2 to 20 μm, a resist pattern can be stably formed in a satisfactory shape.

The wavelength used for light exposure is not particularly limited and the exposure can be conducted using radiation such as an ArF excimer laser, a KrF excimer laser, an F₂ excimer laser, extreme ultraviolet rays (EUV), vacuum ultraviolet rays (VUV), electron beams (EB), X-rays, and soft X-rays. The resist composition is highly useful for a KrF excimer laser, an ArF excimer laser, EB, or EUV, more useful for ultraviolet rays such as g-line and i-line, KrF excimer laser light, or ArF excimer laser light, and particularly useful for ultraviolet rays such as g-line and i-line, and KrF excimer laser light. That is, the method for forming a resist pattern according to the present embodiment is a method particularly useful in a case where the step of exposing the resist film to light is performed by irradiating the resist film with ultraviolet rays such as g-line and i-line, or KrF excimer laser light.

The exposure of the resist film to light can be a general exposure (dry exposure) conducted in air or an inert gas such as nitrogen, or liquid immersion exposure (liquid immersion lithography).

The liquid immersion exposure is an exposure method in which the region between the resist film and the lens at the lowermost position of the exposure apparatus is filled with a solvent (liquid immersion medium) in advance that has a larger refractive index than the refractive index of air, and the exposure (immersion exposure) is conducted in this state.

A solvent that exhibits a refractive index greater than the refractive index of air but less than the refractive index of the resist film to be exposed to light is preferable as the liquid immersion medium, and examples thereof include water, a fluorine-based inert liquid, a silicon-based solvent, and a hydrocarbon-based solvent.

As the liquid immersion medium, water is preferably used.

As the alkali developing solution used for the developing treatment in the alkali developing process, a 0.1 to 10 mass % tetramethylammonium hydroxide (TMAH) aqueous solution is an exemplary example.

The developing treatment can be performed according to a known developing method, and examples thereof include a method of immersing a support in a developing solution for a certain time (a dip method), a method of raising a developing solution on the surface of a support using the surface tension and maintaining the state for a certain time (a puddle method), a method of spraying a developing solution to the surface of a support (spray method), and a method of continuously ejecting a developing solution onto a support rotating at a certain rate while scanning a developing solution ejection nozzle at a certain rate (dynamic dispense method).

A known additive can be blended into the rinse solution as necessary. Examples of the additive include a surfactant. As the surfactant, the same surfactants as those described above are exemplary examples. Among these, a non-ionic surfactant is preferable, and a non-ionic fluorine-based surfactant or a non-ionic silicon-based surfactant is more preferable.

In a case where a surfactant is blended into the solution, the blending amount of the surfactant is typically in a range of 0.001% to 5% by mass, preferably in a range of 0.005% to 2% by mass, and more preferably in a range of 0.01% to 0.5% by mass with respect to the total amount of the rinse solution.

The rinse treatment carried out using a rinse solution (washing treatment) can be performed according to a known rinse method. Examples of the method of performing the rinse treatment include a method of continuously ejecting a rinse solution onto a support rotating at a certain rate (rotary coating method), a method of immersing a support in a rinse solution for a certain time (dip method), and a method of spraying a rinse solution to the surface of a support (spray method).

According to the method for forming a resist pattern of the present embodiment described above, since the resist composition described above is used, a thick-film resist pattern that is unlikely to cause cracking and has satisfactory coating properties with respect to a substrate while the lithography characteristics such as the resolution and DOF are maintained can be formed.

It is preferable that various materials that are used in the resist composition according to the above-described embodiment and the pattern forming method according to the above-described embodiment (for example, a resist solvent, a developing solution, a rinse solution, a composition for forming an antireflection film, and a composition for forming a top coat) do not contain impurities such as a metal, a metal salt containing halogen, an acid, an alkali, and a component having a sulfur atom or phosphorus atom. Here, examples of the impurities containing metal atoms include Na, K, Ca, Fe, Cu, Mn, Mg, Al, Cr, Ni, Zn, Ag, Sn, Pb, Li, and salts thereof. The content of the impurities contained in these materials is preferably 200 ppb or less, more preferably 1 ppb or less, still more preferably 100 parts per trillion (ppt) or less, particularly preferably 10 ppt or less, and most preferably substantially zero (less than or equal to the detection limit of the measuring device).

### EXAMPLES

Hereinafter, the present invention will be described in more detail based on examples, but the present invention is not limited to these examples.

### <Preparation of Resist Composition>

### Examples 1 to 26 and Comparative Examples 1 to 6

Each of the components shown in Tables 1 to 4 was mixed and dissolved to prepare a resist composition of each Example.

TABLE 1

| | Component | Component | Component | Component | Component | Component | |
|---|---|---|---|---|---|---|---|
| | (A) | (B) | (C) | (D) | (Z) | (S) | |
| Example 1 | (A)-1 | (B)-1 | (C)-1 | (D)-1 | (Z)-1 | (S)-1 | (S)-2 |
| | [100] | [5.0] | [15] | [0.5] | [5.0] | [75] | [300] |
| Example 2 | (A)-1 | (B)-1 | (C)-1 | (D)-1 | (Z)-2 | (S)-1 | (S)-2 |
| | [100] | [5.0] | [15] | [0.5] | [5.0] | [75] | [300] |
| Example 3 | (A)-1 | (B)-1 | (C)-1 | (D)-1 | (Z)-3 | (S)-1 | (S)-2 |
| | [100] | [5.0] | [15] | [0.5] | [5.0] | [75] | [300] |
| Example 4 | (A)-1 | (B)-1 | (C)-1 | (D)-1 | (Z)-4 | (S)-1 | (S)-2 |
| | [100] | [5.0] | [15] | [0.5] | [5.0] | [75] | [300] |
| Example 5 | (A)-1 | (B)-1 | (C)-1 | (D)-1 | (Z)-1 | (S)-1 | (S)-2 |
| | [100] | [5.0] | [15] | [0.5] | [10.0] | [75] | [300] |
| Example 6 | (A)-1 | (B)-1 | (C)-1 | (D)-1 | (Z)-2 | (S)-1 | (S)-2 |
| | [100] | [5.0] | [15] | [0.5] | [10.0] | [75] | [300] |
| Example 7 | (A)-1 | (B)-1 | (C)-1 | (D)-1 | (Z)-3 | (S)-1 | (S)-2 |
| | [100] | [5.0] | [15] | [0.5] | [10.0] | [75] | [300] |
| Example 8 | (A)-1 | (B)-1 | (C)-1 | (D)-1 | (Z)-4 | (S)-1 | (S)-2 |
| | [100] | [5.0] | [15] | [0.5] | [10.0] | [75] | [300] |
| Example 9 | (A)-1 | (B)-2 | (C)-1 | (D)-1 | (Z)-4 | (S)-1 | (S)-2 |
| | [100] | [5.0] | [15] | [0.5] | [10.0] | [75] | [300] |
| Example 10 | (A)-1 | (B)-3 | (C)-1 | (D)-1 | (Z)-4 | (S)-1 | (S)-2 |
| | [100] | [5.0] | [15] | [0.5] | [10.0] | [75] | [300] |

TABLE 2

| | Component | Component | Component | Component | Component | Component | |
|---|---|---|---|---|---|---|---|
| | (A) | (B) | (C) | (D) | (Z) | (S) | |
| Example 11 | (A)-1 | (B)-4 | (C)-1 | (D)-1 | (Z)-4 | (S)-1 | (S)-2 |
| | [100] | [5.0] | [15] | [0.5] | [10.0] | [75] | [300] |
| Example 12 | (A)-1 | (B)-2 | (C)-1 | (D)-1 | (Z)-1 | (S)-1 | (S)-2 |
| | [100] | [5.0] | [15] | [0.5] | [10.0] | [75] | [300] |
| Example 13 | (A)-1 | (B)-3 | (C)-1 | (D)-1 | (Z)-2 | (S)-1 | (S)-2 |
| | [100] | [5.0] | [15] | [0.5] | [10.0] | [75] | [300] |
| Example 14 | (A)-1 | (B)-4 | (C)-1 | (D)-1 | (Z)-3 | (S)-1 | (S)-2 |
| | [100] | [5.0] | [15] | [0.5] | [10.0] | [75] | [300] |
| Example 15 | (A)-1 | (B)-2 | (C)-1 | (D)-1 | (Z)-4 | (S)-1 | (S)-2 |
| | [100] | [5.0] | [10] | [0.5] | [10.0] | [75] | [300] |
| Example 16 | (A)-1 | (B)-2 | (C)-1 | (D)-1 | (Z)-4 | (S)-1 | (S)-2 |
| | [100] | [5.0] | [5] | [0.5] | [10.0] | [75] | [300] |
| Example 17 | (A)-1 | (B)-1 | (C)-1 | (D)-1 | (Z)-2 | (S)-1 | (S)-2 |
| | [100] | [5.0] | [15] | [0.5] | [1.0] | [75] | [300] |
| Example 18 | (A)-1 | (B)-1 | (C)-1 | (D)-1 | (Z)-2 | (S)-1 | (S)-2 |
| | [100] | [5.0] | [15] | [0.5] | [3.0] | [75] | [300] |
| Example 19 | (A)-1 | (B)-1 | (C)-1 | (D)-1 | (Z)-2 | (S)-1 | (S)-2 |
| | [100] | [5.0] | [15] | [0.5] | [20.0] | [75] | [300] |
| Example 20 | (A)-1 | (B)-1 | (C)-2 | (D)-1 | (Z)-4 | (S)-1 | (S)-2 |
| | [100] | [5.0] | [10] | [0.5] | [10.0] | [75] | [300] |

TABLE 3

| | Component | Component | Component | Component | Component | Component | |
|---|---|---|---|---|---|---|---|
| | (A) | (B) | (C) | (D) | (Z) | (S) | |
| Example 21 | (A)-2 | (B)-1 | (C)-1 | (D)-1 | (Z)-4 | (S)-1 | (S)-2 |
| | [100] | [5.0] | [15] | [0.5] | [10.0] | [75] | [300] |
| Example 22 | (A)-3 | (B)-1 | (C)-1 | (D)-1 | (Z)-4 | (S)-1 | (S)-2 |
| | [100] | [5.0] | [15] | [0.5] | [10.0] | [75] | [300] |
| Example 23 | (A)-4 | (B)-1 | (C)-1 | (D)-1 | (Z)-4 | (S)-1 | (S)-2 |
| | [100] | [5.0] | [15] | [0.5] | [10.0] | [75] | [300] |
| Example 24 | (A)-5 | (B)-1 | (C)-1 | (D)-1 | (Z)-4 | (S)-1 | (S)-2 |
| | [100] | [5.0] | [15] | [0.5] | [10.0] | [75] | [300] |
| Example 25 | (A)-1 | (B)-1 | (C)-1 | (D)-1 | (Z)-2 | (S)-1 | (S)-2 |
| | [100] | [5.0] | [15] | [0.5] | [10.0] | [60] | [240] |
| Example 26 | (A)-1 | (B)-1 | (C)-1 | (D)-1 | (Z)-2 | (S)-1 | (S)-2 |
| | [100] | [5.0] | [15] | [0.5] | [10.0] | [100] | [400] |

TABLE 4

| | Component | Component | Component | Component | Component | Component | |
|---|---|---|---|---|---|---|---|
| | (A) | (B) | (C) | (D) | (Z) | (S) | |
| Comparative | (A)-1 | (B)-1 | (C)-1 | (D)-1 | — | (S)-1 | (S)-2 |
| Example 1 | [100] | [5.0] | [15] | [0.5] | | [75] | [300] |
| Comparative | (A)-1 | (B)-3 | (C)-1 | (D)-1 | — | (S)-1 | (S)-2 |
| Example 2 | [100] | [5.0] | [15] | [0.5] | | [75] | [300] |
| Comparative | (A)-1 | (B)-1 | (C)-1 | (D)-1 | (Z)-11 | (S)-1 | (S)-2 |
| Example 3 | [100] | [5.0] | [15] | [0.5] | [10.0] | [75] | [300] |
| Comparative | (A)-1 | (B)-1 | (C)-1 | (D)-1 | — | (S)-1 | (S)-2 |
| Example 4 | [100] | [5.0] | [15] | [0.5] | | [60] | [240] |
| Comparative | (A)-1 | (B)-1 | (C)-1 | (D)-1 | — | (S)-1 | (S)-2 |
| Example 5 | [100] | [5.0] | [15] | [0.5] | | [240] | [960] |
| Comparative | (A)-1 | (B)-1 | (C)-1 | (D)-1 | (Z)-2 | (S)-1 | (S)-2 |
| Example 6 | [100] | [5.0] | [15] | [0.5] | [10.0] | [240] | [960] |

In Tables 1 to 4, each abbreviation has the following meaning. The numerical values in the brackets are blending amounts (parts by mass).

(A)-1: polymer compound represented by Chemical Formula (A-1) This polymer compound (A-1) was obtained by anionic polymerization using monomers from which constitutional units constituting the polymer compound were derived, at a predetermined molar ratio. The weight-average molecular weight (Mw) of the polymer compound (A-1) determined by GPC measurement in terms of standard polystyrene was 2.500, and the polydispersity (Mw/Mn) was 1.20. The copolymerization compositional ratio (the ratio (molar ratio) of each constitutional unit in the structural formula) determined by ¹³C-NMR was l/m=85/15.

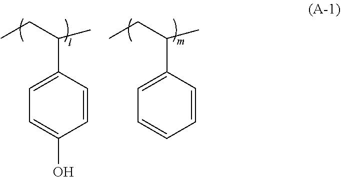

(A)-2: polymer compound (homopolymer) represented by Chemical Formula (A-2) This polymer compound (A-2) was obtained by anionic polymerization using a monomer (hydroxystyrene) from which constitutional units constituting the polymer compound were derived. The weight-average molecular weight (Mw) of the polymer compound (A-2) determined by GPC measurement in terms of standard polystyrene was 2.500, and the polydispersity (Mw/Mn) was 1.20.

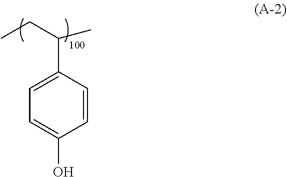

(A)-3: polymer compound represented by Chemical Formula (A-3) This polymer compound (A-3) was obtained by radical polymerization using monomers from which constitutional units constituting the polymer compound were derived, at a predetermined molar ratio. The weight-average molecular weight (Mw) of the polymer compound (A-3) determined by GPC measurement in terms of standard polystyrene was 2,500, and the polydispersity (Mw/Mn) was 1.50. The copolymerization compositional ratio (the ratio (molar ratio) of each constitutional unit in the structural formula) determined by ¹³C-NMR was l/m=85/15.

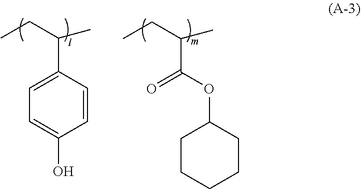

(A)-4: polymer compound represented by Chemical Formula (A-4) This polymer compound (A-4) was obtained by radical polymerization using monomers from which constitutional units constituting the polymer compound were derived, at a predetermined molar ratio. The weight-average molecular weight (Mw) of the polymer compound (A-4) determined by GPC measurement in terms of standard polystyrene was 2.500, and the polydispersity (Mw/Mn) was 1.50. The copolymerization compositional ratio (the ratio (molar ratio) of each constitutional unit in the structural formula) determined by ¹³C-NMR was l/m=85/15.

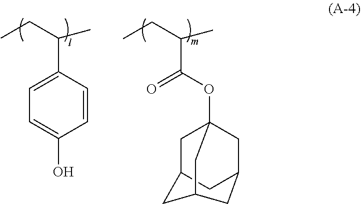

(A)-5: polymer compound represented by Chemical Formula (A-5) This polymer compound (A-5) was obtained by radical polymerization using monomers from which constitutional units constituting the polymer compound were derived, at a predetermined molar ratio. The weight-average molecular weight (Mw) of the polymer compound (A-5) determined by GPC measurement in terms of standard polystyrene was 2,500, and the polydispersity (Mw/Mn) was 1.50. The copolymerization compositional ratio (the ratio (molar ratio) of each constitutional unit in the structural formula) determined by ¹³C-NMR was l/m=85/15.

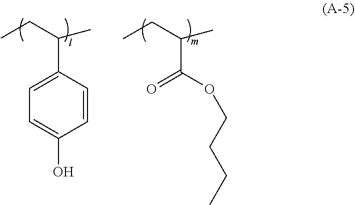

(B)-1 to (B)-4: acid generators formed of compounds each represented by Chemical Formulae (B-1) to (B-4)

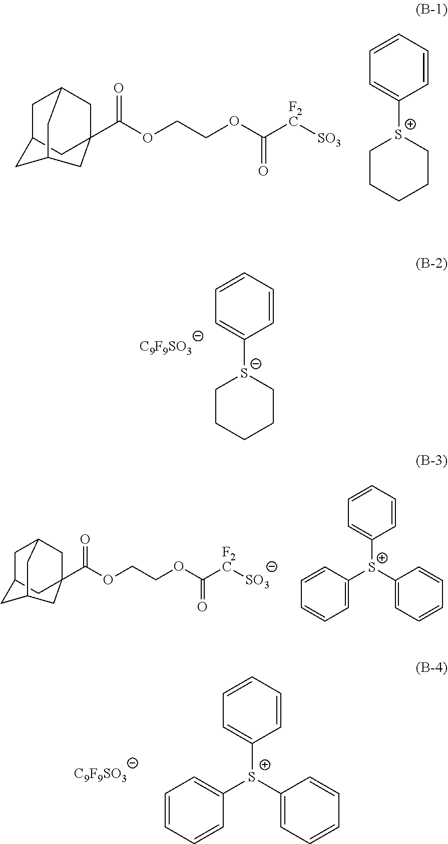

(C)-1 and (C)-2: crosslinking agents formed of compounds each represented by Chemical Formulae (C-1) and (C-2)

(D)-1: nitrogen-containing organic compound formed of compound represented by Chemical Formula (D-1)

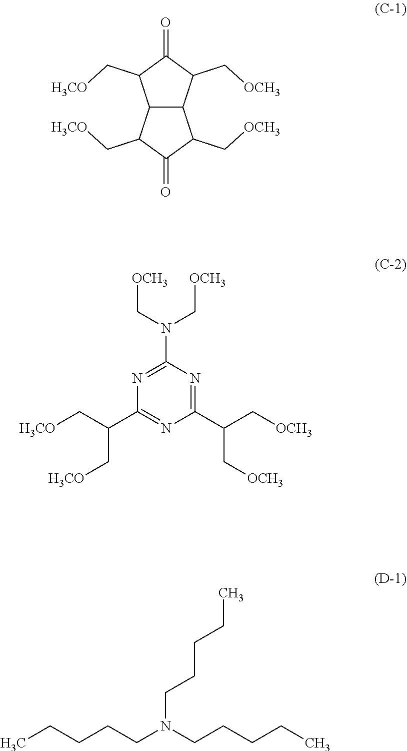 [SMILES: COCC1C(=O)C(COC)C2C(COC)C(=O)C(COC)C12 ; COCC(COC)c1nc(C(COC)COC)nc(N(COC)COC)n1 ; CCCCCN(CCCCC)CCCCC]

(Z)-1 to (Z)-4: compounds each represented by Chemical Formulae (Z-1) to (Z-4)

(Z)-11: compound represented by Chemical Formula (Z-11)

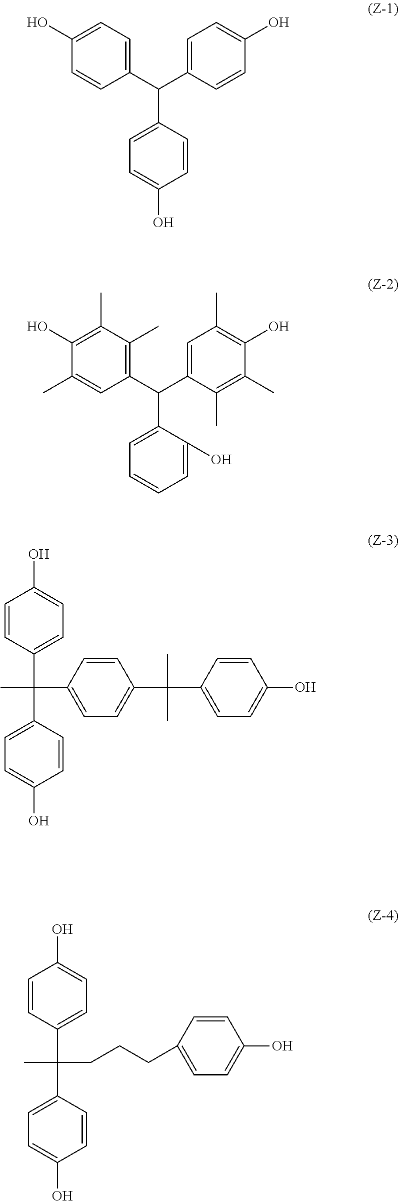

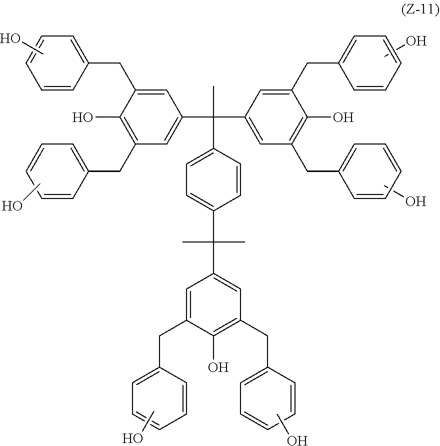

(S)-1: propylene glycol monomethyl ether acetate

(S)-2: propylene glycol monomethyl ether

### <Resist Pattern Formation (1)>

### Step (i):

A silicon wafer that had been treated with hexamethyldisilazane (HMDS) at 110° C. for 60 seconds was coated with the resist composition of each example using a spinner. The wafer was subjected to a post applied bake (PAB) treatment on a hot plate at 90° C. for 60 seconds and dried, thereby forming a resist film having the film thickness listed in Tables 5 to 8.

### Step (ii):

Next, the resist film was selectively irradiated with a KrF excimer laser (248 nm) by a KrF exposure apparatus NSR—S203B (manufactured by Nikon Corporation; numerical aperture (NA)=0.60, σ=0.68) through a mask pattern (binary mask).

Thereafter, a post exposure bake (PEB) treatment was performed on the resist film at 110° C. for 60 seconds.

Step (iii):

Subsequently, alkali development was performed under the conditions of 23° C. and 60 seconds using a 2.38% by mass tetramethylammonium hydroxide (TMAH) aqueous solution “NMD-3” (product name, manufactured by TOKYO OHKA KOGYO CO., LTD.) as a developing solution.

Thereafter, post bake was performed at 100° C. for 60 seconds.

As a result, an isolated space pattern (IS pattern) having a space width of 500 nm was formed.

### [Evaluation of Sensitivity]

The optimum exposure amount Eop (mJ/cm²) in which an IS pattern having a space width of 500 nm was formed in the section of <resist pattern formation (1)> described above was determined. The results are listed in the columns of “sensitivity (mJ/cm²)” in Tables 5 to 8.

### [Evaluation of Resolution]

The minimum dimensions of the pattern that was resolved without being collapsed during formation of an IS pattern by gradually increasing the exposure amount from the optimum exposure amount Eop in which an IS pattern having a target size was formed in the section of <resist pattern formation (1)> described above were determined using a scanning electron microscope 5-9380 (manufactured by Hitachi High-Tech Corporation). The results are listed in the columns of “resolution (nm)” in Tables 5 to 8.

### [Evaluation of Depth of Focus (DOF)]

An IS pattern was formed by the same method as in the section of <resist pattern formation (1)> described above by appropriately shifting the focus in the vertical direction at the optimum exposure amount (Eop (mJ/cm²)) in which an IS pattern was formed in the section of <resist pattern formation (1)>. Here, the width of depth of focus (DOF, unit: nm) at which an IS pattern can be formed within a range of a dimensional change rate of the target dimensions±10% was determined. The results are listed in the columns of “10% DOF (nm)” in Tables 5 to 8.

### <Resist Pattern Formation (2)>

### Step (i):

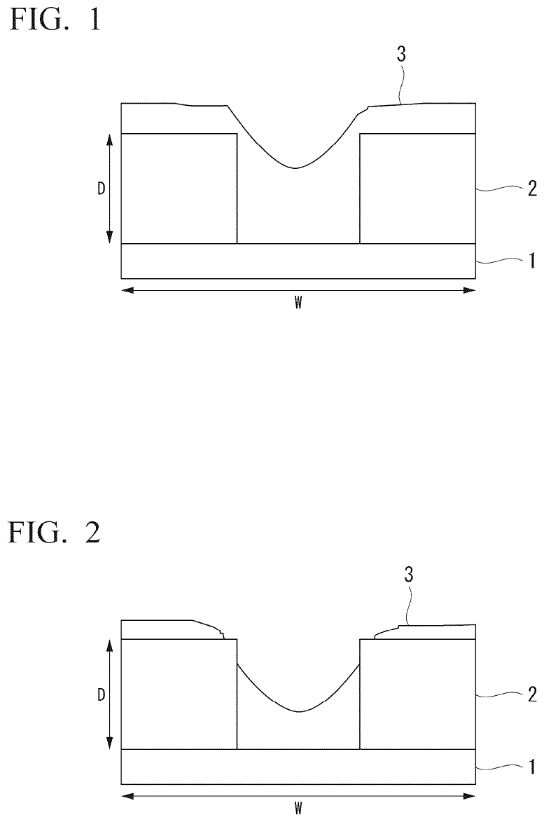

A SiO₂ substrate having a step with a depth (D in FIG. 1 or 2) of 6 μm and a width (W in FIG. 1 or 2) of 2.5 μm, which had been treated with hexamethyldisilazane (HMDS) at 110° C. for 60 seconds, was coated with the resist composition of each example using a spinner. The wafer was subjected to a post applied bake (PAB) treatment on a hot plate at 90° C. for 60 seconds and dried, thereby forming a resist film having the film thickness listed in Tables 5 to 8.

### Step (ii):

Next, the entire surface of the resist film was exposed to a KrF excimer laser (248 nm) using a KrF exposure apparatus NSR—S203B (manufactured by Nikon Corporation; numerical aperture (NA)=0.60, σ=0.68).

Thereafter, a post exposure bake (PEB) treatment was performed on the resist film at 110° C. for 60 seconds.

Step (iii):

Subsequently, alkali development was performed under the conditions of 23° C. and 60 seconds using a 2.38% by mass tetramethylammonium hydroxide (TMAH) aqueous solution “NMD-3” (product name, manufactured by TOKYO OHKA KOGYO CO., LTD.) as a developing solution.

Thereafter, post bake was performed at 100° C. for 60 seconds.

As a result, a substrate having a surface on which a simulated resist pattern was formed was obtained.

### [Evaluation of Cracks]

The substrate obtained in the section of <resist pattern formation (2)> described above was observed with an optical microscope, and the number of cracks was counted. The number of cracks was evaluated based on the following evaluation criteria. The results are listed in the columns of “Cracks” in Tables 5 to 8.

### Evaluation Criteria

A: The number of cracks was 0.
B: The number of cracks was in a range of 1 to 9.
Z: The number of cracks was 10 or greater.

### [Evaluation of Coating Properties]

The substrate obtained in the section of <resist pattern formation (2)> described above was observed with a scanning electron microscope SU5000 (manufactured by Hitachi High-Tech Corporation), and the coating properties were evaluated according to the following evaluation criteria. The results are listed in the columns of “coating properties” in Tables 5 to 8.

### Evaluation Criteria

A: As shown in FIG. 1, the entire surface of the substrate was covered with the simulated resist pattern.

Z: As shown in FIG. 2, portions which were not covered with the simulated resist pattern were found in the stepped portion of the substrate.

TABLE 5

| | Thickness | | Reso- | 10% | | |
|---|---|---|---|---|---|---|
| | of resist | Sensitivity | lution | DOF | | Coating |
| | film (μm) | (mJ/cm²) | (nm) | (nm) | Cracks | properties |
| Example 1 | 3 | 35 | 425 | 750 | B | A |
| Example 2 | 3 | 30 | 400 | 800 | B | A |
| Example 3 | 3 | 35 | 425 | 700 | B | A |
| Example 4 | 3 | 25 | 400 | 800 | A | A |
| Example S | 3 | 30 | 450 | 700 | B | A |
| Example 6 | 3 | 25 | 425 | 750 | A | A |
| Example 7 | 3 | 35 | 450 | 650 | A | A |
| Example 8 | 3 | 25 | 425 | 800 | A | A |
| Example 9 | 3 | 20 | 425 | 850 | A | A |
| Example 10 | 3 | 35 | 475 | 700 | A | A |

TABLE 6

| | Thickness | | Reso- | 10% | | |
|---|---|---|---|---|---|---|
| | of resist | Sensitivity | lution | DOF | | Coating |
| | film (μm) | (mJ/cm²) | (nm) | (nm) | Cracks | properties |
| Example 11 | 3 | 30 | 475 | 750 | A | A |
| Example 12 | 3 | 25 | 450 | 750 | B | A |
| Example 13 | 3 | 35 | 475 | 800 | A | A |
| Example 14 | 3 | 40 | 500 | 600 | A | A |
| Example 15 | 3 | 20 | 425 | 800 | A | A |
| Example 16 | 3 | 25 | 450 | 850 | A | A |
| Example 17 | 3 | 30 | 400 | 800 | B | A |
| Example 18 | 3 | 30 | 400 | 800 | B | A |
| Example 19 | 3 | 20 | 450 | 750 | A | A |
| Example 20 | 3 | 50 | 500 | 600 | A | A |

TABLE 7

| | Thickness | | Reso- | 10% | | |
|---|---|---|---|---|---|---|
| | of resist | Sensitivity | lution | DOF | | Coating |
| | film (μm) | (mJ/cm²) | (nm) | (nm) | Cracks | properties |
| Example 21 | 3 | 25 | 450 | 800 | A | A |
| Example 22 | 3 | 35 | 400 | 850 | A | A |
| Example 23 | 3 | 30 | 400 | 800 | A | A |
| Example 24 | 3 | 35 | 400 | 900 | A | A |
| Example 25 | 5 | 30 | 500 | 600 | A | A |
| Example 26 | 2 | 25 | 400 | 800 | A | A |

TABLE 8

| | Thickness | | Reso- | 10% | | |
|---|---|---|---|---|---|---|
| | of resist | Sensitivity | lution | DOF | | Coating |
| | film (μm) | (mJ/cm²) | (nm) | (nm) | Cracks | properties |
| Comparative | 3 | 30 | 400 | 800 | Z | A |
| Example 1 | | | | | | |
| Comparative | 3 | 40 | 450 | 750 | Z | A |
| Example 2 | | | | | | |
| Comparative | 3 | 40 | 600 | 400 | B | A |
| Example 3 | | | | | | |
| Comparative | 5 | 35 | 500 | 600 | Z | A |
| Example 4 | | | | | | |
| Comparative | 1 | 25 | 375 | 800 | A | Z |
| Example 5 | | | | | | |
| Comparative | 1 | 25 | 375 | 800 | A | Z |
| Example 6 | | | | | | |

As shown in the results listed in Tables 5 to 8, it was confirmed that the thick-film resist patterns formed by using the resist compositions of Examples 1 to 26 had satisfactory resolution and 10% DOF, reduced occurrence of cracking, and had satisfactory coating properties.

While preferred examples of the present invention have been described and illustrated above, it should be understood that these are exemplary of the present invention and are not to be considered as limiting. Additions, omissions, substitutions, and other modifications of configurations can be made without departing from the scope of the present invention. The present invention is not limited by the foregoing description, but is limited only by the scope of the appended claims.

### REFERENCE SIGNS LIST

1: Substrate
2: Step
3: Resist

What is claimed is:

1. A resist composition comprising:
a polymer compound (A1) having a constitutional unit (a10) represented by General Formula (a10-1);
an onium salt-based acid generator (B1);
at least one crosslinking agent (C) selected from the group consisting of a melamine-based crosslinking agent, a urea-based crosslinking agent, an alkylene urea-based crosslinking agent, a glycoluril-based crosslinking agent, and an epoxy-based crosslinking agent; and
a polynuclear phenol low-molecular-weight compound (Z) containing 5 or less phenyl groups,
wherein the resist composition has a solid content concentration of 15% by mass or greater, 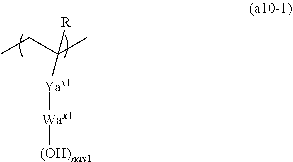
wherein R represents a hydrogen atom, an alkyl group having 1 to 5 carbon atoms, or a halogenated alkyl group having 1 to 5 carbon atoms, Ya^{x1} represents a single bond or a divalent linking group, Wa^{x1} represents an aromatic hydrocarbon group which may have a substituent, and nₐₓ₁ represents an integer of 1 or greater.

2. The resist composition according to claim 1, wherein the polynuclear phenol low-molecular-weight compound (Z) has 2 to 5 phenyl groups.

3. The resist composition according to claim 1,
wherein the polynuclear phenol low-molecular-weight compound (Z) includes a compound represented by General Formula (z-1), 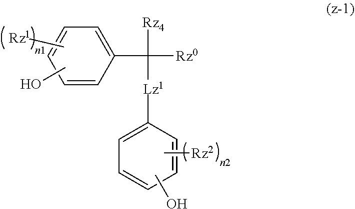
wherein Rz¹ and Rz² each independently represent a substituent, n1 and n2 each independently represent an integer of 0 to 4, Lz¹ represents a single bond or a divalent linking group, Rz⁰ represents a hydrocarbon group which may have a substituent, and Rz⁴ represents a hydrogen atom or an alkyl group.

4. The resist composition according to claim 1,
wherein the polynuclear phenol low-molecular-weight compound (Z) includes a compound represented by General Formula (z-1-1), 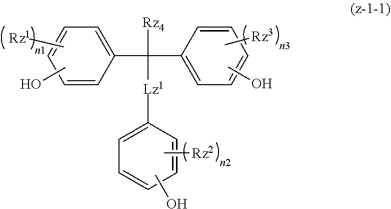
wherein Rz¹, Rz², and Rz³ each independently represent a substituent, n1, n2, and n3 each independently represent an integer of 0 to 4, Lz¹ represents a single bond or a divalent linking group, and Rz⁴ represents a hydrogen atom or an alkyl group.

5. The resist composition according to claim 1,
wherein the onium salt-based acid generator (B1) includes an acid generator (B1-1) represented by General Formula (b1-1), 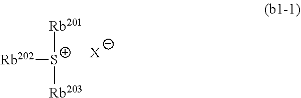
wherein Rb²⁰¹ to Rb²⁰³ each independently represent an aryl group which may have a substituent, an alkyl group which may have a substituent, or an alkenyl group which may have a substituent, R²⁰¹ to R²⁰³ may be bonded to each other to form a ring with a sulfur atoms in the formula, and X⁻ represents a counter anion.

6. A method for forming a resist pattern, comprising:
forming a resist film on a support using the resist composition according to claim 1;
exposing the resist film to light; and
developing the resist film exposed to light to form a resist pattern.
